(19) United States
(12) Patent Application Publication
(10) Pub. No.: US 2022/0091503 A1
(43) Pub. Date: Mar. 24, 2022

(54) COMPOSITION FOR FORMING PATTERN, CURED FILM, LAMINATE, PATTERN PRODUCING METHOD, AND METHOD FOR MANUFACTURING SEMICONDUCTOR ELEMENT

(71) Applicant: FUJIFILM Corporation, Tokyo (JP)

(72) Inventor: Yuichiro GOTO, Shizuoka (JP)

(73) Assignee: FUJIFILM Corporation, Tokyo (JP)

(21) Appl. No.: 17/542,499

(22) Filed: Dec. 6, 2021

Related U.S. Application Data
(63) Continuation of application No. PCT/JP2020/021513, filed on Jun. 1, 2020.

(30) Foreign Application Priority Data
Jun. 7, 2019 (JP) 2019-107130

(51) Int. Cl. G03F 7/004; G03F 7/20

(52) U.S. Cl. CPC G03F 7/0045; G03F 7/2004

(57) ABSTRACT

Provided are a composition for forming a pattern for imprinting, including (A) a polymerizable compound which contains an aromatic ring and does not contain a hydroxyl group, (B) a photopolymerization initiator which contains an aromatic ring and does not contain a hydroxyl group, and (C) a photopolymerization initiator which has a specific structure containing a hydroxyl group, in which a viscosity of components excluding a solvent from the composition for forming a pattern at 23° C. is 300 mPa·s or lower; a cured film to which the composition for forming a pattern is applied; a laminate; a pattern producing method; and a method for manufacturing a semiconductor element.

### CROSS-REFERENCE TO RELATED APPLICATIONS

This application is a Continuation of PCT International Application No. PCT/JP2020/021513 filed on Jun. 1, 2020, which claims priority under 35 U.S.C § 119(a) to Japanese Patent Application No. 2019-107130 filed on Jun. 7, 2019. Each of the above application(s) is hereby expressly incorporated by reference, in its entirety, into the present application.

### BACKGROUND OF THE INVENTION

### 1. Field of the Invention

The present invention relates to a composition for forming a pattern for imprinting, a cured film, a laminate, a pattern producing method, and a method for manufacturing a semiconductor element.

### 2. Description of the Related Art

An imprinting method is a technique in which a fine pattern is transferred to a plastic material by pressing a metal mold (generally also called a mold or a stamper) on which a pattern is formed. The imprinting method enables simple and precise production of a fine pattern, and thus is expected to be applied in various fields in recent years. In particular, a nanoimprint technique for forming a fine pattern of a nano-order level is attracting attention.

The imprinting method is roughly classified into a thermal imprinting method and an optical imprinting method according to a transfer method thereof. In the thermal imprinting method, a mold is pressed against a thermoplastic resin heated to a temperature equal to or higher than a glass transition temperature (hereinafter, referred to as a “Tg” in some cases), the thermoplastic resin is cooled, and then the mold is released to form a fine pattern. This method has an advantage that various materials can be selected, but also has problems in that a high pressure is required during pressing, and as the pattern size is finer, the dimensional accuracy is more likely to be reduced due to thermal shrinkage or the like. Meanwhile, in the optical imprinting method, after photocuring is performed in a state where a mold is pressed against a photocurable composition for forming a pattern, the mold is released. In this method, high-pressure application or high-temperature heating is not required, a dimensional change before and after curing is small, and thus there is an advantage that a fine pattern can be formed with high accuracy.

In the optical imprinting method, a composition for forming a pattern is applied onto a substrate, and then a mold made of a light-transmitting material such as quartz is pressed (JP2007-523249A). The composition for forming a pattern is cured by light irradiation in a state where the mold is pressed, and then the mold is released to produce a cured substance to which a desired pattern is transferred.

As irradiation light for curing the composition for forming a pattern, ultraviolet rays are usually used, and as a light source lamp which radiates the ultraviolet rays, a high-pressure mercury lamp, an ultra-high pressure mercury lamp, a low-pressure mercury lamp, a xenon lamp, a metal halide lamp, an excimer lamp, an ultraviolet ray light emitting diode (LED), and the like are used.

A method of performing fine processing on a substrate such as a wafer using a transferred imprint pattern as a mask is called nanoimprint lithography (NIL), and has been developed as a next-generation lithography technology. A composition for forming a pattern used for NIL is required to have a high etching selectivity (high etching resistance) with an object to be processed, and be able to form an ultrafine and high-aspect ratio pattern (high resolution), in addition to imprint suitability.

In addition, in order to ensure the reactivity to light, a photopolymerization initiator may be added to the composition for forming a pattern (JP2007-523249A, JP2015-070145A, WO2016/152597A, and JP6092200B). As the photopolymerization initiator, a radical polymerization initiator, a cationic polymerization initiator, and the like are used, but from the viewpoint of a throughput (productivity), a radical polymerization initiator which has high reactivity and allows the curing reaction to proceed in a shorter time may be selected. Moreover, in order to further promote the reaction, the addition of a sensitizer and the like have also been under consideration (JP2008-238417A, JP2015-179807A, and JP2017-085148A).

### SUMMARY OF THE INVENTION

In the imprinting method, while higher resolution of the pattern is required, since the aspect ratio of the pattern increases in a case where the pattern is miniaturized, the problem of pattern collapse (collapse defects) due to insufficient curing is remarkable. In addition, it has now been found that an unreacted polymerizable compound remaining in the composition for forming a pattern may be attached to a surface of a mold to induce the pattern collapse defects.

The present invention has been made in consideration of the aforementioned problems, and an object of the present invention is to provide a composition for forming a pattern, which is capable of suppressing occurrence of collapse defects even in high-resolution pattern formation.

Moreover, another object of the present invention is to provide a cured film to which the composition for forming a pattern is applied, a laminate, a pattern producing method, and a method for manufacturing a semiconductor element.

The above-described problems can be solved by using a polymerizable compound having a specific structure and two types of photopolymerization initiators respectively having a specific structure. Specifically, the aforementioned problems can be solved by the following unit <1> and preferably by a unit <2> and subsequent units.

<1>

A composition for forming a pattern for imprinting, comprising:

(A) a polymerizable compound which contains an aromatic ring and does not contain a hydroxyl group;

(B) a photopolymerization initiator which contains an aromatic ring and does not contain a hydroxyl group; and

(C) a photopolymerization initiator represented by Formula (In-1),

in which a viscosity of components excluding a solvent from the composition for forming a pattern at 23° C. is 300 mPa·s or lower,

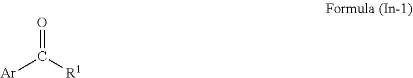

in Formula (In-1), Ar represents an aromatic ring-containing group having an aromatic ring substituted with one or more substituents, where at least one of the substituents is an electron-donating group, at least one of the substituents includes —O— directly linked to the aromatic ring, and at least one of the substituents includes a hydroxyl group, and

R¹ represents an aliphatic hydrocarbon group substituted with one or more hydroxyl groups.

<2>

The composition for forming a pattern according to <1>,

in which Cb/Cc, which is a mass ratio of a content Cb of the photopolymerization initiator (B) to a content Cc of the photopolymerization initiator (C), is 0.5 to 5.

<3>

The composition for forming a pattern according to <1> or <2>,

in which a content of the photopolymerization initiator (B) is 0.5% to 8% by mass with respect to the polymerizable compound (A).

<4>

The composition for forming a pattern according to any one of <1> to <3>, in which a content of the photopolymerization initiator (C) is 0.5% to 5% by mass with respect to the polymerizable compound (A).

<5>

The composition for forming a pattern according to any one of <1> to <4>,

in which a compound represented by Formula (In-2) is contained as the photopolymerization initiator (C),

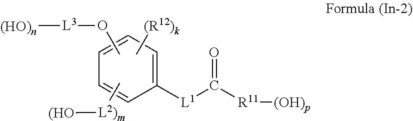

in Formula (In-2), L¹ and L² each independently represent a single bond or a divalent linking group,
L³ represents an (n+1)-valent linking group,

R¹¹ represents a (p+1)-valent aliphatic hydrocarbon group,

R¹² represents a monovalent substituent,

k, m, and n each independently represent an integer of 0 to 2, where m+n is 1 to 3 and k+m+n is 1 to 5, and

p represents an integer of 1 to 3.

<6>

The composition for forming a pattern according to any one of <1> to <5>,

in which a compound represented by Formula (In-3) is contained as the photopolymerization initiator (C),

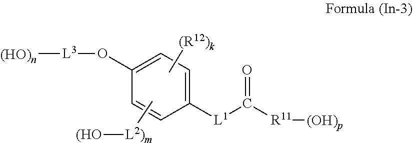

in Formula (In-3), L¹ and L² each independently represent a single bond or a divalent linking group,

L³ represents an (n+1)-valent linking group,

R¹¹ represents a (p+1)-valent aliphatic hydrocarbon group,

R¹² represents a monovalent substituent,

k, m, and n each independently represent an integer of 0 to 2, where m+n is 1 to 3 and k+m+n is 1 to 5, and

p represents an integer of 1 to 3.

<7>

The composition for forming a pattern according to any one of <1> to <6>,

in which a molecular weight of the photopolymerization initiator (C) is 170 to 330.

<8>

The composition for forming a pattern according to any one of <1> to <7>,

in which a Hansen solubility parameter distance ΔHSP between the photopolymerization initiator (B) and the photopolymerization initiator (C) is 4 or more.

<9>

The composition for forming a pattern according to any one of <1> to <8>,

in which an acylphosphine oxide-based compound is contained as the photopolymerization initiator (B).

<10>

The composition for forming a pattern according to any one of <1> to <9>,

in which a content of the polymerizable compound (A) is 30% to 90% by mass with respect to a total polymerizable compound.

<11>

The composition for forming a pattern according to any one of <1> to <10>,

in which a content of a total solid content in the composition for forming a pattern is 90% by mass or greater with respect to an entire composition for forming a pattern.

<12>

The composition for forming a pattern according to <11>,

in which the composition for forming a pattern does not substantially contain the solvent.

<13>

The composition for forming a pattern according to any one of <1> to <12>, further comprising:

(D) a release agent.

<14>

The composition for forming a pattern according to <13>,

in which the release agent includes a compound which contains a hydroxyl group.

<15>

The composition for forming a pattern according to <13> or <14>,

in which the release agent includes a compound which does not contain a hydroxyl group.

<16>

A cured film formed from the composition for forming a pattern according to any one of <1> to <15>.

<17>

A laminate comprising:

a layered film consisting of the composition for forming a pattern according to any one of <1> to <15>; and

a substrate for forming the layered film.

<18>

A pattern producing method comprising:

applying the composition for forming a pattern as described in any one of <1> to <15> onto a substrate or a mold; and

irradiating the composition for forming a pattern with light in a state of being sandwiched between the mold and the substrate.

<19>

A method for manufacturing a semiconductor element, comprising:

the producing method as described in <18> as a step.

<20>

The method for manufacturing a semiconductor element according to <19>, further comprising:

etching the substrate using the pattern as a mask.

With the composition for forming a pattern according to the aspect of the present invention, occurrence of collapse defects can be suppressed even in high-resolution pattern formation. Moreover, with the cured film, laminate, pattern producing method, and method for manufacturing a semiconductor element according to the aspect of the present invention, semiconductor element can be manufactured efficiently.

### DESCRIPTION OF THE PREFERRED EMBODIMENTS

Hereinafter, representative embodiments of the present invention will be described. Respective constituent elements will be described based on the representative embodiments for convenience, but the present invention is not limited to such embodiments.

In the present specification, a numerical range expressed using the term “to” means a range which includes the preceding and succeeding numerical values of “to” as a lower limit value and an upper limit value, respectively.

In the present specification, the term “step” is meant to include not only an independent step, but also a step which cannot be clearly distinguished from other steps as long as an intended action of the step is achieved.

In the description of a group (atomic group) in the present specification, in a case where the group is described without specifying whether the group is substituted or unsubstituted, the description means that the group includes both a group having no substituent and a group having a substituent. For example, in a case where a group is simply described as an “alkyl group”, the description means that the alkyl group includes both an alkyl group having no substituent (unsubstituted alkyl group) and an alkyl group having a substituent (substituted alkyl group). Moreover, in a case where a group is simply described as an “alkyl group”, the description means that the alkyl group may be chain-like or cyclic, and may be linear or branched in a case where the alkyl group is chain-like.

In the present specification, unless otherwise specified, “exposure” is meant to include not only drawing using light but also drawing using particle rays such as electron beams and ion beams. Examples of energy rays used for the drawing include actinic rays such as a bright line spectrum of a mercury lamp, far ultraviolet rays typified by an excimer laser, extreme ultraviolet rays (EUV light), and X-rays, and particle rays such as electron beams and ion beams.

In the present specification, “light” includes not only light having a wavelength in an ultraviolet, near-ultraviolet, far-ultraviolet, visible, or infrared range, or an electromagnetic wave but also a radiation. Examples of the radiation include microwaves, electron beams, extreme ultraviolet rays (EUV), and X-rays. Moreover, laser light such as a 248-nm excimer laser, a 193-nm excimer laser, and a 172-nm excimer laser can also be used. The light may be monochromatic light (single-wavelength light) passing through an optical filter, or may be light (composite light) having a plurality of wavelengths.

In the present specification, “(meth)acrylate” means both “acrylate” and “methacrylate” or either of them, “(meth)acryl” means both “acryl” and “methacryl” or either of them, and “(meth)acryloyl” means both “acryloyl” and “methacryloyl” or either of them.

In the present specification, a solid content in a composition means components other than the solvent, and a concentration of the solid content in the composition is represented by the mass percentage of the components other than the solvent with respect to the total mass of the composition, unless otherwise specified.

In the present specification, a temperature is 23° C. and an atmospheric pressure is 101,325 Pa (1 atm), unless otherwise specified.

In the present specification, a weight-average molecular weight (Mw) and a number-average molecular weight (Mn) are each expressed as a value in terms of polystyrene according to gel permeation chromatography (GPC measurement), unless otherwise specified. The weight-average molecular weight (Mw) and the number-average molecular weight (Mn) can be determined, for example, by using HLC-8220 (manufactured by TOSOH CORPORATION), and, as columns, GUARD COLUMN HZ-L, TSKgel Super HZM-M, TSKgel Super HZ4000, TSKgel Super HZ3000, and TSKgel Super HZ2000 (manufactured by TOSOH CORPORATION). Moreover, the measurement is performed using tetrahydrofuran (THF) as an eluent, unless otherwise specified. Furthermore, for the detection in the GPC measurement, a detector of ultraviolet rays (UV rays) having a wavelength of 254 nm is used, unless otherwise specified.

In the present specification, regarding a positional relationship of respective layers constituting a laminate, in a case where there is a description of “upper” or “lower”, another layer may be on an upper side or a lower side of a reference layer among a plurality of layers of interest. That is, a third layer or element may be further interposed between the reference layer and the other layer, and the reference layer and the other layer are not necessary to be in contact with each other. Moreover, unless otherwise specified, in a case where a direction in which layers are stacked on a substrate is referred to as “upward” or there is a photosensitive layer, a direction from the substrate to the photosensitive layer is referred to as “upward”, and the opposite direction is referred to as “downward”. Furthermore, such setting of upward and downward directions is for convenience in the present specification, and in a practical aspect, the “upward” direction in the present specification may be different from a vertically upward direction.

In the present specification, “imprint” preferably refers to transfer of a pattern with a size of 1 nm to 10 mm, and more preferably refers to transfer (nanoimprint) of a pattern with a size of about 10 nm to 100 μm.

<Composition for Forming Pattern>

A composition for forming a pattern according to an embodiment of the present invention includes (A) a polymerizable compound (hereinafter, also referred to as a “polymerizable compound (A)”) which contains an aromatic ring and does not contain a hydroxyl group, (B) a photopolymerization initiator (hereinafter, also referred to as a “photopolymerization initiator (B)”) which contains an aromatic ring and does not contain a hydroxyl group, and (C) a photopolymerization initiator (hereinafter, also referred to as a “photopolymerization initiator (C)”) represented by Formula (In-1), in which a viscosity of components excluding a solvent from the composition for forming a pattern at 23° C. is 300 mPa·s or lower.

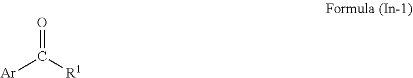

In Formula (In-1), Ar represents an aromatic ring-containing group having an aromatic ring substituted with one or more substituents, where at least one of the substituents is an electron-donating group, at least one of the substituents includes —O— directly linked to the aromatic ring, and at least one of the substituents includes a hydroxyl group, and

R¹ represents an aliphatic hydrocarbon group substituted with one or more hydroxyl groups.

In the present invention, since the composition for forming a pattern contains the above-described polymerizable compound (A), photopolymerization initiator (B), and photopolymerization initiator (C), occurrence of pattern collapse defects can be suppressed. The reason is not clear, but it is considered that the polymerizable compound (A) does not contain a hydroxyl group, so that attachment of the polymerizable compound to a surface of a mold is suppressed. In addition, since the photopolymerization initiator (B) has the same partial structure (a structure which contains an aromatic ring and does not contains a hydroxyl group) as the polymerizable compound (A), it is considered that compatibility between the photopolymerization initiator (B) and the polymerizable compound (A) is improved, and the overall curing of the composition for forming a pattern is promoted. Moreover, since the photopolymerization initiator (C) has a specific hydrophilic moiety, the photopolymerization initiator (C) tends to be unevenly distributed near a surface of the composition for forming a pattern, and since the aromatic ring-containing group has an electron-donating group, active species such as radicals are efficiently generated from the photopolymerization initiator (C) during exposure. As a result, it is considered that a curing of the composition for forming a pattern near the surface of the mold is promoted. Accordingly, it is considered that a polymerization reaction in the composition for forming a pattern can be efficiently promoted and the attachment of unreacted polymerizable compound to the mold can also be suppressed, so that the occurrence of collapse defects can be suppressed even in high-resolution pattern formation.

Hereinafter, each component of the composition for forming a pattern according to the embodiment of the present invention will be described in detail.

<<Polymerizable Compound (A)>>

The composition for forming a pattern according to the embodiment of the present invention contains a polymerizable compound (polymerizable compound (A)) which has a polymerizable group, and contains an aromatic ring and does not contain a hydroxyl group. The polymerizable compound (A) is preferably a radically polymerizable compound. Since the polymerizable compound (A) has an aromatic ring, etching resistance during imprint lithography is improved, and since the polymerizable compound (A) does not contain a hydroxyl group, attachment of the polymerizable compound (A) to the surface of the mold, which tends to be hydrophilic, is suppressed. On the other hand, in a case where the polymerizable compound (A) does not contain a hydroxyl group, the polymerizable compound (A) can have a substituent such as a hydrocarbon group (for example, an alkyl group, an aryl group, and the like) and a halogen atom. Hereinafter, the details will be described.

The aromatic ring of the polymerizable compound (A) may be a single ring or a polycyclic ring, and in a case of a polycyclic ring, a plurality of rings may be condensed. The aromatic ring may be an aromatic ring having a hydrocarbon ring skeleton, or an aromatic ring having a hetero ring skeleton containing a heteroatom such as N, O, and S, and an aromatic ring having a hydrocarbon ring skeleton is preferable. Regarding the aromatic ring having a hydrocarbon ring skeleton, the number of carbon atoms is preferably 6 to 22, more preferably 6 to 18, and still more preferably 6 to 10. As the aromatic ring having a hydrocarbon ring skeleton, for example, a benzene ring, a naphthalene ring, an anthracene ring, a phenanthrene ring, a fluorene ring, or the like is preferable, a benzene ring or a naphthalene ring is more preferable, and a benzene ring is still more preferable. In addition, as the aromatic ring having a hetero ring skeleton, for example, a thiophene ring, a furan ring, a dibenzofuran ring, or the like is preferable.

The polymerizable compound (A) may be a monofunctional polymerizable compound having one polymerizable group, or a polyfunctional polymerizable compound having two or more polymerizable groups. In the present invention, the composition for forming a pattern preferably includes a polyfunctional polymerizable compound (A), and more preferably includes both a polyfunctional polymerizable compound (A) and a monofunctional polymerizable compound (A). The polyfunctional polymerizable compound (A) preferably includes at least one kind of a bifunctional polymerizable compound or a trifunctional polymerizable compound, and more preferably includes a bifunctional polymerizable compound.

As the polymerizable group of the polymerizable compound (A), ethylenically unsaturated bond-containing groups such as a vinyl group, an allyl group, a vinylphenyl group, a (meth)acryloyl group, a (meth)acryloyloxy group, and a (meth)acryloylamino group is preferable. The polymerizable group is preferably a (meth)acryloyl group, a (meth)acryloyloxy group, and a (meth)acryloylamino group, and more preferably an acryloyl group, an acryloyloxy group, and an acryloylamino group.

The polymerizable compound (A) is preferably a compound represented by Formula (2-A).

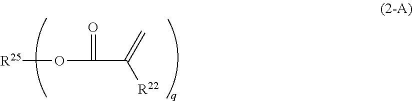

In the formula, R²⁵ is a q-valent organic group having an aromatic ring, R²² is a hydrogen atom or a methyl group, and q is an integer of 1 or greater. That is, in a case where q is 1, the polymerizable compound (A) is a monofunctional polymerizable compound, and in a case where q is 2 or greater, the polymerizable compound (A) is a polyfunctional polymerizable compound.

A molecular weight of the polymerizable compound (A) is preferably less than 2,000, more preferably 1,500 or less, and still more preferably 1,000 or less, and may be 800 or less, further 500 or less. The lower limit value thereof is preferably 100 or greater.

The polymerizable compound (A) may or may not contain a silicon atom. The polymerizable compound containing a silicon atom is, for example, a polymerizable compound having a silicone skeleton. Examples of the polymerizable compound having a silicone skeleton include SILICONE ACRYLATE X-22-1602 manufactured by Shin-Etsu Chemical Co., Ltd.

A content of the polymerizable compound (A) is preferably 40% to 90% by mass with respect to the entire composition for forming a pattern. The upper limit of this numerical range is more preferably 85% by mass or less and still more preferably 80% by mass or less. Moreover, the lower limit of the numerical range is more preferably 45% by mass or greater and still more preferably 50% by mass or greater.

The content of the polymerizable compound (A) is preferably 30% to 95% by mass with respect to the total polymerizable compound. The upper limit of the numerical range is more preferably 90% by mass or less, still more preferably 85% by mass or less, and particularly preferably 80% by mass or less. Moreover, the lower limit of the numerical range is more preferably 50% by mass or greater, still more preferably 60% by mass or greater, and particularly preferably 70% by mass or greater.

The composition for forming a pattern may contain only one kind or two or more kinds of the polymerizable compounds (A). In a case where two or more kinds thereof are contained, the total amount thereof is preferably within the above range.

<<<Polyfunctional Polymerizable Compound (A)>>>

The number of polymerizable groups of the polyfunctional polymerizable compound (A) is 2 or more, preferably 2 to 7, more preferably 2 to 4, still more preferably 2 or 3, and even more preferably 2.

The viscosity of the polyfunctional polymerizable compound (A) at 23° C. is preferably 200 mPa·s or lower, more preferably 150 mPa·s or lower, still more preferably 100 mPa·s or lower, and even more preferably 80 mPa·s or lower. By setting the viscosity of the polyfunctional polymerizable compound (A) at 23° C. to be equal to or lower than the upper limit value, the viscosity of components excluding a solvent from the composition for forming a pattern can be reduced, and thus filling properties is improved. The lower limit value thereof is not particularly specified, but can be, for example, 1 mPa·s or higher.

The polyfunctional polymerizable compound (A) preferably satisfies Formula (2-A) described above. By using such a compound, adhesiveness, releasability, and temporal stability in the imprinting are well-balanced, and thus the composition for forming a pattern is comprehensively superior to handle.

In a case where the polyfunctional polymerizable compound (A) satisfies Formula (2-A) described above, q is preferably an integer of 2 to 7, more preferably an integer of 2 to 4, still more preferably 2 or 3, and even more preferably 2.

R²⁵ is preferably a divalent to heptavalent organic group having an aromatic ring, more preferably a divalent to tetravalent organic group, still more preferably a divalent or trivalent organic group, and even more preferably a divalent organic group. R²⁵ is preferably a hydrocarbon group having an aromatic ring. The number of carbon atoms in the hydrocarbon group is preferably 2 to 20 and more preferably 2 to 10.

In a case where R²⁵ is a divalent organic group, R²⁵ is preferably an organic group represented by Formula (1-2-A).

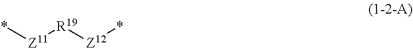

In the formula, it is preferable that Z¹¹ and Z¹² are each independently a single bond, —O—, -Alk-, or -Alk-O—. Alk represents an alkylene group (the number of carbon atoms is preferably 1 to 12, more preferably 1 to 6, and still more preferably 1 to 3), and may have a substituent as long as the effects of the present invention are not impaired, but it is preferable to be unsubstituted. Examples of the substituent include the following substituents T (excluding a group including a hydroxyl group). In the present specification, the asterisk in the chemical formula indicates a bonding site.

In the present specification, examples of the substituent T include one group selected from a halogen atom, a cyano group, a nitro group, a hydrocarbon group, a heteroaryl group, —ORt¹, —CORt¹, —COORt¹, —COCRt¹, —NRt¹Rt², —NHCORt¹, —CONRt¹Rt², —NHCONRt¹Rt², —NHCOORt¹, —SRt¹, —SO₂Rt¹, —SO₂ORt¹, —NHSO₂Rt¹, and —SO₂NRt¹Rt². Here, Rt¹ and Rt² each independently represent a hydrogen atom, a hydrocarbon group, or a heteroaryl group. In a case where Rt¹ and Rt² are hydrocarbon groups, Rt¹ and Rt² may be bonded to each other to form a ring.

Regarding the substituent T, examples of the halogen atom include a fluorine atom, a chlorine atom, a bromine atom, and an iodine atom. Examples of the hydrocarbon group include an alkyl group, an alkenyl group, an alkynyl group, and an aryl group. The number of carbon atoms in the alkyl group is preferably 1 to 10, more preferably 1 to 5, and still more preferably 1 or 2. The alkyl group may be linear, branched, or cyclic, and is preferably linear or branched. The number of carbon atoms in the alkenyl group is preferably 2 to 10, more preferably 2 to 5, and particularly preferably 2 or 3. The alkenyl group may be linear, branched, or cyclic, and is preferably linear or branched. The number of carbon atoms in the alkynyl group is preferably 2 to 10 and more preferably 2 to 5. The alkynyl group may be linear or branched, and is preferably linear or branched. The number of carbon atoms in the aryl group is preferably 6 to 10, more preferably 6 to 8, and still more preferably 6 or 7. The heteroaryl group may be a single ring or a polycyclic ring. The heteroaryl group is preferably a single ring or a polycyclic ring having 2 to 4 rings. The number of heteroatoms constituting a ring of the heteroaryl group is preferably 1 to 3. As the heteroatom constituting the ring of the heteroaryl group, a nitrogen atom, an oxygen atom, or a sulfur atom is preferable. The number of carbon atoms constituting the ring of the heteroaryl group is preferably 3 to 10, more preferably 3 to 8, and more preferably 3 to 5.

The hydrocarbon group and heteroaryl group as the substituent T may further have another substituent or may be unsubstituted. Examples of the other substituent here include the aforementioned substituents T.

As the substituent of Z¹¹ and Z¹², for example, a fluorine atom, a chlorine atom, a bromine atom, a methyl group, an ethyl group, a propyl group, a butyl group, a phenyl group, a naphthyl group, a thienyl group, or a furyl group is preferable, and a methyl group, an ethyl group, a propyl group, or a phenyl group is more preferable. Moreover, the phenyl group, naphthyl group, thienyl group, and furyl group may be bonded through an alkylene group having 1 to 3 carbon atoms.

R¹⁹ is a divalent linking group having an aromatic ring. The linking group is preferably a linking group selected from Formulae (10-1) to (10-9), or a combination thereof. Among them, R¹⁹ is more preferably a linking group of Formula (10-7).

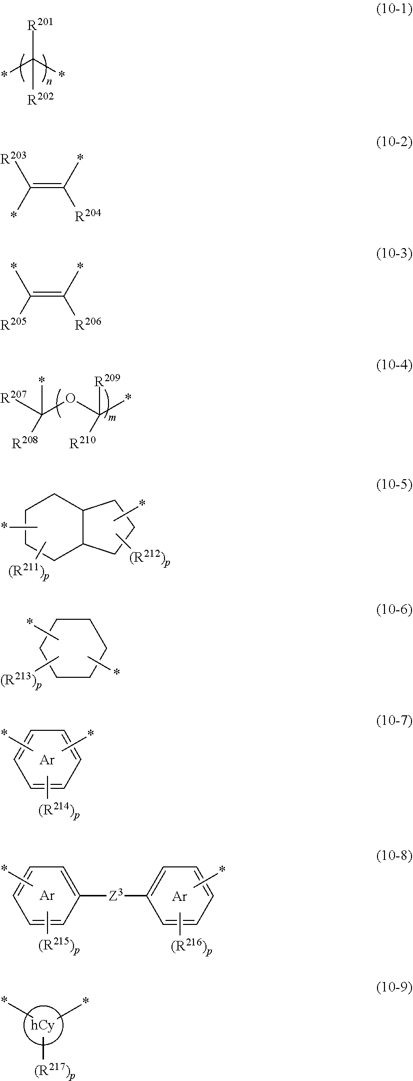

R²⁰¹ to R²¹⁷ are optional substituents. However, at least one of R²⁰¹ or R²⁰², at least one of R²⁰³ or R²⁰⁴, at least one of R²⁰⁵ or R²⁰⁶, at least one of R²⁰⁷, R²⁰⁸, R²⁰⁹, or R²¹⁰, at least one of R²¹¹ or R²¹², and R²¹³ is a group having an aromatic ring. As these substituents, each independently, for example, an alkyl group (the number of carbon atoms is preferably 1 to 12, more preferably 1 to 6, and still more preferably 1 to 3), an arylalkyl group (the number of carbon atoms is preferably 7 to 21, more preferably 7 to 15, and still more preferably 7 to 11), an aryl group (the number of carbon atoms is preferably 6 to 22, more preferably 6 to 18, and still more preferably 6 to 10), a thienyl group, a furyl group, a (meth)acryloyl group, a (meth)acryloyloxy group, or a (meth)acryloyloxyalkyl group (the number of carbon atoms in the alkyl group is preferably 1 to 24, more preferably 1 to 12, and still more preferably 1 to 6) is preferable. R²⁰¹ and R²⁰², R²⁰³ and R²⁰⁴, R²⁰⁵ and R²⁰⁶, R²⁰⁷ and R²⁰⁸, R²⁰⁹ and R²¹⁰, a plurality of R²¹¹'s, a plurality of R²¹²'s, a plurality of R²¹³'s, a plurality of R²¹⁴'s, a plurality of R²¹⁵'s, s a plurality of R²¹⁶'s, and a plurality of R²¹⁷'s may be respectively bonded to each other to form a ring.

Ar is an arylene group (the number of carbon atoms is preferably 6 to 22, more preferably 6 to 18, and still more preferably 6 to 10), and specific examples thereof include a phenylene group, a naphthalenediyl group, an anthracenediyl group, a phenanthrenediyl group, and a fluorenediyl group.

hCy is a heteroaryl group (the number of carbon atoms is preferably 1 to 12, more preferably 1 to 6, and still more preferably 2 to 5), and is more preferably a 5-membered ring or a 6-membered ring. Specific examples of a hetero ring constituting hCy include a thiophene ring, a furan ring, a dibenzofuran ring, a carbazole ring, an indole ring, a tetrahydropyran ring, a tetrahydrofuran ring, a pyrrole ring, a pyridine ring, a pyrazole ring, an imidazole ring, a benzimidazole ring, a triazole ring, a thiazole ring, an oxazole ring, a pyrrolidone ring, and a morpholine ring, and among them, a thiophene ring, a furan ring, and a dibenzofuran ring are preferable.

Z³ is a single bond or a linking group. Examples of the linking group include alkylene groups (the number of carbon atoms is preferably 1 to 12, more preferably 1 to 6, and still more preferably 1 to 3) in which an oxygen atom, a sulfur atom, and a fluorine atom may be substituted.

n and m are each a natural number of 100 or less, and are each preferably 1 to 12, more preferably 1 to 6, and still more preferably 1 to 3.

p is 0 or greater and is an integer equal to or less than the maximum number of groups which can be substituted for each ring. In the respective cases, the upper limit values are independently preferably equal to or less than half of the maximum number of the substitutable group, more preferably 4 or less, and still more preferably 2 or less.

The polyfunctional polymerizable compound (A) is preferably represented by Formula (2-1-A).

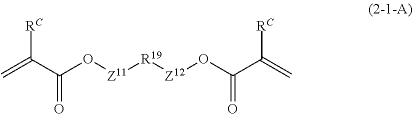

In Formula (2-1-A), R^{C} is a hydrogen atom or a methyl group. Moreover, R¹⁹, Z¹¹, and Z¹² have the same definitions as R¹⁹, Z¹¹, and Z¹² in Formula (1-2-A), respectively, and preferred ranges thereof are also the same.

A kind of an atom constituting the polyfunctional polymerizable compound (A) used in the present invention is not particularly specified, but the polyfunctional polymerizable compound (A) is preferably constituted of only atoms selected from a carbon atom, an oxygen atom, a hydrogen atom, and a halogen atom, and more preferably constituted of only atoms selected from a carbon atom, an oxygen atom, and a hydrogen atom.

Examples of the polyfunctional polymerizable compound (A) preferably used in the present invention include the following compounds. Moreover, polymerizable compounds described in JP2014-170949A can also be used, the contents of which are incorporated in the present specification.

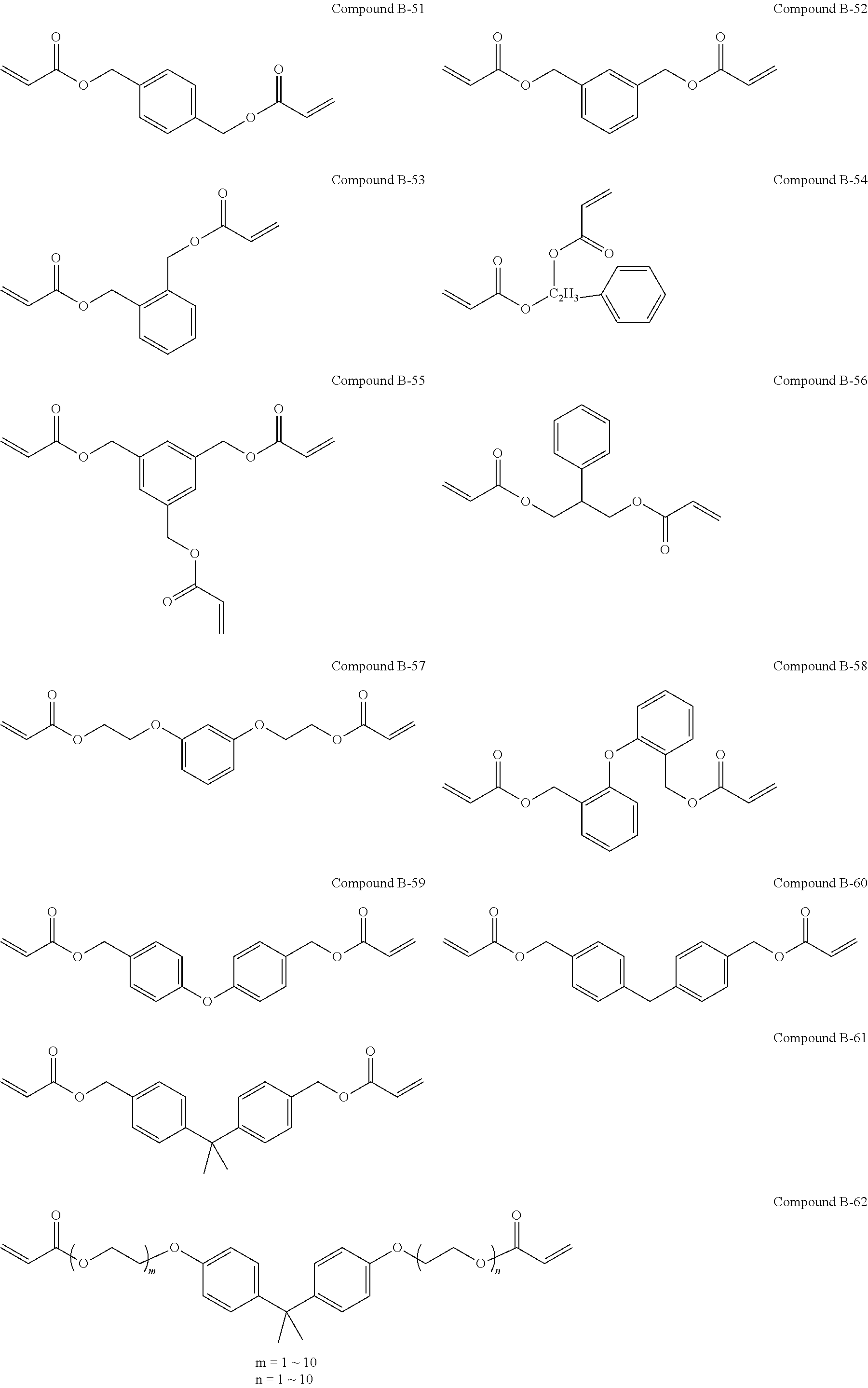

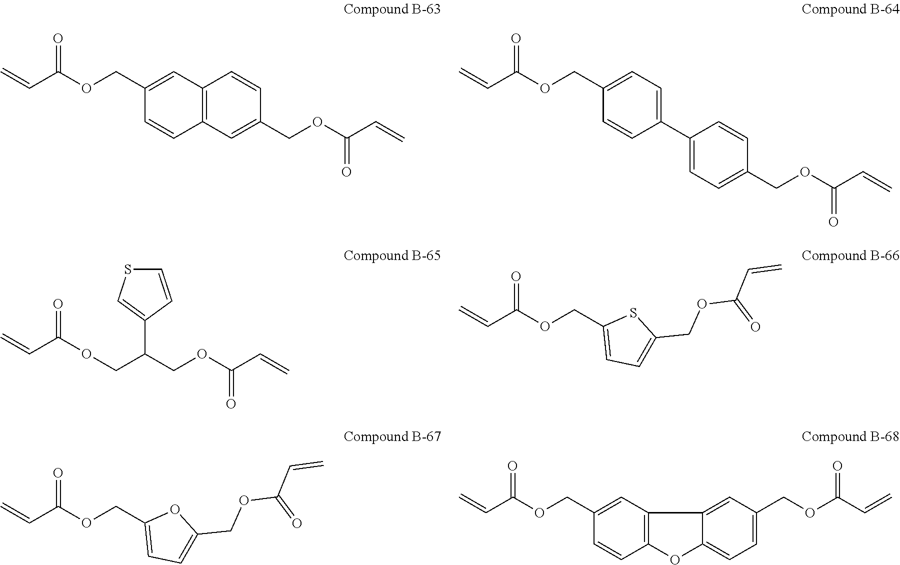 [SMILES: C=CC(=O)OCc1ccc2cc(COC(=O)C=C)ccc2c1 ; C=CC(=O)OCc1ccc(-c2ccc(COC(=O)C=C)cc2)cc1 ; C=CC(=O)OCC(COC(=O)C=C)c1ccsc1 ; C=CC(=O)OCc1ccc(COC(=O)C=C)s1 ; C=CC(=O)OCc1ccc(COC(=O)C=C)o1 ; C=CC(=O)OCc1ccc2oc3ccc(COC(=O)C=C)cc3c2c1]

A content of the polyfunctional polymerizable compound (A) is preferably 20% to 60% by mass with respect to the entire composition for forming a pattern. The upper limit of the numerical range is more preferably 55% by mass or less, still more preferably 50% by mass or less, and particularly preferably 45% by mass or less. Moreover, the lower limit of the numerical range is more preferably 25% by mass or greater, still more preferably 30% by mass or greater, and particularly preferably 35% by mass or greater.

The content of the polyfunctional polymerizable compound (A) is preferably 25% to 65% by mass with respect to the total polymerizable compound. The upper limit of the numerical range is more preferably 60% by mass or less, still more preferably 55% by mass or less, and particularly preferably 50% by mass or less. Moreover, the lower limit of the numerical range is more preferably 30% by mass or greater, still more preferably 35% by mass or greater, and particularly preferably 40% by mass or greater.

The composition for forming a pattern may contain only one kind or two or more kinds of the polyfunctional polymerizable compounds (A). In a case where two or more kinds thereof are contained, the total amount thereof is preferably within the above range.

<<<Monofunctional Polymerizable Compound (A)>>>

The monofunctional polymerizable compound (A) which can be used in the present invention is preferably liquid at 23° C. In the present invention, the compound which is liquid at 23° C. means a compound having fluidity at 23° C., for example, a compound having a viscosity at 23° C. of 100,000 mPa·s or lower. By using, as the monofunctional polymerizable compound (A), a compound which is a liquid at 23° C., an amount of solvent used in the composition for forming a pattern can be reduced.

The viscosity of the monofunctional polymerizable compound (A) at 23° C. is preferably 100 mPa·s or lower, more preferably 10 mPa·s or lower, still more preferably 8 mPa·s or lower, and even more preferably 6 mPa·s or lower. By setting the viscosity of the monofunctional polymerizable compound (A) at 23° C. to be equal to or lower than the upper limit value, the viscosity of components excluding a solvent from the composition for forming a pattern can be reduced, and thus filling properties is improved. The lower limit value thereof is not particularly specified, but can be, for example, 1 mPa·s or higher.

The monofunctional polymerizable compound (A) is preferably a monofunctional (meth)acrylic monomer. Moreover, the monofunctional polymerizable compound (A) is more preferably a monofunctional (meth)acrylate in which q in Formula (2-A) described above is 1, and still more preferably a monofunctional acrylate in which R²² is a hydrogen atom.

A kind of an atom constituting the monofunctional polymerizable compound (A) is not particularly specified, but the monofunctional polymerizable compound (A) is preferably constituted of only atoms selected from a carbon atom, an oxygen atom, a hydrogen atom, and a halogen atom, and more preferably constituted of only atoms selected from a carbon atom, an oxygen atom, and a hydrogen atom.

The monofunctional polymerizable compound (A) preferably has a plastic structure. For example, it is preferable that at least one kind of the monofunctional polymerizable compound (A) includes the following group (1-A).

(1-A) Group (hereinafter, also simply referred to as a group (1-A)″) containing at least one of an alkyl chain or an alkenyl chain, containing an aromatic ring, and having the total number of carbon atoms of 7 or more

With such a configuration, a modulus of elasticity of a cured film can be efficiently reduced while reducing the addition amount of the monofunctional polymerizable compound (A) contained in the composition for forming a pattern. Moreover, interfacial energy with the mold is reduced, and thus an effect of reducing a releasing force (effect of improving releasability) can be enhanced.

In the group (1-A), the alkyl chain and the alkenyl chain may be linear, branched, or cyclic, and is preferably linear or branched. Moreover, it is preferable that the group (1-A) has the alkyl chain and/or the alkenyl chain at a terminal of the monofunctional polymerizable compound (A), that is, have an alkyl group and/or an alkenyl group. With such a structure, the releasability can be further improved.

The alkyl chain and the alkenyl chain may each independently contain an ether group (—O—) in the chain, but it is preferable that an ether group is not contained from the viewpoint of improvement in the releasability.

The total number of carbon atoms in the group (1-A) is preferably 35 or less and more preferably 10 or less.

As the aromatic ring in the group (1-A), a single ring or a polycyclic ring having 3 to 8 members is preferable, and a single ring is preferable. The number of rings constituting the polycyclic ring is preferably 2 or 3. The aromatic ring is preferably a 6-membered ring. As the aromatic ring in the group (1-A), a benzene ring or a naphthalene ring is preferable, and a benzene ring is particularly preferable.

The monofunctional polymerizable compound (A) used in the present invention is preferably a compound in which the group (1-A) is bonded to a polymerizable group directly or through a linking group, and more preferably a compound in which the group (1-A) is directly bonded to a polymerizable group. Examples of the linking group include —O—, —C(═O)—, —CH₂—, —NH—, or a combination thereof. Moreover, the monofunctional polymerizable compound (A) preferably has the above-described group (1-A) as R²⁵ in Formula (2-A) described above.

Specific examples of the monofunctional polymerizable compound (A) are as follows. However, in the present invention, the monofunctional polymerizable compound (A) is not limited to the following compounds. For example, polymerizable compounds described in JP2014-170949A can also be used, the contents of which are incorporated in the present specification.

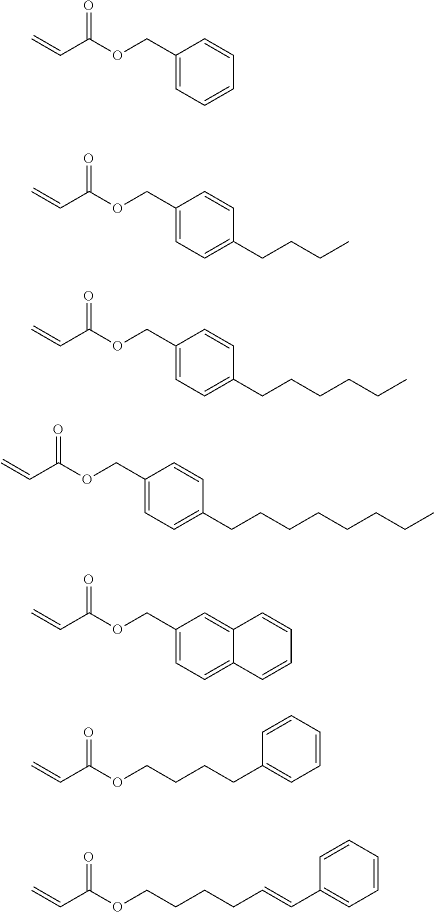

A content of the monofunctional polymerizable compound (A) is preferably 0% to 50% by mass with respect to the entire composition for forming a pattern. The upper limit of the numerical range is more preferably 45% by mass or less, still more preferably 40% by mass or less, and particularly preferably 35% by mass or less. Moreover, the lower limit of the numerical range is more preferably 5% by mass or greater, still more preferably 15% by mass or greater, and particularly preferably 20% by mass or greater.

The content of the monofunctional polymerizable compound (A) is preferably 0% to 55% by mass with respect to the total polymerizable compound. The upper limit of the numerical range is more preferably 50% by mass or less, still more preferably 45% by mass or less, and particularly preferably 40% by mass or less. Moreover, the lower limit of the numerical range is more preferably 10% by mass or greater, still more preferably 20% by mass or greater, and particularly preferably 25% by mass or greater.

The composition for forming a pattern may contain only one kind or two or more kinds of the monofunctional polymerizable compounds (A). In a case where two or more kinds thereof are contained, the total amount thereof is preferably within the above range.

<<Other Polymerizable Compound>>

The composition for forming a pattern according to the embodiment of the present invention can contain a polymerizable compound (hereinafter, simply referred to as an “other polymerizable compound”) other than the polymerizable compound (A), such as a polymerizable compound not containing an aromatic ring and a polymerizable compound containing a hydroxyl group. Consequently, it is easy to adjust the viscosity of components excluding the solvent from the composition for forming a pattern and the viscosity of solid content in the composition.

The other polymerizable compound may have an aromatic ring. The aromatic ring of the other polymerizable compound may be a single ring or a polycyclic ring, and in a case of a polycyclic ring, a plurality of rings may be condensed. Other than that, the aromatic ring is the same as the aromatic ring of the polymerizable compound (A), and for example, a benzene ring, a naphthalene ring, an anthracene ring, a phenanthrene ring, a fluorene ring, or the like is preferable, a benzene ring or a naphthalene ring is more preferable, and a benzene ring is still more preferable.

In the present invention, it is assumed that the case where the above-described other polymerizable compound has an aromatic ring is a case where the other polymerizable compound has a hydroxyl group at the same time. However, as described above, from the viewpoint of suppressing the attachment of the polymerizable compound to the surface of the mold, it is preferable that the other polymerizable compound does not contain a hydroxyl group. Therefore, in the composition for forming a pattern according to the embodiment of the present invention, a content of the polymerizable compound containing a hydroxyl group is preferably 5% by mass or less, more preferably 1% by mass or less, still more preferably 0.5% by mass or less, and particularly preferably 0.1% by mass with respect to the total content of the polymerizable compound. The lower limit of this content is preferably 0, and may be approximately 0.05% by mass. Moreover, a content of the polymerizable compound which contains a hydroxyl group and contains an aromatic ring is preferably 5% by mass or less, more preferably 1% by mass or less, still more preferably 0.5% by mass or less, and particularly preferably 0.1% by mass with respect to the total content of the polymerizable compound. The lower limit of this content is preferably 0, and may be approximately 0.05% by mass. Moreover, a content of the polymerizable compound which contains a hydroxyl group and does not contain an aromatic ring is preferably 5% by mass or less, more preferably 1% by mass or less, still more preferably 0.5% by mass or less, and particularly preferably 0.1% by mass with respect to the total content of the polymerizable compound. The lower limit of this content is preferably 0, and may be approximately 0.05% by mass.

The other polymerizable compound may be a monofunctional polymerizable compound having one polymerizable group, or a polyfunctional polymerizable compound having two or more polymerizable groups. In the present invention, the composition for forming a pattern may have an aspect in which an other polyfunctional polymerizable compound is included, or may be an aspect in which both an other polyfunctional polymerizable compound and an other monofunctional polymerizable compound are included. The other polyfunctional polymerizable compound preferably includes at least one kind of a bifunctional polymerizable compound or a trifunctional polymerizable compound, and more preferably includes a bifunctional polymerizable compound.

As the polymerizable group of the other polymerizable compound, ethylenically unsaturated bond-containing groups such as a vinyl group, an allyl group, a vinylphenyl group, a (meth)acryloyl group, a (meth)acryloyloxy group, and a (meth)acryloylamino group is preferable. The polymerizable group is preferably a (meth)acryloyl group, a (meth)acryloyloxy group, and a (meth)acryloylamino group, and more preferably an acryloyl group, an acryloyloxy group, and an acryloylamino group.

The other polymerizable compound is preferably a compound represented by Formula (2).

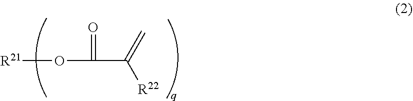

In the formula, R²¹ is a q-valent organic group, R²² is a hydrogen atom or a methyl group, and q is an integer of 1 or greater. That is, in a case where q is 1, the other polymerizable compound is a monofunctional polymerizable compound, and in a case where q is 2 or greater, the other polymerizable compound is a polyfunctional polymerizable compound.

A molecular weight of the other polymerizable compound is preferably less than 2,000, more preferably 1,500 or less, and still more preferably 1,000 or less, and may be 800 or less, further 500 or less. The lower limit value thereof is preferably 100 or greater.

The other polymerizable compound may or may not contain a silicon atom. The polymerizable compound containing a silicon atom is, for example, a polymerizable compound having a silicone skeleton. Examples of the polymerizable compound having a silicone skeleton include SILICONE ACRYLATE X-22-1602 manufactured by Shin-Etsu Chemical Co., Ltd.

A content of the other polymerizable compound is preferably 5% to 70% by mass with respect to the entire composition for forming a pattern. The upper limit of the numerical range is more preferably 50% by mass or less, still more preferably 40% by mass or less, and particularly preferably 30% by mass or less. Moreover, the lower limit of the numerical range is more preferably 10% by mass or greater, still more preferably 15% by mass or greater, and particularly preferably 18% by mass or greater.

The content of the other polymerizable compound is preferably 30% to 95% by mass with respect to the total polymerizable compound. The upper limit of the numerical range is more preferably 90% by mass or less, still more preferably 85% by mass or less, and particularly preferably 80% by mass or less. Moreover, the lower limit of the numerical range is more preferably 50% by mass or greater, still more preferably 60% by mass or greater, and particularly preferably 70% by mass or greater.

The composition for forming a pattern may contain only one kind or two or more kinds of the other polymerizable compounds. In a case where two or more kinds thereof are contained, the total amount thereof is preferably within the above range.

<<<Other Polyfunctional Polymerizable Compound>>>

The number of polymerizable groups of other polyfunctional polymerizable compound is 2 or more, preferably 2 to 7, more preferably 2 to 4, still more preferably 2 or 3, and even more preferably 2.

The viscosity of the other polyfunctional polymerizable compound at 23° C. is preferably 200 mPa·s or lower, more preferably 150 mPa·s or lower, still more preferably 100 mPa·s or lower, and even more preferably 80 mPa·s or lower. By setting the viscosity of the other polyfunctional polymerizable compound at 23° C. to be equal to or lower than the upper limit value, the viscosity of components excluding a solvent from the composition for forming a pattern can be reduced, and thus filling properties is improved. The lower limit value thereof is not particularly specified, but can be, for example, 1 mPa·s or higher.

The other polyfunctional polymerizable compound preferably satisfies Formula (2) described above. By using such a compound, adhesiveness, releasability, and temporal stability in the imprinting are well-balanced, and thus the composition for forming a pattern is comprehensively superior to handle.

In a case where the other polyfunctional polymerizable compound satisfies Formula (2) described above, q is preferably an integer of 2 to 7, more preferably an integer of 2 to 4, still more preferably 2 or 3, and even more preferably 2.

R²¹ is preferably a divalent to heptavalent organic group, more preferably a divalent to tetravalent organic group, still more preferably a divalent or trivalent organic group, and even more preferably a divalent organic group. R²¹ is preferably a hydrocarbon group. The number of carbon atoms in the hydrocarbon group is preferably 2 to 20 and more preferably 2 to 10.

In a case where R²¹ is a divalent organic group, R²¹ is preferably an organic group represented by Formula (1-2).

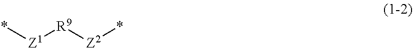

In the formula, it is preferable that Z¹ and Z² are each independently a single bond, —O—, -Alk-, or -Alk-O—. Alk represents an alkylene group (the number of carbon atoms is preferably 1 to 12, more preferably 1 to 6, and still more preferably 1 to 3), and may have a substituent as long as the effects of the present invention are not impaired, but it is preferable to be unsubstituted. Examples of the substituent include the above-described substituents T.

As the substituent of Z¹ and Z², for example, a fluorine atom, a chlorine atom, a bromine atom, a methyl group, an ethyl group, a propyl group, a butyl group, a phenyl group, a naphthyl group, a thienyl group, or a furyl group is preferable, and a methyl group, an ethyl group, a propyl group, or a phenyl group is preferable. Moreover, the phenyl group, naphthyl group, thienyl group, and furyl group may be bonded through an alkylene group having 1 to 3 carbon atoms.

R⁹ is a divalent linking group. The linking group is preferably a linking group selected from Formulae (9-1) to (9-10), or a combination thereof. Among them, a linking group selected from Formulae (9-1) to (9-3), (9-7), and (9-8) is preferable.

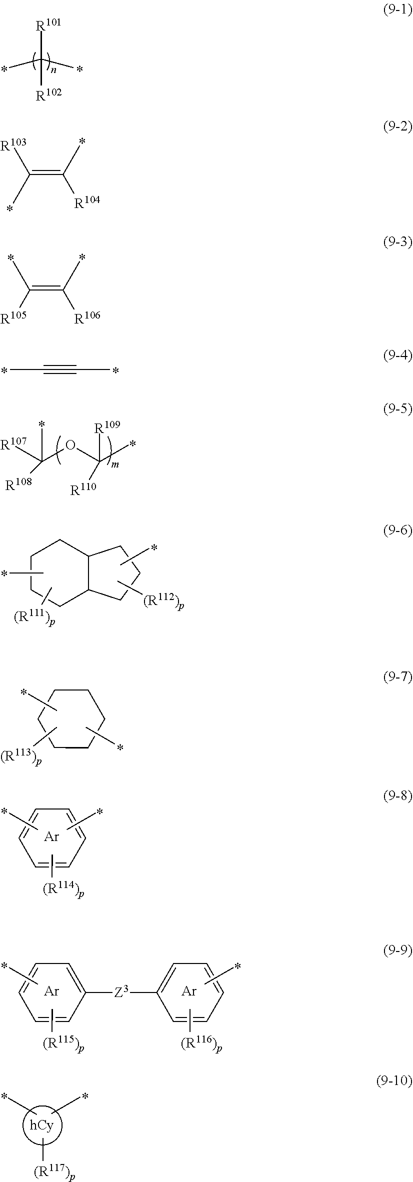

R¹⁰¹ to R¹¹⁷ are optional substituents. As each of these substituents, for example, an alkyl group (the number of carbon atoms is preferably 1 to 12, more preferably 1 to 6, and still more preferably 1 to 3), an arylalkyl group (the number of carbon atoms is preferably 7 to 21, more preferably 7 to 15, and still more preferably 7 to 11), an aryl group (the number of carbon atoms is preferably 6 to 22, more preferably 6 to 18, and still more preferably 6 to 10), a thienyl group, a furyl group, a (meth)acryloyl group, a (meth)acryloyloxy group, or a (meth)acryloyloxyalkyl group (the number of carbon atoms in the alkyl group is preferably 1 to 24, more preferably 1 to 12, and still more preferably 1 to 6) is preferable. R¹⁰¹ and R₁₀₂, R¹⁰³ and R¹⁰⁴, R¹⁰⁵ and R¹⁰⁶, R¹⁰⁷ and R¹⁰⁸, R¹⁰⁹ and R¹¹⁰, a plurality of R¹¹¹'s, a plurality of R¹¹²'s, a plurality of R¹¹³'s, a plurality of R¹¹⁴'s, a plurality of R¹¹⁵'s, a plurality of R¹¹⁶'s, and a plurality of R¹¹⁷'s may be respectively bonded to each other to form a ring.

Ar is an arylene group (the number of carbon atoms is preferably 6 to 22, more preferably 6 to 18, and still more preferably 6 to 10), and specific examples thereof include a phenylene group, a naphthalenediyl group, an anthracenediyl group, a phenanthrenediyl group, and a fluorenediyl group.

hCy is a heteroaryl group (the number of carbon atoms is preferably 1 to 12, more preferably 1 to 6, and still more preferably 2 to 5), and is more preferably a 5-membered ring or a 6-membered ring. Specific examples of a hetero ring constituting hCy include a thiophene ring, a furan ring, a dibenzofuran ring, a carbazole ring, an indole ring, a tetrahydropyran ring, a tetrahydrofuran ring, a pyrrole ring, a pyridine ring, a pyrazole ring, an imidazole ring, a benzimidazole ring, a triazole ring, a thiazole ring, an oxazole ring, a pyrrolidone ring, and a morpholine ring, and among them, a thiophene ring, a furan ring, and a dibenzofuran ring are preferable.

Z³ is a single bond or a linking group. Examples of the linking group include alkylene groups (the number of carbon atoms is preferably 1 to 12, more preferably 1 to 6, and still more preferably 1 to 3) in which an oxygen atom, a sulfur atom, and a fluorine atom may be substituted.

n and m are each a natural number of 100 or less, and are each preferably 1 to 12, more preferably 1 to 6, and still more preferably 1 to 3.

p is 0 or greater and is an integer equal to or less than the maximum number of groups which can be substituted for each ring. In the respective cases, the upper limit values are independently preferably equal to or less than half of the maximum number of the substitutable group, more preferably 4 or less, and still more preferably 2 or less.

The other polyfunctional polymerizable compound is preferably represented by Formula (2-1).

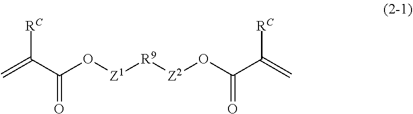

In Formula (2-1), R^{C} is a hydrogen atom or a methyl group. Moreover, R⁹, Z¹, and Z² have the same definitions as R⁹, Z¹, and Z² in Formula (1-2), respectively, and preferred ranges thereof are also the same.

A kind of an atom constituting the other polyfunctional polymerizable compound used in the present invention is not particularly specified, but the other polyfunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

Examples of the other polyfunctional polymerizable compound preferably used in the present invention include the following compounds. Moreover, polymerizable compounds described in JP2014-170949A can also be used, the contents of which are incorporated in the present specification.

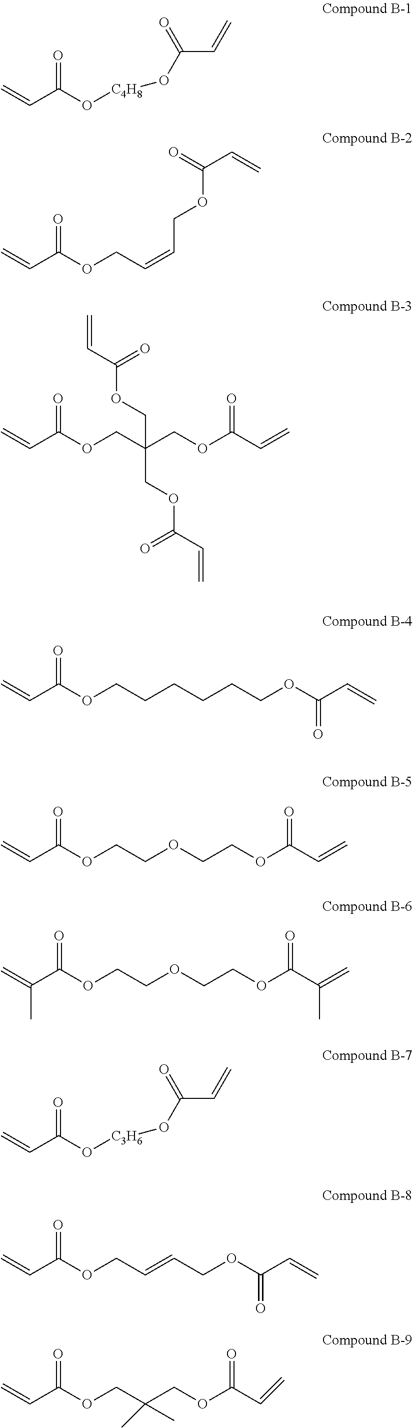

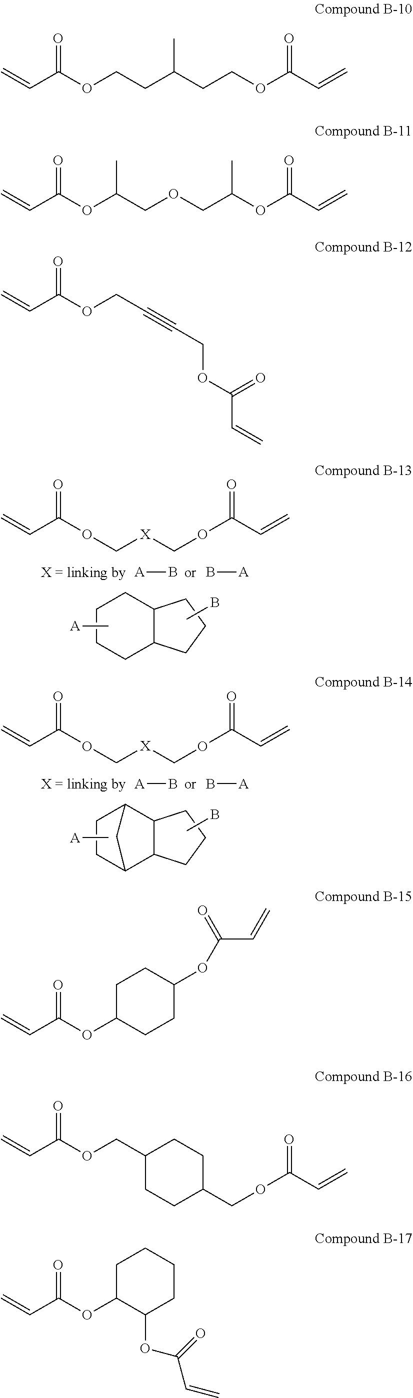

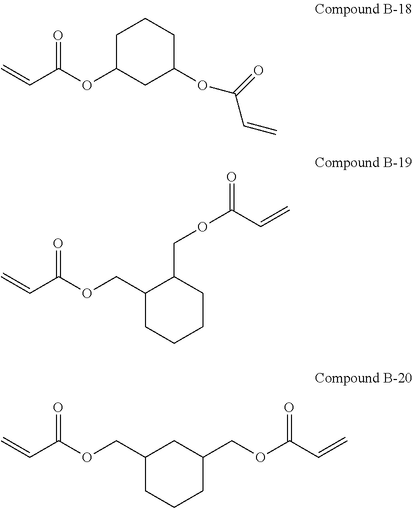

A content of the other polyfunctional polymerizable compound is preferably 0% to 50% by mass with respect to the entire composition for forming a pattern. The upper limit of the numerical range is more preferably 45% by mass or less, still more preferably 40% by mass or less, and particularly preferably 35% by mass or less. Moreover, the lower limit of the numerical range may be 5% by mass or greater, or 10% by mass or greater.

The content of the other polyfunctional polymerizable compound is preferably 0% to 55% by mass with respect to the total polymerizable compound. The upper limit of the numerical range is more preferably 50% by mass or less, still more preferably 45% by mass or less, and particularly preferably 40% by mass or less. Moreover, the lower limit of the numerical range may be 5% by mass or greater, or 10% by mass or greater.

The composition for forming a pattern may contain only one kind or two or more kinds of the other polyfunctional polymerizable compounds. In a case where two or more kinds thereof are contained, the total amount thereof is preferably within the above range.

<<<Other Monofunctional Polymerizable Compound>>>

The other monofunctional polymerizable compound which can be used in the present invention is preferably liquid at 23° C. By using, as the other monofunctional polymerizable compound, a compound which is a liquid at 23° C., an amount of solvent used in the composition for forming a pattern can be reduced.

The viscosity of the other monofunctional polymerizable compound at 23° C. is preferably 100 mPa·s or lower, more preferably 10 mPa·s or lower, still more preferably 8 mPa·s or lower, and even more preferably 6 mPa·s or lower. By setting the viscosity of the other monofunctional polymerizable compound at 23° C. to be equal to or lower than the upper limit value, the viscosity of components excluding a solvent from the composition for forming a pattern can be reduced, and thus filling properties is improved. The lower limit value thereof is not particularly specified, but can be, for example, 1 mPa·s or higher.

The other monofunctional polymerizable compound is preferably a monofunctional (meth)acrylic monomer. Moreover, the other monofunctional polymerizable compound is more preferably a monofunctional (meth)acrylate in which q in Formula (2) described above is 1, and still more preferably a monofunctional acrylate in which R²² is a hydrogen atom.

A kind of an atom constituting the other monofunctional polymerizable compound is not particularly specified, but the monofunctional polymerizable compound is preferably constituted of only atoms selected from a carbon atom, an oxygen atom, a hydrogen atom, and a halogen atom, and more preferably constituted of only atoms selected from a carbon atom, an oxygen atom, and a hydrogen atom.

The other monofunctional polymerizable compound preferably has a plastic structure. For example, it is preferable that at least one kind of the other monofunctional polymerizable compounds contains one group selected from the group consisting of the following (1) to (3).

(1) Group (hereinafter, referred to as a “group (1)” in some cases) which has at least one of an alkyl chain or an alkenyl chain and at least one of an alicyclic ring structure or an aromatic ring structure, and has the total number of carbon atoms of 7 or more

(2) Group (hereinafter, referred to as a “group (2)” in some cases) containing an alkyl chain having 4 or more carbon atoms

(3) Group (hereinafter, referred to as a “group (3)” in some cases) containing an alkenyl chain having 4 or more carbon atoms

With such a configuration, a modulus of elasticity of a cured film can be efficiently reduced while reducing the addition amount of the other monofunctional polymerizable compound contained in the composition for forming a pattern. Moreover, interfacial energy with the mold is reduced, and thus an effect of reducing a releasing force (effect of improving releasability) can be enhanced.

In the groups (1) to (3), the alkyl chain and the alkenyl chain may be linear, branched, or cyclic, and are each independently preferably linear or branched. Moreover, it is preferable that the groups (1) to (3) have the alkyl chain and/or the alkenyl chain at a terminal of the monofunctional polymerizable compound, that is, have an alkyl group and/or an alkenyl group. With such a structure, the releasability can be further improved.

The alkyl chain and the alkenyl chain may each independently contain an ether group (—O—) in the chain, but it is preferable that an ether group is not contained from the viewpoint of improvement in the releasability.

Group (1)

The total number of carbon atoms in the group (1) is preferably 35 or less and more preferably 10 or less.

As the cyclic structure, a single ring or a polycyclic ring of 3- to 8-membered rings is preferable. The number of rings constituting the polycyclic ring is preferably 2 or 3. The cyclic structure is more preferably a 5-membered ring or a 6-membered ring and still more preferably a 6-membered ring. Moreover, a single ring is more preferable. As the cyclic structure in the group (1), a cyclohexane ring, a benzene ring, and a naphthalene ring are more preferable, and a benzene ring is particularly preferable. Moreover, the cyclic structure is preferably an aromatic ring structure.

The number of cyclic structures in the group (1) may be 1 or may be 2 or more, but is preferably 1 or 2 and more preferably 1.

Group (2)

The group (2) is a group containing an alkyl chain having 4 or more carbon atoms, and preferably a group (that is, an alkyl group) consisting of an alkyl chain having 4 or more carbon atoms. The number of carbon atoms in the alkyl chain is preferably 7 or more and more preferably 9 or more. The upper limit value of the number of carbon atoms in the alkyl chain is not particularly limited, but can be, for example, 25 or less. Moreover, a compound in which some carbon atoms of the alkyl chain are substituted with silicon atoms can also be exemplified as the other monofunctional polymerizable compound.

Group (3)

The group (3) is a group containing an alkenyl chain having 4 or more carbon atoms, and preferably a group (that is, an alkylene group) consisting of an alkenyl chain having 4 or more carbon atoms. The number of carbon atoms in the alkenyl chain is preferably 7 or more and more preferably 9 or more. The upper limit value of the number of carbon atoms in the alkenyl chain is not particularly limited, but can be, for example, 25 or less.

In the present invention, the other monofunctional polymerizable compound is preferably a compound in which any one or more of the group (1), (2), or (3) are bonded to a polymerizable group directly or through a linking group, and more preferably a compound in which any one of the group (1), (2), or (3) is directly bonded to a polymerizable group. Examples of the linking group include —O—, —C(═O)—, —CH₂—, —NH—, or a combination thereof. Moreover, the other monofunctional polymerizable compound preferably has any one or more of the above-described group (1), (2), or (3) as R²¹ in Formula (2) described above.

Specific examples of the other monofunctional polymerizable compound are as follows. However, in the present invention, the other monofunctional polymerizable compound is not limited to the following compounds. For example, polymerizable compounds described in JP2014-170949A can also be used, the contents of which are incorporated in the present specification.

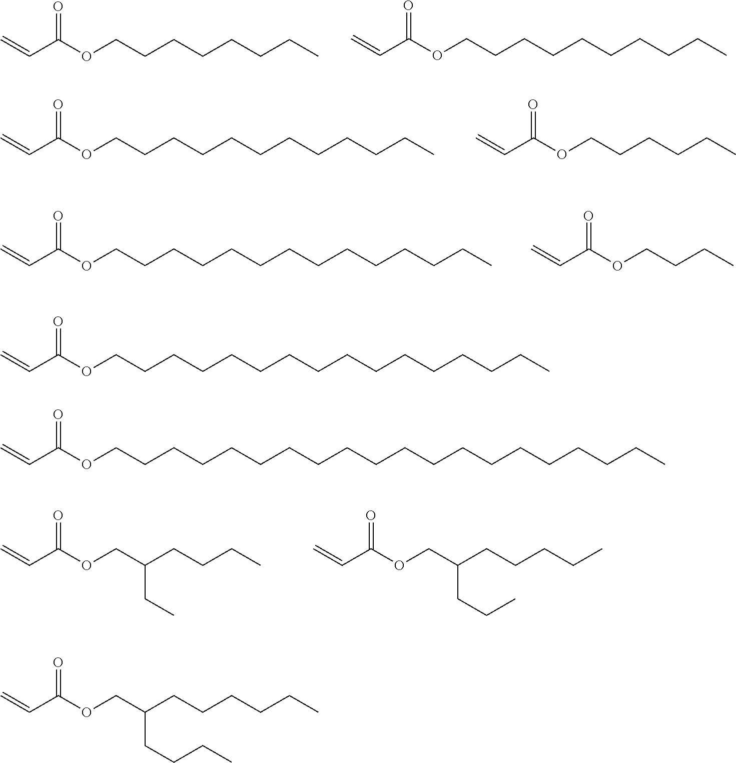

A content of the other monofunctional polymerizable compound is preferably 5% to 40% by mass with respect to the entire composition for forming a pattern. The upper limit of the numerical range is more preferably 35% by mass or less, still more preferably 30% by mass or less, and particularly preferably 25% by mass or less. Moreover, the lower limit of the numerical range is more preferably 10% by mass or greater, still more preferably 15% by mass or greater, and particularly preferably 25% by mass or greater.

The content of the other monofunctional polymerizable compound is preferably 10% to 40% by mass with respect to the total polymerizable compound. The upper limit of the numerical range is more preferably 35% by mass or less, still more preferably 32.5% by mass or less, and particularly preferably 30% by mass or less. Moreover, the lower limit of the numerical range is more preferably 10% by mass or greater, still more preferably 15% by mass or greater, and particularly preferably 20% by mass or greater.

The composition for forming a pattern may contain only one kind or two or more kinds of the other monofunctional polymerizable compounds. In a case where two or more kinds thereof are contained, the total amount thereof is preferably within the above range.

<<Total Polymerizable Compound>>

In the composition for forming a pattern according to the embodiment of the present invention, the total polymerizable compound which is the total of the above-described polymerizable compound (A) and the above-described other polymerizable compound may be consist of only the polyfunctional polymerizable compound or only the monofunctional polymerizable compound, but it is preferable to contain both the polyfunctional polymerizable compound and the monofunctional polymerizable compound.

A content of the polyfunctional polymerizable compound in the total polymerizable compound is preferably 25% to 90% by mass with respect to the entire composition for forming a pattern. The upper limit of this numerical range is more preferably 80% by mass or less, still more preferably 70% by mass or less, particularly preferably 60% by mass or less, and even more preferably 50% by mass or less. Moreover, the lower limit of the numerical range is more preferably 30% by mass or greater, still more preferably 35% by mass or greater, and particularly preferably 40% by mass or greater.

The content of the polyfunctional polymerizable compound in the total polymerizable compound is preferably 25% to 90% by mass with respect to the total polymerizable compound. The upper limit of this numerical range is more preferably 80% by mass or less, still more preferably 70% by mass or less, particularly preferably 60% by mass or less, and even more preferably 50% by mass or less. Moreover, the lower limit of the numerical range is more preferably 30% by mass or greater, still more preferably 35% by mass or greater, and particularly preferably 40% by mass or greater.

A content of the monofunctional polymerizable compound in the total polymerizable compound is preferably 5% to 70% by mass with respect to the entire composition for forming a pattern. The upper limit of the numerical range is more preferably 65% by mass or less, still more preferably 60% by mass or less, and particularly preferably 55% by mass or less. Moreover, the lower limit of this numerical range is more preferably 10% by mass or greater, still more preferably 30% by mass or greater, particularly preferably 40% by mass or greater, and even more preferably 45% by mass or greater.

The content of the monofunctional polymerizable compound in the total polymerizable compound is preferably 5% to 70% by mass with respect to the total polymerizable compound. The upper limit of the numerical range is more preferably 65% by mass or less, still more preferably 60% by mass or less, and particularly preferably 55% by mass or less. Moreover, the lower limit of this numerical range is more preferably 10% by mass or greater, still more preferably 30% by mass or greater, particularly preferably 40% by mass or greater, and even more preferably 45% by mass or greater.

The composition for forming a pattern according to the embodiment of the present invention may contain only one kind or two or more kinds of various polymerizable compounds. In a case where two or more kinds thereof are contained, the total amount thereof is preferably within the above range.

In the total polymerizable compound, in a case of containing the monofunctional polymerizable compound (A), Db/Da, which is a mass ratio of a content Da of the polyfunctional polymerizable compound to a content Db of the monofunctional polymerizable compound, is preferably 0.7 to 1.5. The upper limit of the numerical range is more preferably 1.4 or less, still more preferably 1.3 or less, and particularly preferably 1.2 or less. Moreover, the lower limit of the numerical range is more preferably 0.8 or greater, still more preferably 0.9 or greater, and particularly preferably 1.0 or greater. On the other hand, in a case of not containing the monofunctional polymerizable compound (A), db/Da is preferably 0.05 to 0.6. The upper limit of the numerical range is more preferably 0.5 or less, still more preferably 0.4 or less, and particularly preferably 0.3 or less. Moreover, the lower limit of the numerical range is more preferably 0.06 or greater, still more preferably 0.08 or greater, and particularly preferably 0.1 or greater. Consequently, the occurrence of collapse defects can be further suppressed in high-resolution pattern formation.

In the composition for forming a pattern, preferred formulation examples of the polymerizable compound are as follows. Consequently, the occurrence of collapse defects can be further suppressed in high-resolution pattern formation.

Formulation Example 1 (Case of Containing Monofunctional Polymerizable Compound (A))

| | |
|---|---|
| Polyfunctional polymerizable compound (A) | 30% to 50% by mass |
| Monofunctional polymerizable compound (A) | 20% to 40% by mass |
| Other monofunctional polymerizable compound | 10% to 30% by mass |

Formulation Example 2 (Case of not Containing Monofunctional Polymerizable Compound (A))

| | |
|---|---|
| Polyfunctional polymerizable compound (A) | 40% to 60% by mass |
| Other polyfunctional polymerizable compound | 20% to 40% by mass |
| Other monofunctional polymerizable compound | 5% to 20% by mass |

In the composition for forming a pattern according to the embodiment of the present invention, monofunctional polymerizable compounds other than the aforementioned monofunctional polymerizable compounds may be used as long as the compounds do not depart from the spirit of the present invention, and examples thereof include the monofunctional polymerizable compounds among the polymerizable compounds described in JP2014-170949A, the contents of which are incorporated in the present specification.

<<Photopolymerization Initiator>>

The composition for forming a pattern according to the embodiment of the present invention contains a photopolymerization initiator (photopolymerization initiator (B)) which contains an aromatic ring and does not contain a hydroxyl group, and a photopolymerization initiator (photopolymerization initiator (C)) represented by Formula (In-1) described above. The photopolymerization initiator (B) has excellent compatibility with the polymerizable compound (A) and is easily uniformly distributed in the composition for forming a pattern, due to its common structure with the polymerizable compound (A). As a result, it is considered that the photopolymerization initiator (B) mainly contributes to a promotion of curing of the entire composition. On the other hand, since the photopolymerization initiator (C) contains a hydroxyl group, the photopolymerization initiator (C) tends to be unevenly distributed on the surface of the composition for forming a pattern. As a result, it is considered that the photopolymerization initiator (C) mainly contributes to the curing of the composition near the surface of the mold.

Moreover, the composition for forming a pattern according to the embodiment of the present invention can also contain a photopolymerization initiator (hereinafter, also simply referred to as an “other photopolymerization initiator”) other than the photopolymerization initiator (B) and the photopolymerization initiator (C). From the viewpoint of suppressing the occurrence of pattern collapse defects, it is preferable that the composition for forming a pattern does not contain such other photopolymerization initiators.

In the composition for forming a pattern according to the embodiment of the present invention, the content of the total photopolymerization initiator is preferably 0.01% to 10% by mass with respect to the amount of the total solid content in the composition for forming a pattern. The upper limit of the numerical range is preferably 7.0% by mass or less, more preferably 5.5% by mass or less, and still more preferably 4.5% by mass or less. Moreover, the lower limit of the numerical range is preferably 0.1% by mass or greater, more preferably 0.5% by mass or greater, and still more preferably 1.0% by mass or greater.

<<<Photopolymerization Initiator (B)>>>

The photopolymerization initiator (B) is preferably a photoradical polymerization initiator. The photoradical polymerization initiator is not particularly limited as long as the photoradical polymerization initiator is a compound which generates active species polymerizing the aforementioned polymerizable compounds by light irradiation. Specific examples of such a photopolymerization initiator include compounds described in paragraph 0091 of JP2008-105414A.

A molecular weight of the photopolymerization initiator (B) is preferably 170 to 600. The upper limit of the numerical range is more preferably 500 or less and still more preferably 450 or less. Moreover, the lower limit of the numerical range is more preferably 200 or greater and still more preferably 250 or greater.

The aromatic ring of the photopolymerization initiator (B) may be the same as or different from the aromatic ring of the polymerizable compound (A). From the viewpoint of improving solubility or compatibility of the photopolymerization initiator (B), it is preferable that the aromatic ring of the photopolymerization initiator (B) is the same as the aromatic ring of the polymerizable compound (A). For example, the aromatic ring of the photopolymerization initiator (B) has the same ring structure as the aromatic ring of the polymerizable compound (A), and the aromatic ring may be a single ring or a polycyclic ring, and in a case of a polycyclic ring, a plurality of rings may be condensed. The aromatic ring of the photopolymerization initiator (B) may be a hetero ring containing a heteroatom such as N, O, and S, but preferably has a hydrocarbon ring skeleton, is more preferably a benzene ring or a naphthalene ring, and still more preferably a benzene ring. The number of aromatic rings of the photopolymerization initiator (B) in units of a single ring is preferably 1 to 5, more preferably 1 to 4, and still more preferably 2 or 3.

From the viewpoint of curing sensitivity and absorption characteristics, as the photopolymerization initiator (B), the composition for forming a pattern according to the embodiment of the present invention preferably contains at least one kind of an acetophenone-based compound (compound having an acetophenone skeleton), an acylphosphine oxide-based compound (compound having an acylphosphine oxide skeleton), or an oxime ester-based compound (compound having an oxime ester skeleton), more preferably contains at least one kind of an acylphosphine oxide-based compound or an oxime ester-based compound, and still more preferably contains an acylphosphine oxide-based compound.

Examples of preferred initiators as the photopolymerization initiator (B) include Irgacure OXE01, Irgacure OXE02, Irgacure OXE04, Irgacure TPO, Irgacure TPO-L, Irgacure 369, Irgacure 369E, Irgacure 379EG, Irgacure 651, and Irgacure 819 (all manufactured by BASF SE), and Omnirad TPO-H, Omnirad TPO-L, Omnirad 369, Omnirad 369E, Omnirad 379EG, Omnirad 651, and Omnirad 819 (all manufactured by IGM Resins B.V).

Moreover, in the present invention, an oxime compound having a fluorine atom can also be used as the photopolymerization initiator. Specific examples of the oxime compound having a fluorine atom include the compound described in JP2010-262028A, the compounds 24 and 36 to 40 described in JP2014-500852A, and the compound (C-3) described in JP2013-164471A. The contents thereof are incorporated in the present specification.

A maximum light absorption coefficient of the photopolymerization initiator (B) at a wavelength of 300 to 500 nm is preferably 0.1 to 1,000 L/(g·cm). The upper limit of the numerical range is preferably 1,000 L/(g·cm) or less, more preferably 500 L/(g·cm) or less, and still more preferably 100 L/(g·cm) or less. Moreover, the lower limit of the numerical range is preferably 0.1 L/(g·cm) or greater, more preferably 1.0 L/(g·cm) or greater, and still more preferably 10 L/(g·cm) or greater.

In addition, in the present invention, a content of the photopolymerization initiator (B) is preferably 0.01% to 10% by mass with respect to the total solid content of the composition for forming a pattern. The upper limit of the numerical range is more preferably 7.0% by mass or less, still more preferably 5.0% by mass or less, and particularly preferably 3.0% by mass or less. Moreover, the lower limit of the numerical range is more preferably 0.5% by mass or greater, still more preferably 1.0% by mass or greater, and particularly preferably 1.5% by mass or greater.

Moreover, in the present invention, the content of the photopolymerization initiator (B) is preferably 0.3% to 12% by mass with respect to the total polymerizable compound. The upper limit of the numerical range is more preferably 9.0% by mass or less, still more preferably 6.0% by mass or less, and particularly preferably 3.0% by mass or less. Moreover, the lower limit of the numerical range is preferably 0.8% by mass or greater, more preferably 1.6% by mass or greater, and still more preferably 1.8% by mass or greater.

Moreover, in the present invention, the content of the photopolymerization initiator (B) is preferably 0.5% to 15% by mass with respect to the polymerizable compound (A). The upper limit of the numerical range is more preferably 10% by mass or less, still more preferably 7.0% by mass or less, and particularly preferably 4.0% by mass or less. Moreover, the lower limit of the numerical range is preferably 1.0% by mass or greater, more preferably 2.0% by mass or greater, and still more preferably 2.5% by mass or greater.

The composition for forming a pattern according to the embodiment of the present invention may contain only one kind or two or more kinds of the photopolymerization initiators (B). In a case where two or more kinds thereof are contained, the total amount thereof is preferably within the above range.

<<<Photopolymerization Initiator (C)>>>

The photopolymerization initiator (C) represented by Formula (In-1) described above is preferably a photoradical polymerization initiator. The photoradical polymerization initiator is not particularly limited as long as the photoradical polymerization initiator is a compound which generates active species polymerizing the aforementioned polymerizable compounds by light irradiation. Specific examples of such a photopolymerization initiator include compounds described in paragraph 0091 of JP2008-105414A.

A molecular weight of the photopolymerization initiator (C) is preferably 170 to 330. The upper limit of the numerical range is more preferably 320 or less and still more preferably 310 or less. Moreover, the lower limit of the numerical range is preferably 180 or greater and more preferably 190 or greater.

The aromatic ring of the aromatic ring-containing group in Formula (In-1) may be a single ring or a polycyclic ring, and in a case of a polycyclic ring, a plurality of rings may be condensed. The aromatic ring may be an aromatic ring having a hydrocarbon ring skeleton, or an aromatic ring having a hetero ring skeleton containing a heteroatom such as N, O, and S. Regarding the aromatic ring having a hydrocarbon ring skeleton, the number of carbon atoms is preferably 6 to 22, more preferably 6 to 18, and still more preferably 6 to 10. As the aromatic ring having a hydrocarbon ring skeleton, for example, a benzene ring, a naphthalene ring, an anthracene ring, a phenanthrene ring, or a fluorene ring is preferable, a benzene ring or a naphthalene ring is more preferable, and a benzene ring is still more preferable. In addition, as the aromatic ring having a hetero ring skeleton, for example, a thiophene ring, a furan ring, or a dibenzofuran ring is preferable.

In addition, the above-described substituents of the above-described aromatic ring in Formula (In-1), as described above, at least one of the substituents is an electron-donating group, at least one of the substituents includes —O— directly linked to the aromatic ring, and at least one of the substituents includes a hydroxyl group. The above-described electron-donating group is not particularly limited as long as it can generate active species such as radicals from the photopolymerization initiator (C), but the above-described electron-donating group preferably has —O— directly linked to the aromatic ring. The number of “—O— directly linked to the aromatic ring” included in the substituent of the aromatic ring is preferably 1 to 3, more preferably 1 or 2, and still more preferably 1. The number of hydroxyl groups included in the substituent of the aromatic ring is preferably 1 to 4 and more preferably 1 to 3, and may be 1 or 2.

For example, the above-described electron-donating group is preferably a g represented by Formula (S-1).

(HO)ₙ-L³-O—* Formula (S-1):

In Formula (S-1), L³ represents an (n+1)-valent linking group, and n represents an integer of 0 to 2. In a case where n is 0, one terminal of L³ is a hydrogen atom. In the formula, the asterisk “*” represents a bonding site to the aromatic ring.

The linking group L³ is preferably one kind selected from an alkylene group having 1 to 5 carbon atoms, an alkenylene group having 2 to 5 carbon atoms, an arylene group, —CH═N—, —NH—, —O—, —C(═O)—, —S—, —S(═O)₂—, or —C(═S)—, or a group obtained by combining two or more kinds thereof.

The number of carbon atoms in the alkylene group as L³ is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring.

Specifically, the above-described linking group L³ is preferably one kind selected from a methylene group, an ethylene group, a vinylene group, a phenylene group, —CH═N—, —NH—, —O—, —C(═O)—, —S—, —S(═O)₂—, or —C(═S)—, or a group obtained by combining two or more kinds thereof, more preferably one kind selected from a methylene group, an ethylene group, —CH═N—, —NH—, —O—, or —C(═O)—, or a group obtained by combining two or more kinds thereof, and still more preferably a methylene group or an ethylene group. Regarding the above-described linking group L³, a plurality of the same constituent elements may be selected. Moreover, for example, the above-described linking group L³ may have a substituent such as the above-mentioned substituent T, or may be unsubstituted.

In Formula (S-1), n is preferably 1 or 2, and preferably 1.

In a case of a plurality of electron-donating groups, each electron-donating group may be the same as or different from each other. The number of electron-donating groups in Formula (In-1) is preferably 1 to 3, more preferably 1 or 2, and still more preferably 1.

Regarding the above-described substituent of the above-described aromatic ring in Formula (In-1), substituents other than the group having —O— directly linked to the aromatic ring may have a hydroxyl group. For example, the aromatic ring in Formula (In-1) may have a group represented by Formula (S-2) as a substituent.

HO-L⁵-* Formula (S-2):

In Formula (S-2), L⁵ represents a single bond or a divalent linking group which does not contain —O— directly linked to the aromatic ring. In the formula, the asterisk “*” represents a bonding site to the aromatic ring.

The linking group L⁵ is preferably one kind selected from an alkylene group having 1 to 5 carbon atoms, an alkenylene group having 2 to 5 carbon atoms, an arylene group, —CH═N—, —NH—, —O—, —C(═O)—, —S—, —S(═O)₂—, or —C(═S)—, or a group obtained by combining two or more kinds thereof. In particular, a terminal portion of the above-described linking group L² to be bonded to the aromatic ring is preferably an alkylene group, an alkenylene group, or an arylene group.

The number of carbon atoms in the alkylene group as L⁵ is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring.

Specifically, the above-described linking group L⁵ is preferably one kind selected from a methylene group, an ethylene group, a vinylene group, a phenylene group, —CH═N—, —NH—, —O—, —C(═O)—, —S—, —S(═O)₂—, or —C(═S)—, or a group obtained by combining two or more kinds thereof, more preferably one kind selected from a methylene group, an ethylene group, —CH═N—, —NH—, —O—, or —C(═O)—, or a group obtained by combining two or more kinds thereof, and still more preferably a methylene group or an ethylene group. Regarding the above-described linking group L⁵, a plurality of the same constituent elements may be selected. Moreover, for example, the above-described linking group L⁵ may have a substituent such as the above-mentioned substituent T, or may be unsubstituted.

As the photopolymerization initiator (C), the composition for forming a pattern according to the embodiment of the present invention preferably contains an acetophenone-based compound, and more preferably contains a compound represented by Formula (In-2).

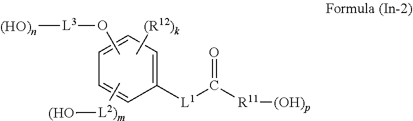

In Formula (In-2), L¹ and L² each independently represent a single bond or a divalent linking group, L³ represents an (n+1)-valent linking group, R¹¹ represents a (p+1)-valent aliphatic hydrocarbon group, R¹² represents a monovalent substituent, k, m, and n each independently represent an integer of 0 to 2, where m+n is 1 to 3 and k+m+n is 1 to 5, and p represents an integer of 1 to 3. In Formula (In-2), it is preferable that the group of (HO)ₙ-L³-O— functions as the electron-donating group in the present invention.

The linking group as L¹ to L³ is preferably one kind selected from an alkylene group having 1 to 5 carbon atoms, an alkenylene group having 2 to 5 carbon atoms, an arylene group, —CH═N—, —NH—, —O—, —C(═O)—, —S—, —S(═O)₂—, or —C(═S)—, or a group obtained by combining two or more kinds thereof.

In Formula (In-2), regarding the above-described linking group, the number of carbon atoms in the alkylene group is more preferably 1 to 3 and still more preferably 1 or 2. The number of carbon atoms in the alkenylene group is more preferably 2 or 3 and still more preferably 2. The arylene group may be a single ring or a polycyclic ring, and is preferably a single ring or a bicyclic ring and more preferably a single ring. One ring constituting the arylene group is preferably a 6-membered ring. In particular, a terminal portion of the above-described linking group L² to be bonded to the aromatic ring is preferably an alkylene group, an alkenylene group, or an arylene group.

Specifically, the above-described linking group is preferably one kind selected from a methylene group, an ethylene group, a vinylene group, a phenylene group, —CH═N—, —NH—, —O—, —C(═O)—, —S—, —S(═O)₂—, or —C(═S)—, or a group obtained by combining two or more kinds thereof, more preferably one kind selected from a methylene group, an ethylene group, —CH═N—, —NH—, —O—, or —C(═O)—, or a group obtained by combining two or more kinds thereof, and still more preferably a methylene group or an ethylene group. Regarding the above-described linking group, a plurality of the same constituent elements may be selected. Moreover, for example, the above-described linking group may have a substituent such as the above-mentioned substituent T, or may be unsubstituted.

Regarding R¹¹, a divalent aliphatic hydrocarbon group is preferably a linear or branched alkylene group having 1 to 10 carbon atoms, more preferably a linear or branched alkylene group having 1 to 5 carbon atoms, and still more preferably a linear or branched alkylene group having 1 to 3 carbon atoms. Specifically, R¹¹ is preferably a methylene group, an ethylene group, or a linear or branched propylene group, and more preferably a branched propylene group. Moreover, for example, R¹¹ may have a substituent such as the above-mentioned substituent T, or may be unsubstituted.

In Formula (In-2), k is preferably 0 or 1 and more preferably 0. m may be 1 or 2, but more preferably 0. n is preferably 1 or 2, and more preferably 1. p is preferably 1 or 2, and more preferably 1.

In addition, it is also preferable that the composition for forming a pattern contains a compound represented by Formula (In-3) as the photopolymerization initiator (C). Consequently, active species such as radicals are more efficiently generated from the photopolymerization initiator.

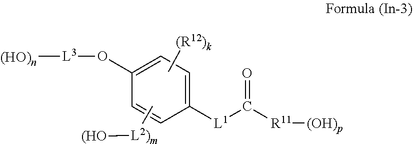

In Formula (In-3), L¹, L², L³, R¹¹, R¹², k, m, n, and p are synonymous with the reference numerals in Formula (In-2), respectively.

A preferred aspect of the photopolymerization initiator (C) represented by Formula (In-2) or Formula (In-3) is as follows.

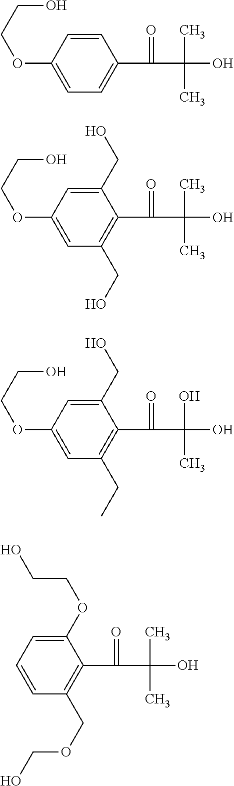

Examples of a preferred commercially available initiator as the photopolymerization initiator (C) include Irgacure 2959 (manufactured by BASF SE) and Omnirad 2959 (manufactured by IGM Resins B.V.).

In addition, in the present invention, a content of the photopolymerization initiator (C) is preferably 0.01% to 8.0% by mass with respect to the total solid content of the composition for forming a pattern. The upper limit of the numerical range is more preferably 5.0% by mass or less, still more preferably 4.0% by mass or less, and particularly preferably 3.0% by mass or less. Moreover, the lower limit of the numerical range is more preferably 0.5% by mass or greater, still more preferably 1.0% by mass or greater, and particularly preferably 1.5% by mass or greater.

Moreover, in the present invention, the content of the photopolymerization initiator (C) is preferably 0.2% to 9.0% by mass with respect to the total polymerizable compound. The upper limit of the numerical range is more preferably 7.0% by mass or less, still more preferably 5.0% by mass or less, and particularly preferably 3.0% by mass or less. Moreover, the lower limit of the numerical range is preferably 0.8% by mass or greater, more preferably 1.6% by mass or greater, and still more preferably 1.8% by mass or greater.

Moreover, in the present invention, the content of the photopolymerization initiator (C) is preferably 0.5% to 10% by mass with respect to the polymerizable compound (A). The upper limit of the numerical range is more preferably 8% by mass or less, still more preferably 6.0% by mass or less, and particularly preferably 4.0% by mass or less. Moreover, the lower limit of the numerical range is preferably 1.0% by mass or greater, more preferably 2.0% by mass or greater, and still more preferably 2.5% by mass or greater.

Moreover, in the present invention, Cb/Cc, which is a mass ratio of a content Cb of the photopolymerization initiator (B) to a content Cc of the photopolymerization initiator (C), is preferably 0.1 to 8.0. The upper limit of the numerical range is more preferably 5.0% by mass or less, still more preferably 4.0% by mass or less, and particularly preferably 2.0% by mass or less. Moreover, the lower limit of the numerical range is more preferably 0.5% by mass or greater, still more preferably 0.6% by mass or greater, and particularly preferably 0.7% by mass or greater.

The composition for forming a pattern according to the embodiment of the present invention may contain only one kind or two or more kinds of the photopolymerization initiators (C). In a case where two or more kinds thereof are contained, the total amount thereof is preferably within the above range.

<<<ΔHSP Between Photopolymerization Initiators (B) and (C)>>>

In the composition for forming a pattern according to the embodiment of the present invention, a Hansen solubility parameter distance ΔHSP between the photopolymerization initiator (B) and the photopolymerization initiator (C) is preferably 4 or greater. Consequently, the uneven distribution of the photopolymerization initiator (C) on the surface of the composition for forming a pattern can be efficiently generated. The ΔHSP is more preferably 5 or greater and still more preferably 6 or greater. The upper limit of the ΔHSP is not particularly limited, but is practically 20 or less and may be 15 or less. The ΔHSP is derived by Expression (1).

ΔHSP=[4.0×(ΔD²+ΔP²+ΔH²)]^{0.5} Expression (1)

In Expression (1), ΔD, ΔP, and ΔH are each as follows.

ΔD: Difference (d component 1-d component 2) between a dispersion element component (d component 1) of a Hansen solubility parameter vector of the photopolymerization initiator (B) and a dispersion element component (d component 2) of a Hansen solubility parameter vector of the photopolymerization initiator (C)

ΔP: Difference (p component 1-p component 2) between a polarity element component (p component 1) of the Hansen solubility parameter vector of the photopolymerization initiator (B) and a polarity element component (p component 2) of the Hansen solubility parameter vector of the photopolymerization initiator (C)

ΔH: Difference (h component 1-h component 2) between a hydrogen bond element component (h component 1) of the Hansen solubility parameter vector of the photopolymerization initiator (B) and a hydrogen bond element component (h component 2) of the Hansen solubility parameter vector of the photopolymerization initiator (C)

<<<Other Photopolymerization Initiator>>>

The other photopolymerization initiator is preferably a photoradical polymerization initiator. The photoradical polymerization initiator is not particularly limited as long as the photoradical polymerization initiator is a compound which generates active species polymerizing the aforementioned polymerizable compounds by light irradiation. Specific examples of such a photopolymerization initiator include compounds described in paragraph 0091 of JP2008-105414A.

A molecular weight of the other photopolymerization initiator is preferably 100 to 600. The upper limit of the numerical range is more preferably 580 or less and still more preferably 550 or less. Moreover, the lower limit of the numerical range is more preferably 130 or greater and still more preferably 150 or greater.

From the viewpoint of curing sensitivity and absorption characteristics, the other photopolymerization initiator is preferably an acetophenone-based compound, an acylphosphine oxide-based compound, or an oxime ester-based compound. Examples of a commercially available initiator which can be used as the other photopolymerization initiator include Irgacure 127 and Irgacure 1173 (both manufactured by BASF SE) and Omnirad 127 and Omnirad 1173 (both manufactured by IGM Resins RV).

<<Sensitizer>>

The composition for forming a pattern according to the embodiment of the present invention can contain a sensitizer. A molecular weight of the sensitizer in the present invention is preferably less than 2,000, more preferably 1,000 or less, still more preferably 800 or less, even more preferably 600 or less, and particularly preferably 550 or less, and may be 500 or less. The lower limit value thereof is preferably 100 or greater, more preferably 200 or greater, and still more preferably 250 or greater.

For example, the sensitizer is preferably a compound represented by Formula (PS-3a) or Formula (PS-3b). Consequently, the pattern defects can be further suppressed.

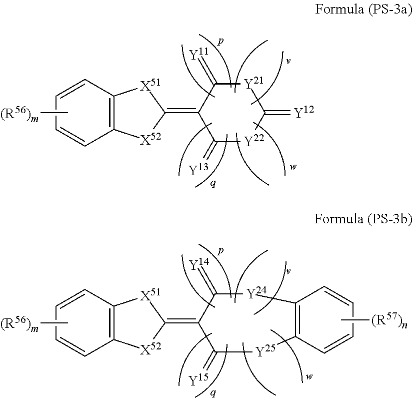

In Formula (PS-3a) and Formula (PS-3b), X⁵¹ and X⁵² each independently represent —S— or —NR⁵⁵—, R⁵⁵ represents a hydrogen atom or a monovalent substituent, R⁵⁶ represents a monovalent substituent, and m represents an integer of 0 to 4.

It is preferable that at least one of X⁵¹ or X⁵² is —S— and more preferable that both are —S—. Moreover, regarding X⁵¹ and X⁵², one of them may be —S— and the other may be —NR⁵⁵—.

For example, the monovalent substituent as R⁵⁵ is preferably the substituent T and more preferably substituents shown below.

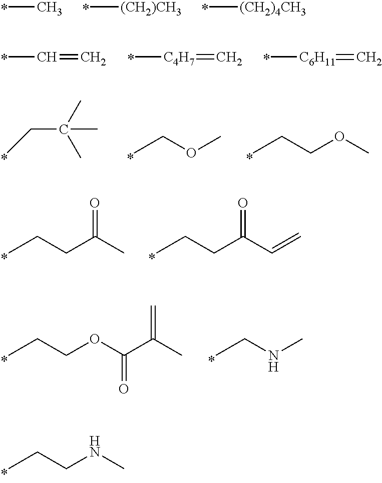

For example, R⁵⁶ is preferably the substituent T, and more preferably an alkyl group having 1 to 10 carbon atoms, an alkenyl group having 2 to 10 carbon atoms, an aryl group having 10 or less carbon atoms, or a heteroaryl group having 10 or less ring members.

The number of carbon atoms in the alkyl group as R⁵⁶ is preferably 1 to 5 and more preferably 2 to 4. In particular, the alkyl group is preferably a methyl group, an ethyl group, an n-propyl group, an isopropyl group, an n-butyl group, or a t-butyl group, more preferably an isopropyl group, an n-butyl group, or a t-butyl group, and still more preferably a t-butyl group. Moreover, the alkyl group can have a substituent, and may be unsubstituted.

The number of carbon atoms in the alkenyl group is preferably 2 to 5 and more preferably 2 to 4. In particular, the alkenyl group is, for example, preferably an ethenyl (vinyl) group, an n-propenyl group, an isopropenyl group, an n-butenyl group, or a t-butenyl group, more preferably an ethenyl group, an n-propenyl group, or an isopropenyl group, and still more preferably an isopropenyl group. Moreover, the alkenyl group can have a substituent, and may be unsubstituted.

The aryl group may be a single ring or a polycyclic ring, and is preferably a single ring or a bicyclic ring and more preferably a single ring. One ring constituting the aryl group is preferably a 6-membered ring. In particular, the aryl group is preferably a phenyl group or a naphthyl group.

Moreover, in Formula (PS-3a) and Formula (PS-3b), Y¹¹, Y¹², Y¹³, Y¹⁴, and Y¹⁵ are each independently an oxygen atom or a sulfur atom, Y²¹, Y²², Y²⁴, and Y²⁵ are each independently —CR⁷⁰R⁷¹, —O—, —NR⁷²—, or —S—, R⁷⁰ to R⁷² each represent a hydrogen atom or a monovalent substituent, R⁵⁷ represents a monovalent substituent, n represents an integer of 0 to 4, p and q are each 0 or 1, p+q satisfies 1 or 2, v and w are each 0 or 1, and v+w satisfies 1 or 2. Furthermore, p+q+v+w in Formula (PS-3a) is 3 or 4, and p+q+v+w in Formula (PS-3b) is 2 or 3.

In Formula (PS-3a), p+q may be 1 or 2, but is preferably 2. v+w may be 1 or 2, but is preferably 2.

In addition, it is preferable that at least one of Y¹¹, Y¹², or Y¹³ is an oxygen atom, more preferable that at least two thereof are oxygen atoms, and still more preferable that Y¹¹ and Y¹³ are oxygen atoms. In particular, regarding Y¹¹, Y¹² and Y¹³, an aspect in which all of Y¹¹, Y¹², and Y¹³ are oxygen atoms, or an aspect in which Y¹¹ and Y¹³ are oxygen atoms and Y¹² is a sulfur atom is preferable.

Y²¹ and Y²² are each preferably —O—, —NR⁷²—, or —S—, more preferably —O— or —NR⁷²—, and still more preferably —NR⁷²—. The monovalent substituent as R⁷⁰ to R⁷² is the same as the monovalent substituent as R⁵⁵. In particular, it is preferable that R⁷⁰ to R⁷² are each independently a hydrogen atom, a methyl group, or an ethyl group.

In Formula (PS-3b), p+q may be 1 or 2, but is preferably 2. v+w may be 1 or 2, but is preferably 1.

Moreover, it is preferable that at least one of Y¹⁴ or Y¹⁵ is an oxygen atom and more preferable that both of them are oxygen atoms.

Similarly to cases of Y²¹ and Y²², Y²⁴ and Y²⁵ are each preferably —O—, —NR⁷²—, or —S—, more preferably —O— or —NR⁷²—, and still more preferably —NR⁷²—. R⁷⁰ to R⁷² are the same as in a case of Formula (PS-3a).

Similarly to R⁵⁶, R⁵⁷ in Formula (PS-3b) is preferably the substituent T, and more preferably an alkyl group having 1 to 10 carbon atoms, an alkenyl group having 2 to 10 carbon atoms, an aryl group having 10 or less carbon atoms, or a heteroaryl group having 10 or less ring members. The specific content of R⁵⁷ is also the same as that of R⁵⁶. n in Formula (PS-3b) is preferably 0 to 3 and more preferably 0 or 1, and may be 0. In a case where n is 2 or greater, a plurality of R⁵⁷'s may be the same as or different from each other.

Hereinafter, preferred aspects of the sensitizer according to the composition for forming a pattern according to the embodiment of the present invention will be shown.

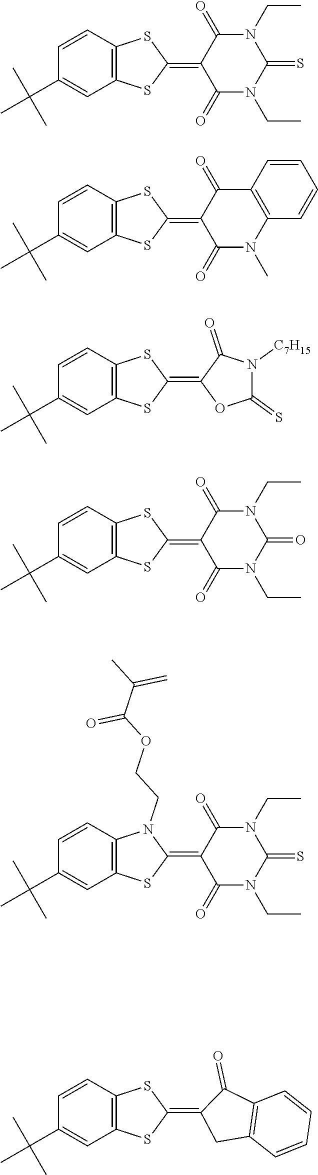

The sensitizer preferably exhibits a light absorption coefficient of 25.0 L/(g·cm) or greater in a wavelength range of 400 nm or greater. That is, regarding the absorption spectrum characteristics of the sensitizer, it is preferable that a wavelength range λ₂₅ exhibiting a light absorption coefficient of 25.0 L/(g·cm) or greater is present and at least a part of the wavelength range λ₂₅ is in a wavelength range of 400 nm or greater. Consequently, the sensitizer can efficiently absorb light of 400 nm or greater, and the pattern defects can be further suppressed. The lower limit wavelength of the wavelength range λ₂₅ is preferably 445 nm or less and more preferably 440 nm or less. Moreover, the upper limit wavelength of the wavelength range λ₂₅ is preferably 380 nm or greater, more preferably 390 nm or greater, and still more preferably 400 nm or greater.

In the composition for forming a pattern according to the embodiment of the present invention, the content of the sensitizer is preferably 0.0001% to 3% by mass with respect to the amount of the total solid content. The content is more preferably 1.5% by mass or less, still more preferably 1.0% by mass or less, and particularly preferably 0.8% by mass or less. Moreover, the content is more preferably 0.001% by mass or greater, still more preferably 0.01% by mass or greater, and particularly preferably 0.05% by mass or greater. Furthermore, Cs/Ci, which is a mass ratio of a content Cs of the sensitizer to a content Ci of the entire photopolymerization initiator, is preferably 0.0002 to 1.5. The mass ratio Cs/Ci is more preferably 1.0 or less, still more preferably 0.5 or less, and particularly preferably 0.3 or less. Moreover, the mass ratio is more preferably 0.0005 or greater, still more preferably 0.002 or greater, even more preferably 0.01 or greater, and particularly preferably 0.02 or greater. The sensitizer is used alone or in combination of a plurality thereof, and in a case where two or more kinds of the sensitizers are used, the total amount thereof is preferably included within the above range.

<<Release Agent>>

The composition for forming a pattern according to the embodiment of the present invention may contain a release agent.

A kind of the release agent used in the present invention is not particularly specified as long as the kind does not depart from the spirit of the present invention. The release agent is preferably an additive having a function of segregating at an interface with the mold to promote separation from the mold. The composition for forming a pattern according to the embodiment of the present invention preferably contains, as the release agent, at least one kind of (a) a surfactant, (b) a non-polymerizable compound (hereinafter, also referred to as a “non-polymerizable compound having releasability”) which has a polyalkylene glycol structure having at least one hydroxyl group at a terminal or having an etherified hydroxyl group, or (c) a polymerizable compound having a fluorine atom.

The release agent in the composition for forming a pattern may be of only one kind or two or more kinds. Moreover, in a case where the release agents are contained, a total content thereof with respect to the total solid content is preferably 0.1% to 20% by mass, more preferably 0.5% to 10% by mass, and still more preferably 1% to 5% by mass. In a case where two or more kinds of the release agents are used, the total amount thereof is preferably included within the above range.

<<<(a) Surfactant>>>

As a surfactant for the release agent, any one of a nonionic surfactant, an anionic surfactant, a cationic surfactant, or an amphoteric surfactant may be used. Moreover, the surfactant preferably includes at least one kind of a nonionic surfactant or an anionic surfactant and preferably includes a nonionic surfactant, from the viewpoint of compatibility with other components or releasability.

The nonionic surfactant is a compound having at least one hydrophobic moiety and at least one nonionic hydrophilic moiety. The hydrophobic moiety and the nonionic hydrophilic moiety may each be at a terminal of a molecule, or inside. The hydrophobic moiety is constituted of a hydrophobic group selected from a hydrocarbon group, a fluorine-containing group, and a Si-containing group, and the number of carbon atoms in the hydrophobic moiety is preferably 1 to 25, more preferably 2 to 15, still more preferably 4 to 10, and even more preferably 5 to 8. The nonionic hydrophilic moiety preferably has at least one group selected from the group consisting of an alcoholic hydroxyl group, a phenolic hydroxyl group, an ether group (preferably, a polyoxyalkylene group and a cyclic ether group), an amide group, an imide group, a ureide group, a urethane group, a cyano group, a sulfonamide group, a lactone group, a lactam group, and a cyclocarbonate group. The nonionic surfactant may be a hydrocarbon-based, fluorine-based, Si-based, or fluorine and Si-based nonionic surfactant, but is more preferably a fluorine-based or Si-based nonionic surfactant and still more preferably a fluorine-based nonionic surfactant. Here, the “fluorine and Si-based surfactant” refers to a surfactant satisfying requirements of both a fluorine-based surfactant and a Si-based surfactant.

Examples of a commercially available product of the fluorine-based nonionic surfactant include FLUORAD FC-4430 and FC-4431 manufactured by Sumitomo 3M Limited, SURFLON S-241, S-242, S-243, and S-650 manufactured by AGC SEIMI CHEMICAL CO., LTD., EFTOP EF-PN31M-03, EF-PN31M-04, EF-PN31M-05, EF-PN31M-06, and MF-100 manufactured by Mitsubishi Materials Electronic Chemicals Co., Ltd., Polyfox PF-636, PF-6320, PF-656, and PF-6520 manufactured by OMNOVA Solutions Inc., FUTAGENT 250, 251, 222F, 212M, and DFX-18 manufactured by NEOS COMPANY LIMITED, UNIDYNE DS-401, DS-403, DS-406, DS-451, and DSN-403N manufactured by DAIKIN INDUSTRIES, LTD., MEGAFACE F-430, F-444, F-477, F-553, F-556, F-557, F-559, F-562, F-565, F-567, F-569, and R-40 manufactured by DIC Corporation, and Capstone FS-3100 and Zonyl FSO-100 manufactured by DuPont.

In addition, examples of the anionic surfactant include alkyl ether phosphate, polyoxyalkylene alkyl ether phosphate, alkyl alcohol phosphoric acid ester salt, alkylbenzene sulfonate, alkyl alcohol sulfuric acid ester salt, and polyoxyalkylene alkyl ether sulfate. Examples of the cationic surfactant include tetraalkylammonium halide, alkylpyridinium halide, and alkylimidazoline halide. Examples of the amphoteric surfactant include alkyl betaine and lecithin.

In a case where the composition for forming a pattern according to the embodiment of the present invention contains a surfactant, a content of the surfactant is preferably 0.1% to 10% by mass, more preferably 0.2% to 5% by mass, and still more preferably 0.5% to 5% by mass, with respect to the amount of the total solid content in the composition. The composition for forming a pattern may contain only one kind or two or more kinds of the surfactants. In a case where two or more kinds thereof are contained, the total amount thereof is preferably within the above range.

<<<(b) Non-Polymerizable Compound Having Releasability>>>

In the composition for forming a pattern according to the embodiment of the present invention, the non-polymerizable compound having releasability is not particularly limited as long as the non-polymerizable compound has a polyalkylene glycol structure having at least one hydroxyl group at the terminal or having an etherified hydroxyl group, and it is preferable that a fluorine atom and a silicon atom are not substantially contained. Here, the non-polymerizable compound refers to a compound having no polymerizable group. Moreover, regarding the non-polymerizable compound, the expression “a fluorine atom and a silicon atom are not substantially contained” indicates, for example, that a total content ratio of the fluorine atom and the silicon atom is 1% by mass or less, and it is preferable that a fluorine atom and a silicon atom are not contained at all. In a case where a fluorine atom and a silicon atom are not contained, compatibility with the polymerizable compound is improved, and particularly in the composition for forming a pattern which does not substantially contain a solvent, coating uniformity, pattern formability during imprinting, and line edge roughness after dry etching are improved.

The polyalkylene glycol structure of the non-polymerizable compound having releasability is preferably a polyalkylene glycol structure including an alkylene group having 1 to 6 carbon atoms, more preferably a polyethylene glycol structure, a polypropylene glycol structure, a polybutylene glycol structure, or a mixed structure thereof, still more preferably a polyethylene glycol structure, a polypropylene glycol structure, or a mixed structure thereof, and even more preferably a polypropylene glycol structure.

Furthermore, the non-polymerizable compound may be substantially constituted of only a polyalkylene glycol structure, except for a substituent at a terminal. Here, the expression “substantially” means that constituent elements other than the polyalkylene glycol structure account for 5% by mass or less and preferably 1% by mass or less of the entire compound. In particular, it is preferable to include a compound substantially consisting of a polypropylene glycol structure, as the non-polymerizable compound having releasability.

The number of alkylene glycol constitutional units included in the polyalkylene glycol structure is preferably 3 to 100, more preferably 4 to 50, still more preferably 5 to 30, and even more preferably 6 to 20.

The non-polymerizable compound having releasability preferably has at least one hydroxyl group at the terminal or has an etherified hydroxyl group. In a case where the non-polymerizable compound has at least one hydroxyl group at the terminal or has an etherified hydroxyl group, the remaining terminal may be a hydroxyl group, or a hydrogen atom of the terminal hydroxyl group may be substituted. As a group in which a hydrogen atom of the terminal hydroxyl group may be substituted, an alkyl group (that is, polyalkylene glycol alkyl ether) and an acyl group (that is, polyalkylene glycol ester) are preferable. A compound having a plurality of (preferably, two or three) polyalkylene glycol chains via a linking group can also be preferably used.

Preferred specific examples of the non-polymerizable compound having releasability include polyethylene glycol, polypropylene glycol (for example, manufactured by FUJIFILM Wako Pure Chemical Corporation), mono or dimethyl ether thereof, mono or dibutyl ether, mono or dioctyl ether, mono or dicetyl ether, monostearic acid ester, monooleic acid ester, polyoxyethylene glyceryl ether, polyoxypropylene glyceryl ether, polyoxyethylene lauryl ether, and trimethyl ether thereof.

A weight-average molecular weight of the non-polymerizable compound having releasability is preferably 150 to 6,000, more preferably 200 to 3,000, still more preferably 250 to 2,000, and even more preferably 300 to 1,200.

In addition, examples of a commercially available product of the non-polymerizable compound having releasability, which can be used in the present invention, include OLFINE E1010 (manufactured by Nissin Chemical Co., Ltd.) and Brij35 (manufactured by Kishida Chemical Co., Ltd.).

In a case where the composition for forming a pattern according to the embodiment of the present invention contains the non-polymerizable compound having releasability, a content of the non-polymerizable compound having releasability is preferably 0.1% by mass or greater, more preferably 0.5% by mass or greater, still more preferably 1.0% by mass or greater, and even more preferably 2% by mass or greater, in the total solid content. Moreover, the content is preferably 20% by mass or less, more preferably 10% by mass or less, and still more preferably 5% by mass or less.

The composition for forming a pattern may contain only one kind or two or more kinds of the non-polymerizable compounds having releasability. In a case where two or more kinds thereof are contained, the total amount thereof is preferably within the above range.

<<<(c) Polymerizable Compound Having Fluorine Atom>>>

The polymerizable compound having a fluorine atom as the release agent in the present invention preferably has a polymerizable group, and a functional group containing a fluorine atom.

The kind of the polymerizable group is not particularly limited, but, for example, an ethylenically unsaturated bond-containing group, an epoxy group, and the like are preferable, and an ethylenically unsaturated bond-containing group is preferable. As described above, as the ethylenically unsaturated bond-containing group, for example, a vinyl group, an ethynyl group, a (meth)acryloyl group, a (meth)acryloyloxy group, and the like are preferable, a (meth)acryloyl group and a (meth)acryloyloxy group are more preferable, and an acryloyl group and an acryloyloxy group are still more preferable.

As the functional group containing a fluorine atom, a fluorine-containing group selected from a fluoroalkyl group and a fluoroalkyl ether group is preferable.

The fluoroalkyl group is preferably a fluoroalkyl group having 2 or more carbon atoms and more preferably a fluoroalkyl group having 4 or more carbon atoms, and the upper limit value of the number of carbon atoms is not particularly specified, but is preferably 20 or less, more preferably 8 or less, and still more preferably 6 or less. The fluoroalkyl group is most preferably a fluoroalkyl group having 4 to 6 carbon atoms. Specifically, the fluoroalkyl group is preferably a trifluoromethyl group, a pentafluoroethyl group, a heptafluoropropyl group, a hexafluoroisopropyl group, a nonafluorobutyl group, a tridecafluorohexyl group, or a heptadecafluorooctyl group. Moreover, it is also preferable that the fluoroalkyl group has a trifluoromethyl group at a terminal or a side chain.

The fluoroalkyl ether group is preferably a perfluoroethyleneoxy group or a perfluoropropyleneoxy group, for example. Moreover, similarly to a case of the fluoroalkyl group, it is also preferable that the fluoroalkyl ether group has a trifluoromethyl group at the terminal, or has a trifluoromethyl group at the side chain as in —(CF(CF₃)CF₂O)—.

The polymerizable compound having a fluorine atom is also described in paragraphs 0021 to 0043 of JP2011-124554A, the contents of which are incorporated in the present specification.

In a case where the composition for forming a pattern according to the embodiment of the present invention contains the polymerizable compound having a fluorine atom, a content of the polymerizable compound having a fluorine atom is preferably 0.1% by mass or greater, more preferably 0.5% by mass or greater, still more preferably 1.0% by mass or greater, and even more preferably 2% by mass or greater, in the total solid content. Moreover, the content is preferably 20% by mass or less, more preferably 10% by mass or less, and still more preferably 5% by mass or less. The composition for forming a pattern may contain only one kind or two or more kinds of the polymerizable compounds having a fluorine atom. In a case where two or more kinds thereof are contained, the total amount thereof is preferably within the above range.

<<<Release Agent Containing Hydroxyl Group>>>

In the composition for forming a pattern according to the embodiment of the present invention, the release agent is not particularly limited, and a release agent containing a hydroxyl group and a release agent not containing a hydroxyl group may be used separately, or both of them may be used in combination. For example, in a case of using a release agent containing a hydroxyl group, the release agent containing a hydroxyl group tends to be unevenly distributed on the surface of the composition for forming a pattern, and thus easily comes into contact with the surface of the mold in a case where the mold is pressed. As a result, it is possible to prevent the photopolymerization initiator (C) from being excessively unevenly distributed on the surface of the mold, so that curing proceeds more than necessary on the surface of the mold and a mold release is rather hindered. That is, by unevenly distributing the release agent containing a hydroxyl group, a degree of curing of the composition for forming a pattern near the surface of the mold can be adjusted. In a case of adjusting the degree of curing, it is preferable to use, as the release agent, the release agent containing a hydroxyl group and the release agent not containing a hydroxyl group in combination, and adjust the addition amount of each. The composition for forming a pattern may have an aspect in which the release agent containing a hydroxyl group is not substantially contained. Here, the “not substantially contained” refers to that a content of the release agent containing a hydroxyl group is 0.1% by mass or less with respect to the composition for forming a pattern. The content of the release agent containing a hydroxyl group is preferably 8% by mass or less and more preferably 5% by mass or less with respect to the composition for forming a pattern.

Specific examples of the release agent containing a hydroxyl group are as follows. In the following structural formulae, 1+m+n is an integer of 7 to 15. In the present invention, the release agent containing a hydroxyl group is not limited to the following compounds.

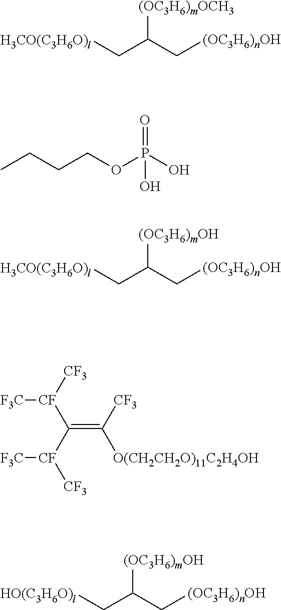

<<Other Components>>

The composition for forming a pattern according to the embodiment of the present invention may contain a sensitizer, an antioxidant, an ultraviolet absorber, a solvent, a polymer, or the like, in addition to the aforementioned components. Each of these compounds in the composition for forming a pattern may be of only one kind or two or more kinds. For the details thereof, reference can be made to the description in paragraphs 0061 to 0064 of JP2014-170949A, the contents of which are incorporated in the present specification.

<<<Solvent>>>

The composition for forming a pattern according to the embodiment of the present invention may contain a solvent. Examples of the solvent include propylene glycol monomethyl ether acetate, cyclohexanone, 2-heptanone, γ-butyrolactone, propylene glycol monomethyl ether, and ethyl lactate. In a case where the solvent is contained, a content thereof is preferably 1% to 20% by mass with respect to the composition. Only one kind or two or more kinds of the solvents may be contained. In a case where two or more kinds thereof are contained, the total amount thereof is preferably within the above range.

Furthermore, in the present invention, a configuration in which the composition for forming a pattern does not substantially contain a solvent can also be adopted. Here, the expression “the composition for forming a pattern does not substantially contain a solvent” means, for example, that the content of the solvent in the composition for forming a pattern is 5% by mass or less. The content of the solvent in the composition for forming a pattern is preferably 3% by mass or less and more preferably 1% by mass or less.

<<<Polymer>>>

The composition for forming a pattern according to the embodiment of the present invention may contain a polymer. The polymer is, for example, a component having a weight-average molecular weight of 2,000 or greater, and preferably a component having a weight-average molecular weight of greater than 2,000.

Furthermore, in the present invention, a configuration in which a polymer is not substantially contained can also be adopted. The expression “polymer is not substantially contained” means that the content of the polymer is 5% by mass or less, and the content is preferably 3% by mass or less and more preferably 1% by mass or less.

<Characteristics of Composition for Forming Pattern>

In the composition for forming a pattern according to the embodiment of the present invention, the viscosity of components excluding the solvent from the composition at 23° C. is preferably 50 mPa·s or lower. Moreover, the viscosity thereof is preferably 25 mPa·s or lower, more preferably 20 mPa·s or lower, still more preferably 15 mPa·s or lower, and even more preferably 10 mPa·s or lower. The lower limit value of the viscosity is not particularly specified, but can be, for example, 5 mPa·s or higher. By setting the viscosity within the above range, the composition for forming a pattern according to the embodiment of the present invention is more likely to enter into the mold, and thus mold filling time can be shortened.

A method for measuring the viscosity is not particularly limited, and a known method is appropriately selected. For example, the viscosity can be measured at an appropriate rotation speed using an E-type rotational viscometer RE85L manufactured by TOM SANGYO CO., LTD. and a standard cone rotor (1° 34′×R24) in a state where a temperature of a sample cup is adjusted to 23° C. As the appropriate rotation speed in a case where the above-described standard cone rotor is used, conditions described in Examples below can be used. The unit of the viscosity is mPa·s. Other details regarding the measurement are in accordance with JIS Z 8803:2011. Two samples are produced for one level and are respectively measured three times. An arithmetic mean value of a total of six times is adopted as an evaluation value.

Moreover, the pattern formability and the throughput can also be further improved. In the composition for forming a pattern according to the embodiment of the present invention, the surface tension of components excluding the solvent from the composition at 23° C. is preferably 25 to 40 mN/m. The surface tension is more preferably 38 mN/m or lower, still more preferably 36 mN/m or lower, and particularly preferably 35 mN/m or lower. Furthermore, the surface tension is more preferably 27 mN/m or higher and still more preferably 28 mN/m or higher.

In the composition for forming a pattern according to the embodiment of the present invention, an Ohnishi parameter of components excluding the solvent from the composition is preferably 4.0 or less, more preferably 3.9 or less, still more preferably 3.8 or less, even more preferably 3.6 or less, and particularly preferably 3.5 or less. The lower limit value of the Ohnishi parameter is not particularly specified, but can be, for example, 2.8 or greater. By setting the Ohnishi parameter to 4.0 or less, etching processing characteristics, in particular, pattern disconnection after etching can be further effectively suppressed.

In the composition for forming a pattern according to the embodiment of the present invention, a maximum light absorption coefficient of components excluding the solvent from the composition in a wavelength range of 400 nm to 500 nm is preferably 1.0 L/(g·cm) or less. Moreover, the maximum light absorption coefficient is preferably 0.8 L/(g·cm) or less and more preferably 0.6 L/(g·cm) or less, and by doing so, light reaches a deep portion of the composition for forming a pattern and thus the pattern collapse defects can be further suppressed.

The modulus of elasticity of a cured film formed from the composition for forming a pattern according to the embodiment of the present invention is preferably 3.5 GPa or less, more preferably 3.0 GPa or less, and still more preferably 2.5 GPa or less. The lower limit value of the modulus of elasticity is preferably 1.0 GPa or greater and more preferably 1.5 GPa or greater. By setting the modulus of elasticity within the above range, both the improvement in the releasability and the suppression of the pattern collapse can be further achieved.

The glass transition temperature Tg of the cured film formed from the composition for forming a pattern according to the embodiment of the present invention is preferably 90° C. or higher, more preferably 95° C. or higher, and still more preferably 100° C. or higher. The upper limit value of Tg is not particularly determined, but is practically approximately 200° C. or lower. By setting the Tg within the above range, the aforementioned effects of the present invention can be further effectively exhibited, and pattern disconnection after etching can be further effectively suppressed.

<Method for Producing Composition for Forming Pattern>

The composition for forming a pattern according to the embodiment of the present invention is prepared by formulating raw materials (the respective materials described above) in a predetermined ratio. It is preferable that the raw materials are mixed and then the mixture is subjected to a filtration treatment with a filter. The filtration with a filter is preferably performed after the raw materials for the composition for forming a pattern are mixed.

Effects of filtration are exhibited even with one stage of a filter, but filtration with two or more stages of filters is more preferable. The filtration with two or more stages of filters refers to filtration in a state where two or more filters are arranged in series. In the present invention, filtration with one to four stages of filters is preferable, and filtration with two to four stages of filters is more preferable.

A component (material component) constituting the material for the filter preferably includes a resin. The resin is not particularly limited, and resins well known as the material for the filter can be used. As one preferred embodiment of the component (material component) constituting the material for the filter, a polymer (grafted polymer) in which at least one kind of neutral groups is grafted can be mentioned. The neutral group is preferably at least one kind selected from a hydroxyl group or a carboxy group, and more preferably a hydroxyl group. The grafted polymer is preferably a grafted polyolefin and more preferably a grafted polyethylene. For the description of the grafted polymer, reference can be made to the description in WO2016/081729A, the contents of which are incorporated in the present specification.

A pore diameter of the filter used in the present invention is preferably 100 nm or smaller, more preferably 20 nm or smaller, still more preferably 12 nm or smaller, and even more preferably 8 nm or smaller, and may be 5 nm or smaller. By setting the pore diameter of the filter to 100 nm or smaller, impurities can be further effectively reduced. Moreover, the lower limit value of the pore diameter of the filter is not particularly specified, but is preferably 1 nm or larger, for example. By setting the pore diameter of the filter to 1 nm or larger, an unnecessarily large pressure is not applied during filtration, productivity is improved, and breakage of a filter can be effectively suppressed. In a case where the filtration is performed stepwise, a filter having a pore diameter of 100 to 7 nm (preferably, a filter having a pore diameter of 20 to 7 nm) can be used in first-stage filtration, and a filter having a pore diameter of smaller than 7 nm (preferably, a filter having a pore diameter of smaller than 7 nm and 1 nm or larger) can be used in second-stage filtration. Moreover, a difference in the pore diameter from the immediately preceding stage, such as between the first stage and the second stage and between the second stage and the third stage, is preferably 1 to 8 nm.

<Storage Container>

As a storage container of the composition for forming a pattern according to the embodiment of the present invention, a storage container well known in the related art can be used. Moreover, as the storage container, for the purpose of suppressing impurities from being mixed into a raw material or a composition, a multilayer bottle having a container inner wall made of six layers of six kinds of resins or a bottle having a seven-layer structure of six kinds of resins is also preferably used. Examples of such a container include the container described in JP2015-123351A.

<Pattern Producing Method>

The composition for forming a pattern according to the embodiment of the present invention is applied in a layer form onto the substrate to form a layered film, and then cured by exposure, which will be described later, to form a cured substance. Here, the laminate including the substrate and the layered film that has not been cured corresponds to a laminate according to the embodiment of the present invention, and the cured substance corresponds to a cured film according to the embodiment of the present invention. The layered film may be a continuous film such as a film formed by, for example, a spin coating method, or may be a discontinuous film such as a film formed by, for example, an ink jet method. The composition for forming a pattern according to the embodiment of the present invention is used for producing a patterned cured substance (hereinafter, also simply referred to as a “pattern”) by an optical imprinting method.

A pattern producing method according to the embodiment of the present invention includes applying the composition for forming a pattern according to the embodiment of the present invention onto a substrate or a mold and irradiating the composition for forming a pattern with light in a state where the composition for forming a pattern is sandwiched between the mold and the substrate. The method for applying the composition for forming a pattern onto the substrate or the mold is not particularly limited. Regarding the application method, reference can be made to the description in paragraph 0102 of JP2010-109092A (the corresponding US application is the specification of US2011/0199592A), the contents of which are incorporated in the present specification. In the present invention, as the application method, a spin coating method or an ink jet method is preferable.

In the present invention, the substrate is not particularly limited. Regarding the substrate, reference can be made to the description in paragraph 0103 of JP2010-109092A (the corresponding US application is the specification of US2011/0199592A), the contents of which are incorporated in the present specification. Specific examples thereof include a silicon substrate, a glass substrate, a sapphire substrate, a silicon carbide substrate, a gallium nitride substrate, a metal aluminum substrate, an amorphous aluminum oxide substrate, a polycrystalline aluminum oxide substrate, and a substrate made of GaAsP, GaP, AlGaAs, InGaN, GaN, AlGaN, ZnSe, AlGaInP, or ZnO. Furthermore, specific examples of a material for the glass substrate include aluminosilicate glass, aluminoborosilicate glass, and barium borosilicate glass. In the present invention, as the substrate, a silicon substrate is preferable.

In the present invention, the mold is not particularly limited. Regarding the mold, reference can be made to the description in paragraphs 0105 to 0109 of JP2010-109092A (the corresponding US application is the specification of US2011/0199592A), the contents of which are incorporated in the present specification. In the present invention, as the mold, a quartz mold is preferable. A pattern (line width) of the mold used in the present invention preferably has a size of 50 nm or less. Moreover, the aspect ratio (depth/width) of pattern recesses (region filled with the composition for forming a pattern) of the mold is not particularly limited, and by applying the composition for forming a pattern according to the embodiment of the present invention, it is possible to efficiently form a pattern while suppressing pattern defects even in a case where the pattern has an aspect ratio of 2.5 or greater and further 5 or greater.

The composition for forming a pattern is irradiated with light in a state of being sandwiched between the mold and the substrate. A step of performing pressure contact with the substrate or the mold can be preferably performed under a rare gas atmosphere, under a reduced-pressure atmosphere, or under a pressure-reduced rare gas atmosphere. Here, the reduced-pressure atmosphere means a state in a space filled with a pressure lower than the atmospheric pressure (101,325 Pa), and the pressure is preferably 1,000 Pa or lower, more preferably 100 Pa or lower, and still more preferably 1 Pa or lower. In a case where the rare gas is used, helium is preferable. An exposure amount is desirably in a range of 5 mJ/cm² to 1,000 mJ/cm².

The light used for curing the composition for forming a pattern according to the embodiment of the present invention is not particularly limited, and examples thereof include a high-energy ionizing radiation, light having a wavelength in a near-ultraviolet, far-ultraviolet, visible, or infrared range, and a radiation. As the high-energy ionizing radiation source, for example, electron beams accelerated by an accelerator such as a Cockcroft-type accelerator, a Van de Graaff accelerator, a linear accelerator, a betatron, or a cyclotron are the most conveniently and economically in the industrial aspect, but in addition to the electron beams, radiations such as γ-rays, X-rays, α-rays, neutron rays, and proton beams which are radiated from a radioactive isotope, a nuclear reactor, or the like can also be used. Examples of the ultraviolet ray source include an ultraviolet fluorescent lamp, a low-pressure mercury lamp, a high-pressure mercury lamp, an ultra-high pressure mercury lamp, a xenon lamp, a carbon arc lamp, and a sun lamp. The radiation includes, for example, microwaves and EUV. Moreover, an LED, semiconductor laser light, or laser light, which is used in fine processing of a semiconductor, such as 248-nm KrF excimer laser light or a 193-nm ArF excimer laser can also be suitably used in the present invention. As the light, monochromatic light may be used, or light (mixed light) having a plurality of different wavelengths may be used.

The light which can be used for the exposure is, for example, light having a wavelength of 200 to 450 nm. Specifically, examples of the irradiation light during the exposure include ultraviolet rays such as a g-line (wavelength of 436 nm) and an i-line (wavelength of 365 nm). The exposure using the i-line may be performed while cutting light having a wavelength shorter than 300 nm, as described in KR10-2017-0122130A.

During the exposure, exposure illuminance is preferably in a range of 1 mW/cm² to 10,000 mW/cm². By setting the exposure illuminance to 1 mW/cm² or greater, an exposure time can be shortened, and thus productivity is improved, and by setting the exposure illuminance to 10,000 mW/cm² or less, it is possible to suppress the deterioration in characteristics of a permanent film due to the occurrence of side reactions. An exposure amount is preferably in a range of 5 mJ/cm² to 10,000 mJ/cm². In a case where the exposure amount is less than 5 mJ/cm², an exposure margin gets narrow, photocuring is insufficient, and thus a problem such as attachment of an unreacted substance to the mold is more likely to occur. Meanwhile, in a case where the exposure amount is greater than 10,000 mJ/cm², a risk of deterioration of the permanent film due to decomposition of the composition arises.

Furthermore, during the exposure, in order to prevent the inhibition of radical polymerization by oxygen, an oxygen concentration may be controlled to be lower than 100 mg/L by flowing an inert gas such as nitrogen or argon.

In the pattern producing method according to the embodiment of the present invention, after the layered film consisting of the composition for forming a pattern is cured by the light irradiation, as necessary, a step of applying heat to the cured pattern to further cure the pattern may be included. A temperature for heating and curing the composition according to the embodiment of the present invention after the light irradiation is, for example, preferably 150° C. to 280° C. and more preferably 200° C. to 250° C. Moreover, a time for applying heat is preferably 5 to 60 minutes and more preferably 15 to 45 minutes.

In addition, during the exposure, light may be continuously radiated for the exposure, or may be radiated in the form of a pulse for the exposure (pulse exposure). Moreover, the pulse exposure is an exposure method in which exposure is performed by repeating irradiation with light and resting in a cycle of a short time (for example, a millisecond level or less). In a case of the pulse exposure, a pulse width is preferably 100 nanoseconds (ns) or less, more preferably 50 nanoseconds or less, and still more preferably 30 nanoseconds or less. The lower limit of the pulse width is not particularly limited, but may be 1 femtosecond (fs) or greater and may be 10 femtoseconds or greater. A frequency is preferably 1 kHz or greater, more preferably 2 kHz or greater, and still more preferably 4 kHz or greater. The upper limit of the frequency is preferably 50 kHz or less, more preferably 20 kHz or less, and still more preferably 10 kHz or less. Maximum instantaneous illuminance is preferably 5,000 W/cm² or greater, more preferably 10,000 W/cm² or greater, and still more preferably 20,000 W/cm² or greater. Moreover, the upper limit of the maximum instantaneous illuminance is preferably 100,000 W/cm² or less, more preferably 80,000 W/cm² or less, and still more preferably 50,000 W/cm² or less. Furthermore, the pulse width is a time during which light is radiated in the pulse period. The frequency is the number of pulse periods per second. The maximum instantaneous illuminance is average illuminance within the time during which light is radiated in the pulse period. The pulse period is a period in which irradiation with light and resting are one cycle in the pulse exposure.

In the composition for forming a pattern according to the embodiment of the present invention, an underlayer film or a liquid film may be provided between the substrate and a layer formed of the composition for forming a pattern, by using a composition for forming an underlayer film or a composition for forming a liquid film. That is, the composition for forming a pattern (further, a pattern of the present invention) may be provided directly on the surface of the substrate or the mold, or may be provided on the substrate or the mold via one or more layers. The underlayer film and the liquid film will be described in detail later.

In addition to the aforementioned matters, for details of the pattern producing method, reference can be made to the description in paragraphs 0103 to 0115 of JP2010-109092A (the corresponding US application is the specification of US2011/0199592A), the contents of which are incorporated in the present specification.

In the pattern producing method according to the embodiment of the present invention, a fine pattern can be formed at a low cost and with high accuracy by the optical imprinting method (more preferably, an optical nanoimprinting method). Therefore, the pattern, which was used to be formed by using the photolithography technique in the related art, can be formed with higher accuracy and at a lower cost. As an example, the method is used for manufacturing a semiconductor element. That is, the present invention also discloses a method for manufacturing a semiconductor element, which includes the pattern producing method according to the embodiment of the present invention. More specifically, the pattern of the present invention is preferably used as an etching resist (etching mask). In particular, the pattern can also be applied as a permanent film, such as an overcoat layer or an insulating film, used in a liquid crystal display (LCD) or the like, or an etching resist such as a semiconductor integrated circuit, a recording material, or a flat panel display. In particular, the pattern obtained by the pattern producing method according to the embodiment of the present invention also has excellent etching resistance, and thus can also be preferably used as an etching resist for dry etching using fluorocarbon or the like.

<Pattern>

As described above, the pattern (that is, cured film formed by using the composition for forming a pattern) formed by the pattern producing method according to the embodiment of the present invention can be used as a permanent film used in an LCD or the like, or an etching resist for semiconductor processing. Moreover, a grid pattern is formed on a glass substrate of the LCD using the pattern of the present invention, and thus a polarizing plate having low reflection or absorption and a large screen size (for example, 55 inches, or greater than 60 inches) can be manufactured at a low cost. For example, the polarizing plate described in JP2015-132825A or WO2011/132649A can be manufactured. Furthermore, 1 inch is 25.4 mm.

In addition, after the production, the composition for forming a pattern is bottled in a container such as a gallon bottle or a coated bottle, transported, and stored, but in this case, for the purpose of preventing deterioration, the inside of the container may be replaced with inert nitrogen, argon, or the like. Moreover, during the transportation and the storage, the temperature may be a normal temperature, but in order to further prevent degeneration of the composition for forming a pattern, the temperature may be controlled to be in a range of −20° C. to 0° C. It goes without saying that blocking light at a level at which the reaction does not proceed is preferable.

Specifically, the pattern of the present invention can be preferably used for producing a recording medium such as a magnetic disc, a light-receiving element such as a solid-state imaging element, a light emitting element such as an LED and organic EL, an optical device such as an LCD, an optical component such as a diffraction grating, a relief hologram, an optical waveguide, an optical filter, and a microlens array, a member for flat panel display such as a thin film transistor, an organic transistor, a color filter, an antireflection film, a polarizing plate, a polarizing element, an optical film, and a column material, a nanobiodevice, an immunoassay chip, a deoxyribonucleic acid (DNA) separation chip, a microreactor, a photonic liquid crystal, or a guide pattern for fine pattern formation (directed self-assembly, DSA) using self-assembly of block copolymers.

The pattern formed by the pattern producing method according to the embodiment of the present invention is also useful as an etching resist (mask for lithography). In a case where the pattern is used as an etching resist, first, a silicon substrate (silicon wafer or the like) in which a thin film of, for example, SiO₂ or the like is formed or the like is used as a substrate, and a fine pattern of, for example, a nano or micro order is formed on the substrate by the pattern producing method according to the embodiment of the present invention. In the present invention, the pattern producing method is particularly advantageous in that a fine pattern of a nano order can be formed and a pattern having a size of 100 nm or less, further 50 nm or less, and particularly 30 nm or less can also be formed. The lower limit value of the size of the pattern formed by the pattern producing method according to the embodiment of the present invention is not particularly specified, but can be, for example, 1 nm or greater. A shape of the pattern is not particularly specified, but, for example, an aspect including at least one shape of a line, a hole, or a pillar is exemplified.

Thereafter, by performing etching with an etching gas such as hydrogen fluoride or the like in a case of wet etching and CF₄ or the like in a case of dry etching, a desired pattern can be formed on the substrate. The pattern has favorable etching resistance particularly to dry etching. That is, the pattern obtained by the producing method according to the embodiment of the present invention is preferably used as an etching mask. Moreover, the present invention also discloses a method for manufacturing a semiconductor element, in which etching is performed using, as a mask, the pattern obtained by the producing method according to the embodiment of the present invention.

<Composition for Forming Underlayer Film>

As described above, by providing the underlayer film between the substrate and the layer formed of the composition for forming a pattern, effects such as improvement in the adhesiveness between the substrate and the layer formed of the composition for forming a pattern can be achieved. In the present invention, the underlayer film can be obtained by applying the composition for forming an underlayer film onto the substrate and then curing the composition, in the same manner as the composition for forming a pattern. Hereinafter, each component of the composition for forming an underlayer film will be described.

The composition for forming an underlayer film of the present invention contains a curable component. The curable component is a component constituting the underlayer film, and may be any one of a high-molecular-weight component (for example, a molecular weight is greater than 1,000) or a low-molecular-weight component (for example, a molecular weight is less than 1,000). Specific examples thereof include a resin and a crosslinking agent. Each of these components may be used alone or in combination of two or more kinds thereof.

A total content of the curable components in the composition for forming an underlayer film is not particularly limited, but is preferably 50% by mass or greater in the total solid content, more preferably 70% by mass or greater in the total solid content, and still more preferably 80% by mass or greater in the total solid content. The upper limit thereof is not particularly limited, but is preferably 99.9% by mass or less.

A concentration of the curable component in the composition for forming an underlayer film (including a solvent) is not particularly limited, but is preferably 0.01% by mass or higher, more preferably 0.05% by mass or higher, and still more preferably 0.1% by mass or higher. The upper limit thereof is preferably 10% by mass or lower, more preferably 5% by mass or lower, still more preferably 1% by mass or lower, and even more preferably lower than 1% by mass.

<<Resin>>

As the resin in the composition for forming an underlayer film, well-known resins can be widely used. The resin used in the present invention preferably has at least one of a radically polymerizable group or a polar group, and more preferably has both a radically polymerizable group and a polar group.

By having the radically polymerizable group, an underlayer film having excellent hardness can be obtained. Moreover, by having a polar group, adhesiveness to a substrate is improved. Furthermore, in a case where a crosslinking agent is formulated, a crosslinking structure formed after curing is further firmed, and thus hardness of the obtained underlayer film can be improved.

The radically polymerizable group preferably includes an ethylenically unsaturated bond-containing group. Examples of the ethylenically unsaturated bond-containing group include a (meth)acryloyl group (preferably a (meth)acryloyloxy group and a (meth)acryloylamino group), a vinyl group, a vinyloxy group, an allyl group, a methylallyl group, a propenyl group, a butenyl group, a vinylphenyl group, and a cyclohexenyl group, a (meth)acryloyl group and a vinyl group are preferable, a (meth)acryloyl group is more preferable, and a (meth)acryloyloxy group is still more preferable. The ethylenically unsaturated bond-containing group defined here is referred to as Et.

Furthermore, the polar group is preferably at least one kind of an acyloxy group, a carbamoyloxy group, a sulfonyloxy group, an acyl group, an alkoxycarbonyl group, an acylamino group, a carbamoyl group, an alkoxycarbonylamino group, a sulfonamide group, a phosphoric acid group, a carboxy group, or a hydroxyl group, more preferably at least one kind of an alcoholic hydroxyl group, a phenolic hydroxyl group, or a carboxy group, and still more preferably an alcoholic hydroxyl group or a carboxy group. The polar group defined here is referred to as a polar group Po. The polar group is preferably a nonionic group.

The resin in the composition for forming an underlayer film may further contain a cyclic ether group. Examples of the cyclic ether group include an epoxy group and an oxetanyl group, and an epoxy group is preferable. The cyclic ether group defined here is referred to as a cyclic ether group Cyt.

Examples of the resin include a (meth)acrylic resin, a vinyl resin, a novolac resin, a phenol resin, a melamine resin, a urea resin, an epoxy resin, and a polyimide resin, and at least one kind of a (meth)acrylic resin, a vinyl resin, or a novolac resin is preferable.

A weight-average molecular weight of the resin is preferably 4,000 or greater, more preferably 6,000 or greater, and still more preferably 8,000 or greater. The upper limit thereof is preferably 1,000,000 or less and may be 500,000 or less.

The resin preferably has at least one of constitutional units represented by Formulae (1) to (3).

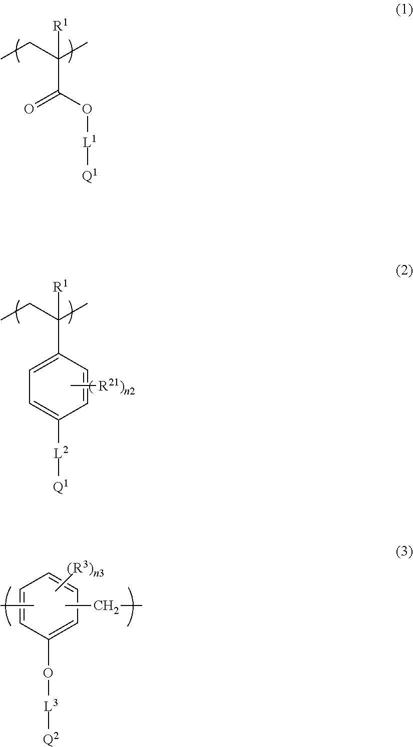

In the formulae, R¹ and R² are each independently a hydrogen atom or a methyl group. R²¹ and R³ are each independently a substituent. L¹, L², and L³ are each independently a single bond or a linking group. n2 is an integer of 0 to 4. n3 is an integer of 0 to 3. Q¹ is an ethylenically unsaturated bond-containing group or a cyclic ether group. Q² is an ethylenically unsaturated bond-containing group, a cyclic ether group, or a polar group.

R¹ and R² are each preferably a methyl group.

R²¹ and R³ are each independently preferably the substituent T.

In a case where there are a plurality of R²¹'s, R²¹'s may be linked to each other to form a cyclic structure. In the present specification, the linking is meant to include not only an aspect in which groups are continued by bonding but also an aspect in which groups lose some atoms and are fused (condensed). Moreover, unless otherwise specified, an oxygen atom, a sulfur atom, and a nitrogen atom (amino group) may be included in the linking cyclic structure. Examples of the formed cyclic structure include an aliphatic hydrocarbon ring (groups exemplified below are referred to as a ring CO (for example, a cyclopropyl group, a cyclobutyl group, a cyclopentyl group, a cyclohexyl group, a cyclopropenyl group, a cyclobutenyl group, a cyclopentenyl group, a cyclohexenyl group, and the like), an aromatic hydrocarbon ring (rings exemplified below are referred to as a ring Cr) (a benzene ring, a naphthalene ring, an anthracene ring, a phenanthrene ring, and the like), a nitrogen-containing heterocyclic ring (rings exemplified below are referred to as a ring Cn) (for example, a pyrrole ring, an imidazole ring, a pyrazole ring, a pyridine ring, a pyrroline ring, a pyrrolidine ring, an imidazolidine ring, a pyrazolidine ring, a piperidine ring, a piperazine ring, a morpholine ring, and the like), an oxygen-containing heterocyclic ring (rings exemplified below are referred to as a ring Co) (a furan ring, a pyran ring, an oxirane ring, an oxetane ring, a tetrahydrofuran ring, a tetrahydropyran ring, a dioxane ring, and the like), and a sulfur-containing heterocyclic ring (rings exemplified below are referred to as a ring Cs) (a thiophene ring, a thiirane ring, a thietane ring, a tetrahydrothiophene ring, a tetrahydrothiopyran ring, and the like).

In a case where there are a plurality of R³'s, R³'s may be linked to each other to form a cyclic structure. Examples of the formed cyclic structure include the ring Cf, the ring Cr, the ring Cn, the ring Co, and the ring Cs.

It is preferable that L¹, L², and L³ are each independently a single bond or a linking group L which will be described later. Among them, a single bond, or an alkylene group or an (oligo)alkyleneoxy group, which is defined as the linking group L, is preferable, and an alkylene group is more preferable. The linking group L preferably has the polar group Po as a substituent. Moreover, an aspect in which the alkylene group has a hydroxyl group as a substituent is also preferable. In the present specification, the “(oligo)alkyleneoxy group” means a divalent linking group having one or more “alkyleneoxy” constitutional units. The number of carbon atoms in an alkylene chain in the constitutional unit may be the same or different for every constitutional unit.

n2 is preferably 0 or 1 and more preferably 0. n3 is preferably 0 or 1 and more preferably 0.

Q¹ is preferably the ethylenically unsaturated bond-containing group Et.

Q² is preferably a polar group, and preferably an alkyl group having an alcoholic hydroxyl group.

The resin may further contain at least one of a constitutional unit (11), a constitutional unit (21), or a constitutional unit (31). In particular, in the resin included in the present invention, the constitutional unit (11) is preferably combined with the constitutional unit (1), the constitutional unit (21) is preferably combined with the constitutional unit (2), and the constitutional unit (31) is preferably combined with the constitutional unit (3).

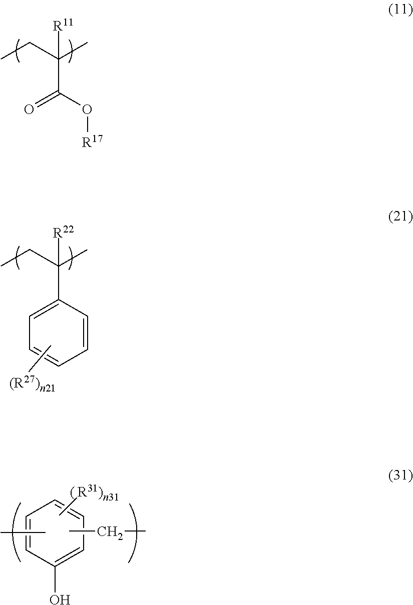

In the formulae, R¹¹ and R²² are each independently a hydrogen atom or a methyl group. R¹⁷ is a substituent. R²⁷ is a substituent. n21 is an integer of 0 to 5. R¹¹ is a substituent, and n31 is an integer of 0 to 3.

R¹¹ and R²² are each preferably a methyl group.

R¹⁷ is preferably a group containing a polar group or a group containing a cyclic ether group. In a case where R¹⁷ is a group containing a polar group, R¹⁷ is preferably a group containing the polar group Po, and more preferably the polar group Po or the substituent T substituted with the polar group Po. In a case where R¹⁷ is a group containing a cyclic ether group, R¹⁷ is preferably a group containing the cyclic ether group Cyt, and more preferably the substituent T substituted with the cyclic ether group Cyt.

R²⁷ is a substituent, and at least one of R²⁷'s is preferably a polar group. The substituent is preferably the substituent T. n21 is preferably 0 or 1 and more preferably 0. In a case where there are a plurality of R²⁷'s, R²⁷'s may be linked to each other to form a cyclic structure. Examples of the formed cyclic structure include examples of the ring Cf, the ring Cr, the ring Cn, the ring Co, and the ring Cs.

R³¹ is preferably the substituent T. n31 is an integer of 0 to 3, preferably 0 or 1, and more preferably 0. In a case where there are a plurality of R³¹'s, R³¹'s may be linked to each other to form a cyclic structure. Examples of the formed cyclic structure include examples of the ring Cf, the ring Cr, the ring Cn, the ring Co, and the ring Cs.

Examples of the linking group L include an alkylene group (the number of carbon atoms is preferably 1 to 24, more preferably 1 to 12, and still more preferably 1 to 6), an alkenylene group (the number of carbon atoms is preferably 2 to 12, more preferably 2 to 6, and still more preferably 2 or 3), an (oligo)alkyleneoxy group (the number of carbon atoms in an alkylene group in one constitutional unit is preferably 1 to 12, more preferably 1 to 6, and still more preferably 1 to 3; and the repetition number is preferably 1 to 50, more preferably 1 to 40, and still more preferably 1 to 30), an arylene group (the number of carbon atoms is preferably 6 to 22, more preferably 6 to 18, and still more preferably 6 to 10), an oxygen atom, a sulfur atom, a sulfonyl group, a carbonyl group, a thiocarbonyl group, —NR^{N}—, and a linking group related to a combination thereof. The alkylene group, alkenylene group, and alkyleneoxy group may have the substituent T. For example, the alkylene group may have a hydroxyl group.

A linking chain length of the linking group L is preferably 1 to 24, more preferably 1 to 12, and still more preferably 1 to 6. The linking chain length means the number of atoms positioned on the shortest path among the atomic groups involved in the linkage. For example, in a case of —CH₂-(C═O)—O—, the linking chain length is 3.

Furthermore, the alkylene group, alkenylene group, and (oligo)alkyleneoxy group, which are defined as the linking group L, may be chain-like or cyclic, or may be linear or branched.

It is preferable that as an atom constituting the linking group L, a carbon atom, a hydrogen atom, and as necessary, a heteroatom (at least one kind selected from an oxygen atom, a nitrogen atom, or a sulfur atom, and the like) are included. The number of carbon atoms in the linking group is preferably 1 to 24, more preferably 1 to 12, and still more preferably 1 to 6. The number of hydrogen atom may be determined according to the number of carbon atoms and the like. In a case of the number of heteroatoms, the numbers of the oxygen atoms, the nitrogen atoms, and the sulfur atoms are each independently preferably 0 to 12, more preferably 0 to 6, and still more preferably 0 to 3.

The resin may be synthesized by a conventional method. For example, a resin having the constitutional unit represented by Formula (1) can be appropriately synthesized by a well-known method for addition polymerization of olefin. A resin having the constitutional unit represented by Formula (2) can be appropriately synthesized by a well-known method for addition polymerization of styrene. A resin having the constitutional unit represented by Formula (3) can be appropriately synthesized by a well-known method for synthesis of a phenol resin.

The resin may be used alone or in combination of a plurality thereof.

As the resin as the curable component, in addition to the aforementioned resins, the resins described in paragraphs 0016 to 0079 of WO2016/152600A, paragraphs 0025 to 0078 of WO2016/148095A, paragraphs 0015 to 0077 of WO2016/031879A, and paragraphs 0015 to 0057 of WO2016/027843A can be used, the contents of which are incorporated in the present specification.

<<Crosslinking Agent>>

The crosslinking agent in the composition for forming an underlayer film is not particularly limited as long as the crosslinking agent advances curing by a crosslinking reaction. In the present invention, the crosslinking agent is preferably reacted with a polar group of a resin to form a crosslinking structure. By using such a crosslinking agent, the resin is more firmly bonded, and thus a firmer film can be obtained.

Examples of the crosslinking agent include an epoxy compound (compound having an epoxy group), an oxetanyl compound (compound having an oxetanyl group), an alkoxymethyl compound (compound having an alkoxymethyl group), a methylol compound (compound having a methylol group), and a blocked isocyanate compound (compound having a blocked isocyanate group), and an alkoxymethyl compound (compound having an alkoxymethyl group) can form a firm bond at a low temperature and thus is preferable.

<<Other Components>>

The composition for forming an underlayer film of the present invention may contain other components in addition to the aforementioned components.

Specifically, one or more kinds of a solvent, a thermal acid generator, an alkylene glycol compound, a polymerization initiator, a polymerization inhibitor, an antioxidant, a leveling agent, a thickener, a surfactant, or the like may be contained. Regarding the aforementioned components, the respective components described in JP2013-036027A, JP2014-090133A, and JP2013-189537A can be used. Also regarding the content or the like, reference can be made to the description in the aforementioned publications.

<<<Solvent>>>

In the present invention, the composition for forming an underlayer film particularly preferably contains a solvent (hereinafter, also referred to as a “solvent for an underlayer film”). The solvent is, for example, preferably a compound which is liquid at 23° C. and has a boiling point of 250° C. or lower. A content of the solvent for an underlayer film in the composition for forming an underlayer film is preferably 99.0% by mass or greater and more preferably 99.2% by mass or greater, and may be 99.4% by mass or greater. That is, the concentration of the total solid content in the composition for forming an underlayer film is preferably 1% by mass or lower, more preferably 0.8% by mass or lower, and still more preferably 0.6% by mass or lower. Moreover, the lower limit value thereof is preferably higher than 0% by mass, more preferably 0.001% by mass or higher, still more preferably 0.01% by mass or higher, and even more preferably 0.1% by mass or higher. By setting the proportion of the solvent within the above range, a film thickness during film formation is kept thin, and thus pattern formability during etching processing is improved.

Only one kind or two or more kinds of the solvents may be contained in the composition for forming an underlayer film. In a case where two or more kinds thereof are contained, the total amount thereof is preferably within the above range.

A boiling point of the solvent for an underlayer film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the underlayer film, which is preferable.

The solvent for an underlayer film is preferably an organic solvent. The solvent is preferably a solvent having any one or more of an ester group, a carbonyl group, a hydroxyl group, or an ether group. Among them, it is preferable to use an aprotic polar solvent.

Examples of a preferred solvent among the solvents for an underlayer film include alkoxy alcohol, propylene glycol monoalkyl ether carboxylate, propylene glycol monoalkyl ether, lactic acid ester, acetic acid ester, alkoxypropionic acid ester, chain-like ketone, cyclic ketone, lactone, and alkylene carbonate, and propylene glycol monoalkyl ether and lactone are particularly preferable.

<<<Thermal Acid Generator>>>

The thermal acid generator is a compound which generates an acid by heating and advances crosslinking by the action of the acid. In a case of being used in combination with the crosslinking agent, an underlayer film having higher hardness can be obtained.

As the thermal acid generator, an organic onium salt compound in which a cationic component and an anionic component are paired is usually used. As the cationic component, for example, organic sulfonium, organic oxonium, organic ammonium, organic phosphonium, and organic iodonium can be mentioned. Moreover, as the anionic component, for example, BF⁴⁻, B(C₆F₅)⁴⁻, SbF⁶⁻, AsF⁶⁻, PF⁶⁻, CF₃SO₃⁻, C₄F₉SO₃⁻, and (CF₃SO₂)₃C⁻ can be mentioned.

Specifically, reference can be made to the description in paragraphs 0243 to 0256 of JP2017-224660A and paragraph 0016 of JP2017-155091A, the contents of which are incorporated in the present specification.

A content of the thermal acid generator is preferably 0.01 to 10 parts by mass and more preferably 0.1 to 5 parts by mass, with respect to 100 parts by mass of the crosslinking agent. The thermal acid generator may be used alone or in combination of two or more kinds thereof. In a case where two or more kinds thereof are used, the total amount thereof is preferably within the above range.

<<<Polymerization Initiator>>>

The composition for forming an underlayer film may contain a polymerization initiator and preferably contains at least one kind of a thermal polymerization initiator or a photopolymerization initiator. By containing the polymerization initiator, a reaction of a polymerizable group contained in the composition for forming an underlayer film is promoted, and thus the adhesiveness is improved. From the viewpoint that crosslinking reactivity with the composition for forming a pattern is improved, a photopolymerization initiator is preferable. As the photopolymerization initiator, a radical polymerization initiator and a cationic polymerization initiator are preferable, and a radical polymerization initiator is more preferable. Moreover, in the present invention, a plurality of kinds of photopolymerization initiators may be used in combination.

As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound such as acylphosphine oxide, hexaarylbiimidazole, an oxime compound such as an oxime derivative, an organic peroxide, a thio compound, a ketone compound, an aromatic onium salt, ketoxime ether, an aminoacetophenone compound, hydroxyacetophenone, an azo-based compound, an azide compound, a metallocene compound, an organic boron compound, and an iron arene complex. For the details thereof, reference can be made to the description in paragraphs 0165 to 0182 of JP2016-027357A, the contents of which are incorporated in the present specification.

Examples of the acylphosphine compound include 2,4,6-trimethylbenzoyl-diphenyl-phosphine oxide.

In addition, as the photopolymerization initiator, commercially available initiators can also be used. Examples of such an initiator are the same as the commercially available initiators exemplified as the initiators which can be used, for example, in the composition for forming a pattern.

In a case where the photopolymerization initiator used in the composition for forming an underlayer film is formulated, a content thereof in the total solid content is, for example, 0.0001% to 5% by mass, preferably 0.0005% to 3% by mass, and more preferably 0.01% to 1% by mass. In a case where two or more kinds of photopolymerization initiators are used, the total amount thereof is within the above range.

<Composition for Forming Liquid Film>

In addition, in the present invention, it is also preferable that a liquid film is formed on the underlayer film by using a composition for forming a liquid film containing a radically polymerizable compound which is a liquid at 23° C. and 1 atm. In the present invention, the liquid film can be obtained by applying the composition for forming a liquid film onto the substrate and then drying the composition, in the same manner as the composition for forming a pattern. By forming such a liquid film, there are effects that the adhesiveness between the substrate and the composition for forming a pattern is further improved, and that the wettability of the composition for forming a pattern on the substrate is also improved. Hereinafter, the composition for forming a liquid film will be described.

The viscosity of the composition for forming a liquid film is preferably 1,000 mPa·s or lower, more preferably 800 mPa·s or lower, still more preferably 500 mPa·s or lower, and even more preferably 100 mPa·s or lower. The lower limit value of the viscosity is not particularly limited, but can be, for example, 1 mPa·s or higher. A method for measuring the viscosity is not particularly limited, and a known method is appropriately selected. For example, the viscosity is measured according to the method described above.

<<Radically Polymerizable Compound A>>

The composition for forming a liquid film contains a radically polymerizable compound (radically polymerizable compound A) which is a liquid at 23° C. and 1 atm.

A viscosity of the radically polymerizable compound A at 23° C. is preferably 1 to 100,000 mPa·s. The lower limit thereof is preferably 5 mPa·s or higher and more preferably 11 mPa·s or higher. The upper limit thereof is preferably 1,000 mPa·s or lower and more preferably 600 mPa·s or lower.

The radically polymerizable compound A may be a monofunctional radically polymerizable compound having only one radically polymerizable group in one molecule, or a polyfunctional radically polymerizable compound having two or more radically polymerizable groups in one molecule. The monofunctional radically polymerizable compound and the polyfunctional radically polymerizable compound may be used in combination. Among them, for a reason of suppressing pattern collapse, the radically polymerizable compound A contained in the composition for forming a liquid film preferably includes a polyfunctional radically polymerizable compound, more preferably includes a radically polymerizable compound having two to five radically polymerizable groups in one molecule, still more preferably includes a radically polymerizable compound having two to four radically polymerizable groups in one molecule, and particularly preferably includes a radically polymerizable compound having two radically polymerizable groups in one molecule.

Furthermore, the radically polymerizable compound A preferably contains at least one of an aromatic ring (the number of carbon atoms is preferably 6 to 22, more preferably 6 to 18, and still more preferably 6 to 10) or an alicyclic ring (the number of carbon atoms is preferably 3 to 24, more preferably 3 to 18, and still more preferably 3 to 6), and more preferably contains an aromatic ring. The aromatic ring is preferably a benzene ring. Moreover, a molecular weight of the radically polymerizable compound A is preferably 100 to 900.

Examples of the radically polymerizable group of the radically polymerizable compound A include ethylenically unsaturated bond-containing groups, such as a vinyl group, an allyl group, and a (meth)acryloyl group, and a (meth)acryloyl group is preferable.

It is also preferable that the radically polymerizable compound A is a compound represented by Formula (I-1).

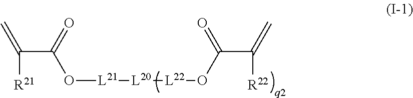

L²⁰ is a (1+q2)-valent linking group, and examples thereof include (1+q2)-valent linking groups which contains a group (the number of carbon atoms is preferably 1 to 12, more preferably 1 to 6, and still more preferably 1 to 3) having an alkane structure, a group (the number of carbon atoms is preferably 2 to 12, more preferably 2 to 6, and still more preferably 2 or 3) having an alkene structure, a group (the number of carbon atoms is preferably 6 to 22, more preferably 6 to 18, and still more preferably 6 to 10) having an aryl structure, a group (the number of carbon atoms is preferably 1 to 22, more preferably 1 to 18, and still more preferably 1 to 10, examples of a heteroatom include a nitrogen atom, a sulfur atom, and an oxygen atom, and a 5-membered ring, a 6-membered ring, and a 7-membered ring are preferable) having a heteroaryl structure, or a group obtained by combining these groups. Examples of the group in which two aryl groups are combined include groups having a structure such as biphenyl, diphenylalkane, biphenylene, and indene. Examples of a combination of the group having a heteroaryl structure and the group having an aryl structure include groups having a structure such as indole, benzimidazole, quinoxaline, and carbazole.

L²⁰ is preferably a linking group containing at least one kind selected from a group having an aryl structure or a group having a heteroaryl structure, and more preferably a linking group containing a group having an aryl structure.

R²¹ and R²² each independently represent a hydrogen atom or a methyl group.

L²¹ and L²² each independently represent a single bond or the linking group L, and a single bond or an alkylene group is preferable.

L²⁰ and L²¹ or L²² may be bonded to each other via or without via the linking group L to form a ring. L²⁰, L²¹, and L²² may have the substituent T. A plurality of substituents T may be bonded to each other to form a ring. In a case where there are the plurality of substituents T, the plurality of substituents T may be the same as or different from each other.

q2 is an integer of 0 to 5, preferably an integer of 0 to 3, more preferably an integer of 0 to 2, still more preferably 0 or 1, and particularly preferably 1.

As the radically polymerizable compound A, the compounds described in paragraphs 0017 to 0024 and Examples of JP2014-090133A, the compounds described in paragraphs 0024 to 0089 of JP2015-009171A, the compounds described in paragraphs 0023 to 0037 of JP2015-070145A, and the compounds described in paragraphs 0012 to 0039 of WO2016/152597A can also be used.

A content of the radically polymerizable compound A in the composition for forming a liquid film is preferably 0.01% by mass or greater, more preferably 0.05% by mass or greater, and still more preferably 0.1% by mass or greater. The upper limit thereof is preferably 10% by mass or less, more preferably 5% by mass or less, and still more preferably 1% by mass or less.

The content of the radically polymerizable compound A in the solid content of the composition for forming a liquid film is preferably 50% by mass or greater, more preferably 75% by mass or greater, and still more preferably 90% by mass or greater. The upper limit thereof may be 100% by mass. The radically polymerizable compound A may be used alone or in combination of two or more kinds thereof. In a case where two or more kinds thereof are used, the total amount thereof is preferably within the above range.

Furthermore, it is also preferable that the solid content of the composition for forming a liquid film substantially consists of the radically polymerizable compound A. The case where the solid content of the composition for forming a liquid film substantially consists of the radically polymerizable compound A means that the content of the radically polymerizable compound A in the solid content of the composition for forming a liquid film is 99.9% by mass or greater, the content is more preferably 99.99% by mass or greater, and it is still more preferable that the solid content consists of the radically polymerizable compound A.

<<Solvent>>

The composition for forming a liquid film preferably contains a solvent (hereinafter, referred to as a “solvent for a liquid film” in some cases). Examples of the solvent for a liquid film include the solvents described in the aforementioned section of the solvent for an underlayer film, and these solvents can be used. A content of the solvent for a liquid film in the composition for forming a liquid film is preferably 90% by mass or greater and more preferably 99% by mass or greater, and may be 99.99% by mass or greater.

A boiling point of the solvent for a liquid film is preferably 230° C. or lower, more preferably 200° C. or lower, still more preferably 180° C. or lower, even more preferably 160° C. or lower, and further still more preferably 130° C. or lower. The lower limit value thereof is practically 23° C. but more practically 60° C. or higher. By setting the boiling point within the above range, the solvent can be easily removed from the liquid film, which is preferable.

<<Radical Polymerization Initiator>>

The composition for forming a liquid film may contain a radical polymerization initiator. Examples of the radical polymerization initiator include a thermal radical polymerization initiator and a photoradical polymerization initiator, and a photoradical polymerization initiator is preferable. As a photoradical polymerization initiator, well-known compounds can be optionally used. Examples thereof include a halogenated hydrocarbon derivative (for example, a compound having a triazine skeleton, a compound having an oxadiazole skeleton, a compound having a trihalomethyl group, and the like), an acylphosphine compound, a hexaarylbiimidazole compound, an oxime compound, an organic peroxide, a thio compound, a ketone compound, an aromatic onium salt, an acetophenone compound, an azo compound, an azide compound, a metallocene compound, an organic boron compound, and an iron arene complex. For the details thereof, reference can be made to the description in paragraphs 0165 to 0182 of JP2016-027357A, the contents of which are incorporated in the present specification. Among them, an acetophenone compound, an acylphosphine compound, and an oxime compound are preferable.

In addition, as the radical polymerization initiator, commercially available initiators can also be used. Examples of such an initiator are the same as the commercially available initiators exemplified as the initiators which can be used, for example, in the composition for forming a pattern.

In a case where the radical polymerization initiator is contained, the content thereof with respect to the solid content of the composition for forming a liquid film is preferably 0.1% to 10% by mass, more preferably 1% to 8% by mass, and still more preferably 2% to 5% by mass. In a case where two or more kinds of the radical polymerization initiators are used, the total amount thereof is preferably within the above range.

<<Other Components>>

The composition for forming a liquid film may contain one or more kinds of a polymerization inhibitor, an antioxidant, a leveling agent, a thickener, a surfactant, or the like, in addition to the aforementioned components.

<Kit>

A kit according to the embodiment of the present invention includes a combination of the composition for forming a pattern, which is for forming a pattern (cured film) for imprinting, and a composition for forming an underlayer film, which is for forming an underlayer film for imprinting. By using the kit according to the embodiment of the present invention, imprinting having excellent releasability can be performed. The composition for forming an underlayer film particularly preferably contains the resin having a radically polymerizable group, and an organic solvent. Furthermore, the kit according to the embodiment of the present invention preferably includes a composition for forming a liquid film containing a polymerizable compound which is a liquid at 23° C. and 1 atm.

### EXAMPLES

Hereinafter, the present invention will be described in more detail with reference to Examples. The materials, the used amounts, the ratios, the treatment details, the treatment procedures, and the like shown in the following Examples can be appropriately modified without departing from the spirit of the present invention. Therefore, the scope of the present invention is not limited to the specific examples described below. Unless otherwise specified, “parts” and “%” are based on mass.

<Preparation of Composition for Forming Pattern>

For Examples and Comparative Examples in Tables 1 to 3 below, a composition was prepared by mixing components shown in each table at each of formulation proportions shown in each table, and further adding 4-hydroxy-2,2,6,6-tetramethylpiperidine-1-oxyl free radical (produced by Tokyo Chemical Industry Co., Ltd.) as a polymerization inhibitor so that the amount thereof was 200 ppm by mass (0.02% by mass) with respect to the entire polymerizable compound. Moreover, each of the compositions was filtered with a composite filter connected in the following order of a polytetrafluoroethylene (PTFE)-made filter having a pore diameter of 0.1 μm, a nylon-made filter having a pore diameter of 0.02 μm, and a PTFE-made filter having a pore diameter of 0.003 μm, to prepare a composition for forming a pattern. The units of the formulation proportions of the polymerizable compound, photopolymerization initiator, release agent, and sensitizer in the tables are each parts by mass. Moreover, “Cb/Cc” in the tables is the mass ratio of the content Cb of the photopolymerization initiator (B) to the content Cc of the photopolymerization initiator (C).

TABLE 1

| | | Exam- | Exam- | Exam- | Exam- | Exam- | Exam- | Exam- | Exam- | Exam- | Exam- |
|---|---|---|---|---|---|---|---|---|---|---|---|
| | | ple 1 | ple 2 | ple 3 | ple 4 | ple 5 | ple 6 | ple 7 | ple 8 | ple 9 | ple 10 |
| Polymerizable | A-1 | 43 | 43 | 43 | 44 | 40 | 43.6 | 41 | 43 | 25 | 85 |
| compound | A-2 | | | | | | | | | | |
| | A-3 | 30 | 30 | 30 | 30 | 28 | 30 | 29 | 30 | | |
| | Ab-1 | | | | | | | | | 48 | |
| | Ab-2 | | | | | | | | | | |
| | Ab-3 | | | | | | | | | | |
| | Ab-4 | 20 | 20 | 20 | 20.6 | 18 | 21 | 19 | 20 | 20 | 8 |
| | Ab-5 | | | | | | | | | | |
| | Ab-6 | | | | | | | | | | |
| | Ab-7 | | | | | | | | | | |
| Photopolymerization | B-1 | 2 | 1 | 6 | 0.4 | 9 | 2 | 2 | | 2 | 2 |
| initiator | B-2 | | | | | | | | | | |
| | B-3 | | | | | | | | | | |
| | B-4 | | | | | | | | 2 | | |
| | C-1 | 2 | 3 | 1 | 2 | 2 | 0.4 | 6 | 2 | 2 | 2 |
| | C-2 | | | | | | | | | | |
| | C-3 | | | | | | | | | | |
| | D-1 | | | | | | | | | | |
| | D-2 | | | | | | | | | | |
| | D-3 | | | | | | | | | | |
| Release agent | E-1 | 3 | 3 | | 3 | 3 | 3 | 3 | 3 | 3 | 3 |
| | E-2 | | | | | | | | | | |
| | E-3 | | | | | | | | | | |
| | E-4 | | | | | | | | | | |
| | E-5 | | | | | | | | | | |
| Sensitizer | F-1 | | | | | | | | | | |
| | F-2 | | | | | | | | | | |
| Solvent | PGMEA | | | | | | | | | | |

| | | | | | | | | | | |
|---|---|---|---|---|---|---|---|---|---|---|
| Total (parts by mass) | 100 | 100 | 100 | 100 | 100 | 100 | 100 | 100 | 100 | 100 |
| Viscosity: mPa · s | 9.0 | 9.0 | 11.0 | 9.0 | 13.0 | 9.0 | 11.0 | 9.0 | 7.0 | 20.0 |
| Cb/Cc | 1.0 | 0.3 | 6.0 | 0.2 | 4.5 | 5.0 | 0.3 | 1.0 | 1.0 | 1.0 |
| ΔHSP | 7.1 | 7.1 | 7.1 | 7.1 | 7.1 | 7.1 | 7.1 | 11.0 | 7.1 | 7.1 |
| Evaluation of suppression of | A | B | B | B | B | B | B | B | B | A |
| collapse defects | | | | | | | | | | |
| Evaluation of reactivity | A | B | B | B | B | B | B | B | B | B |
| Evaluation of filling properties | A | A | B | A | B | A | B | A | A | C |
| Evaluation of releasability | A | A | A | A | A | A | A | A | A | B |
| Evaluation of defect increase | A | B | A | B | A | B | A | B | B | B |
| rate | | | | | | | | | | |

TABLE 2

| | | Exam- | Exam- | Exam- | Exam- | Exam- | Exam- | Exam- | Exam- | Exam- | Exam- |
|---|---|---|---|---|---|---|---|---|---|---|---|
| | | ple 11 | ple 12 | ple 13 | ple 14 | ple 15 | ple 16 | ple 17 | ple 18 | ple 19 | ple 20 |
| Polymerizable | A-1 | 43 | 43 | 43 | 44 | 43 | | | | | |
| compound | A-2 | | | | | | 50 | 60 | 40 | 50 | 60 |
| | A-3 | 30 | 30 | 30 | 31 | 30 | | | 35 | | |
| | Ab-1 | | | | | | 30 | | | | |
| | Ab-2 | | | | | | | | | | |
| | Ab-3 | | | | | | | 20 | | 30 | 20 |
| | Ab-4 | 20 | 20 | 20 | 21 | 20 | | | 18 | | |
| | Ab-5 | | | | | | 13 | 13 | | 13 | 13 |
| | Ab-6 | | | | | | | | | | |
| | Ab-7 | | | | | | | | | | |
| Photopolymerization | B-1 | 2 | 2 | 2 | 2 | | | 2 | 2 | 2 | |
| initiator | B-2 | | | | | 2 | | | | | |
| | B-3 | | | | | | 2 | | | | 2 |
| | B-4 | | | | | | | | | | |
| | C-1 | | 2 | 2 | 2 | | 2 | 2 | | 1.9 | 1.9 |
| | C-2 | | | | | 2 | | | 2 | | |
| | C-3 | 2 | | | | | | | | | |
| | D-1 | | | | | | | | | | |
| | D-2 | | | | | | | | | | |
| | D-3 | | | | | | | | | | |
| Release agent | E-1 | 3 | | | | 3 | | 3 | | | |
| | E-2 | | | 3 | | | | | | | |
| | E-3 | | | | | | 3 | | | | |
| | E-4 | | 3 | | | | | | 3 | | 3 |
| | E-5 | | | | | | | | | 3 | |
| Sensitizer | F-1 | | | | | | | | | 0.1 | |
| | F-2 | | | | | | | | | | 0.1 |
| Solvent | PGMEA | | | | | | | | | | |

| | | | | | | | | | | |
|---|---|---|---|---|---|---|---|---|---|---|
| Total (parts by mass) | 100 | 100 | 100 | 100 | 100 | 100 | 100 | 100 | 100 | 100 |
| Viscosity: mPa · s | 9.0 | 9.0 | 9.0 | 8.0 | 9.0 | 5.0 | 7.0 | 4.0 | 6.0 | 7.0 |
| Cb/Cc | 1.0 | 1.0 | 1.0 | 1.0 | 1.0 | 1.0 | 1.0 | 1.0 | 1.1 | 1.1 |
| ΔHSP | 9.3 | 7.1 | 7.1 | 7.1 | 10.9 | 6.6 | 7.1 | 11.0 | 7.1 | 6.6 |
| Evaluation of suppression of | B | A | A | A | A | A | A | A | A | A |
| collapse defects | | | | | | | | | | |
| Evaluation of reactivity | B | A | A | A | A | A | A | A | A | A |
| Evaluation of filling properties | A | A | A | A | A | A | A | A | A | A |
| Evaluation of releasability | A | B | A | C | A | A | A | A | A | A |
| Evaluation of defect increase | B | B | B | A | A | A | A | A | A | A |
| rate | | | | | | | | | | |

TABLE 3

| | | | | Com- | Com- | Com- | Com- | Com- | Com- | Com- | Com- |
|---|---|---|---|---|---|---|---|---|---|---|---|
| | | | | par- | par- | par- | par- | par- | par- | par- | par- |
| | | | | ative | ative | ative | ative | ative | ative | ative | ative |
| | | Exam- | Exam- | Exam- | Exam- | Exam- | Exam- | Exam- | Exam- | Exam- | Exam- |
| | | ple 21 | ple 22 | ple 1 | ple 2 | ple 3 | ple 4 | ple 5 | ple 6 | ple 7 | ple 8 |
| Polymerizable | A-1 | 1.29 | | 43 | 43 | 43 | 43 | | | | 43 |
| compound | A-2 | | 1.5 | | | | | | | | |
| | A-3 | 0.9 | | 30 | 30 | 30 | 30 | | | | 30 |
| | Ab-1 | | 0.9 | | | | | 43 | 23 | 20 | |
| | Ab-2 | | | | | | | | 20 | 30 | |
| | Ab-3 | | | | | | | | 30 | | |
| | Ab-4 | 0.6 | | 20 | 20 | 20 | 20 | 20 | | | 20 |
| | Ab-5 | | 0.39 | | | | | | | 23 | |
| | Ab-6 | | | | | | | 30 | | | |
| | Ab-7 | | | | | | | | | 20 | |
| Photopolymerization | B-1 | 0.06 | | 2 | 2 | | 4 | 2 | 2 | 2 | 2 |
| initiator | B-2 | | | | | | | | | | |
| | B-3 | | 0.06 | | | | | | | | |
| | B-4 | | | | | | | | | | |
| | C-1 | 0.06 | 0.06 | | | 4 | | 2 | | 2 | |
| | C-2 | | | | | | | | 2 | | |
| | C-3 | | | | | | | | | | |
| | D-1 | | | 2 | | | | | | | |
| | D-2 | | | | 2 | | | | | | |
| | D-3 | | | | | | | | | | 2 |
| Release agent | E-1 | 0.09 | | 3 | 3 | 3 | 3 | 3 | | | 3 |
| | E-2 | | | | | | | | | 3 | |
| | E-3 | | 0.09 | | | | | | | | |
| | E-4 | | | | | | | | | | |
| | E-5 | | | | | | | | 3 | | |
| Sensitizer | F-1 | | | | | | | | | | |
| | F-2 | | | | | | | | | | |
| Solvent | PGMEA | 97 | 97 | | | | | | | | |

| | | | | | | | | | | |
|---|---|---|---|---|---|---|---|---|---|---|
| Total (parts by mass) | 100 | 100 | 100 | 100 | 100 | 100 | 100 | 80 | 100 | 100 |
| Viscosity: mPa · s | 9.0 | 5.0 | 9.0 | 9.0 | 9.0 | 9.0 | 11.0 | 13.0 | 60.0 | 9.0 |
| Cb/Cc | 1.0 | 1.0 | — | — | — | — | 1.0 | 1.0 | 1.0 | — |
| ΔHSP | 7.1 | 6.6 | 3.5 | 1.9 | — | — | 7.1 | 11.0 | 7.1 | 3.1 |
| Evaluation of suppression of collapse | A | A | D | C | D | C | C | C | C | D |
| defects | | | | | | | | | | |
| Evaluation of reactivity | A | A | C | C | D | C | B | B | B | C |
| Evaluation of filling properties | A | A | A | A | A | A | B | A | D | A |
| Evaluation of releasability | A | A | A | A | A | A | A | C | C | A |
| Evaluation of defect increase rate | A | A | C | C | D | C | C | C | C | C |

<Raw Materials>

The specifications of respective raw materials are as follows.

<<(A) Polymerizable Compound which Contains Aromatic Ring and does not Contain Hydroxyl Group>>

A-1: Phenylethylene glycol diacrylate (molecular weight of 246).

A-2: Compound having the following structure (molecular weight of 246).

A-3: Benzyl acrylate (molecular weight of 162).

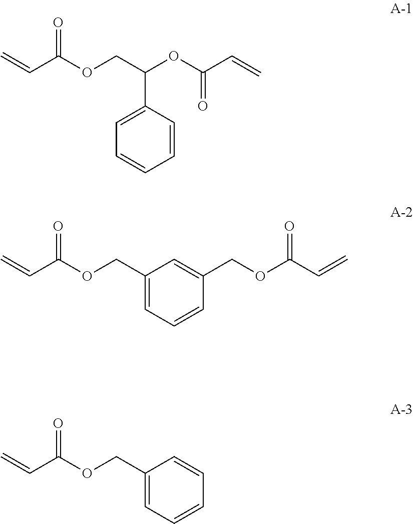

<<(Ab) Other Polymerizable Compound>>

Ab-1: Neopentylglycol diacrylate (molecular weight of 212).

Ab-2: Compound having the following structure (molecular weight of 262).

Ab-3: Compound having the following structure (molecular weight of 196).

Ab-4: Isobornyl acrylate (molecular weight of 208).

Ab-5: Compound having the following structure (molecular weight of 240).

Ab-6: Compound having the following structure (molecular weight of 192).

Ab-7: Pentaerythritol tetraacrylate (molecular weight of 352).

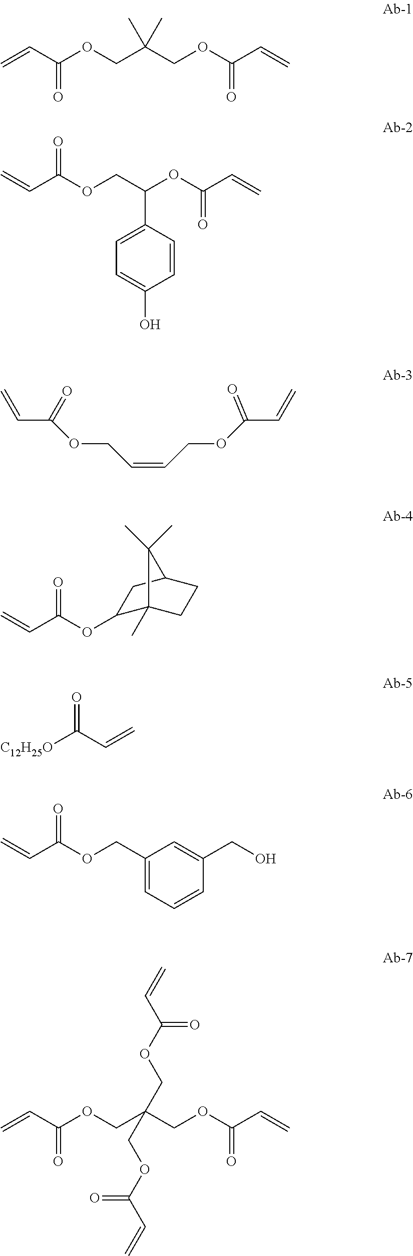

<<(B) Photopolymerization Initiator which Contains Aromatic Ring and does not Contain Hydroxyl Group>>

B-1: Compound having the following structure (molecular weight of 418, d component of 19.7, p component of 8.6, h component of 6.1, Omnirad 819, manufactured by IGM Resins B.V.).

B-2: Compound having the following structure (molecular weight of 348, d component of 20, p component of 9.3, h component of 6.2, Omnirad TPO, manufactured by IGM Resins B.V.).

B-3: Compound having the following structure (molecular weight of 316, d component of 19.3, p component of 9.1, h component of 6.2, Omnirad TPO-L, manufactured by IGM Resins B.V.).

B-4: Compound having the following structure (molecular weight of 445, d component of 18.7, p component of 8.5, h component of 1.7, Irgacure OXE01, manufactured by BASF SE).

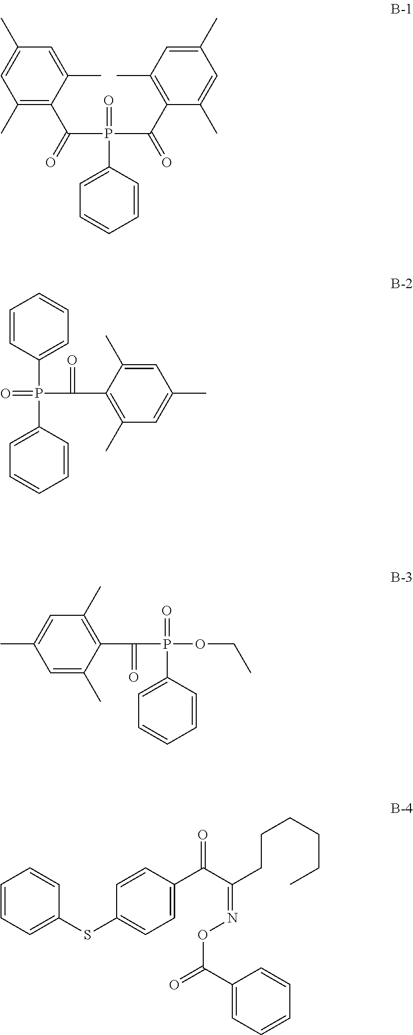

<<(C) Photopolymerization Initiator Represented by Formula (In-1)>>

C-1: Compound having the following structure (molecular weight of 224, d component of 18.7, p component of 10.8, h component of 12.5, Irgacure 2959, manufactured by BASF SE).

C-2: Compound having the following structure (molecular weight of 284, d component of 18.3, p component of 12.8, h component of 15.9).

C-3: Compound having the following structure (molecular weight of 284, d component of 18.2, p component of 12.6, h component of 13.9).

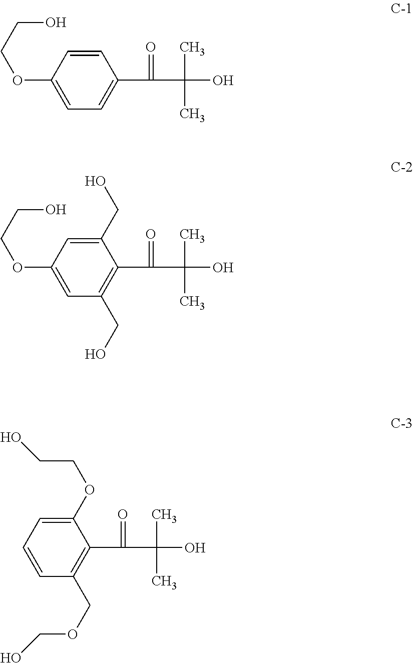 [SMILES: CC(C)(O)C(=O)c1ccc(OCCO)cc1 ; CC(C)(O)C(=O)c1c(CO)cc(OCCO)cc1CO ; CC(C)(O)C(=O)c1c(COCO)cccc1OCCO]

<<(D) Other Photopolymerization Initiator>>

D-1: Compound having the following structure (molecular weight of 164, d component of 18.4, p component of 7.5, h component of 8.1, Omnirad 1173, manufactured by IGM Resins B.V.).

D-2: Compound having the following structure (molecular weight of 340, d component of 19.2, p component of 9.5, h component of 7.4, Omnirad 127, manufactured by IGM Resins B.V.).

D-3: Compound having the following structure (molecular weight of 222, d component of 18.3, p component of 7.8, h component of 7.1).

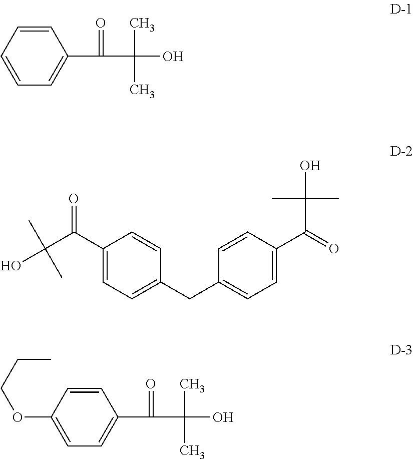 [SMILES: CC(C)(O)C(=O)c1ccccc1 ; CC(C)(O)C(=O)c1ccc(Cc2ccc(C(=O)C(C)(C)O)cc2)cc1 ; CCCOc1ccc(C(=O)C(C)(C)O)cc1]

<<(E) Release Agent>>

E-1 to E-5: Compounds having the following respective structures.

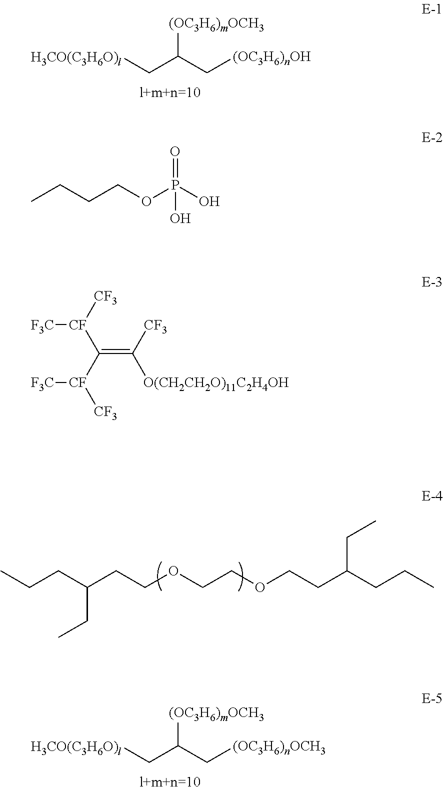

<<(F) Sensitizer>>

F-1, F-2: Compounds having the following respective structures.

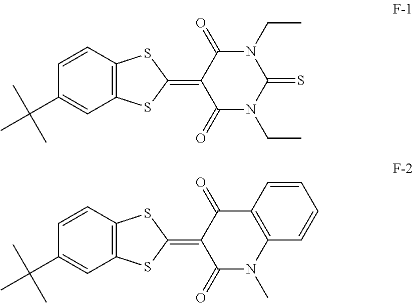

<Measurement>

The measurement of the following characteristics was performed for each raw material, and each composition for forming a pattern of Examples and Comparative Examples, as necessary.

<<Viscosity>>

For each composition for forming a pattern of Examples 1 to 20 and Comparative Examples 1 to 8, the viscosity (unit: mPa.$) of the composition for forming a pattern, which had not been cured, was measured under a temperature condition of 23° C.±0.2° C. using a RE-80L-type rotational viscometer manufactured by TOM SANGYO CO., LTD. The viscosities of the components excluding a solvent from the composition for forming a pattern in Examples 21 and 22 were substituted by the measured viscosities of the compositions of Examples 1 and 16, respectively. A rotation speed during the measurement was adjusted as shown in Table 4 below according to the viscosity.

TABLE 4

| Viscosity [mPa · s] | Appropriate rotation speed [rpm] |
|---|---|
| 0.001 or more and less than 6.077 | 100 |
| 6.077 or more and less than 12.16 | 50 |
| 12.16 or more and less than 30.39 | 20 |
| 30.39 or more and less than 60.77 | 10 |
| 60.77 or more and less than 121.6 | 5 |
| 121.6 or more and less than 303.9 | 2 |
| 303.9 or more and less than 607.7 | 1 |
| 607.7 or more and less than 1216 | 0.5 |
| 1216 or more and less than 2025 | 0.3 |

<<Calculation of Hansen Solubility Parameter Distance (ΔHSP)>>

For the photopolymerization initiators (B) and (C) according to Examples and Comparative Examples, the Hansen solubility parameter and the boiling point were calculated using HSP calculation software HSPiP. Specifically, first, the respective components of the Hansen solubility parameter vector were calculated by inputting a molecular formula of respective photopolymerization initiator in a SMILES format into the above software. Next, the Hansen solubility parameter distance (ΔHSP) was calculated by determining ΔD, ΔP, and ΔH, respectively, from respective components (d component, p component, and h component) of a Hansen solubility parameter of respective compounds and applying ΔD, ΔP, and ΔH to Expression (1). Moreover, temperature conditions during the formation of the underlayer film were set in consideration of the boiling point calculated by the same software. For Comparative Examples 1 and 2, ΔHSP was calculated using the Hansen solubility parameter of other photopolymerization initiator instead of the Hansen solubility parameter of the photopolymerization initiator (C).

<Evaluation>

For each composition for forming a pattern of Examples and Comparative Examples, the following items were evaluated. Moreover, the illuminance of the ultra-high pressure mercury lamp was measured using ACCUMULATED UV METER UIT-250 manufactured by Ushio Inc.

<<Evaluation of Suppression of Pattern Collapse Defects>>

A silicon wafer was spin-coated with the composition for forming a closely adhesive layer shown in Example 6 of JP2014-024322A, and heated for 1 minute using a hot plate at 220° C. to form a closely adhesive layer having a thickness of 5 nm. Moreover, for Examples 1 to 20 and Comparative Examples 1 to 8, the composition for forming a pattern was applied onto the closely adhesive layer using an ink jet device (INK JET PRINTER DMP-2831 manufactured by FUJIFILM Dimatix Inc.). Moreover, for Examples 21 and 22, the composition for forming a pattern was applied onto the closely adhesive layer at 1500 rpm using a spin coating device, and then heated at 60° C. for 30 seconds using a hot plate for application. Thereafter, a mold for imprinting was pressed against the silicon wafer from the side of the composition for forming a pattern under a helium atmosphere. The used mold is a quartz mold with line/space having a line width of 13 nm, a depth of 40 nm, and a pitch of 26 nm. Subsequently, exposure was performed from the surface of the mold using an ultra-high pressure mercury lamp, and the mold was released to obtain a pattern consisting of a cured substance of the composition for forming a pattern. Regarding the exposure conditions, the illuminance at a wavelength of 313 nm is 500 mW/cm², and the exposure time is 0.1 seconds.

Using a defect review classifying device (RS-5500 manufactured by Hitachi High-Tech Fielding Corporation), scanning electron microscope (SEM) observation was performed at 500 places in the line/space area of the pattern consisting of the cured substance. Moreover, a rate (defect generation rate) R (%) at which pattern collapse defects were generated was derived by the following expression, and a degree of defect suppression of the pattern was evaluated according to the value based on the following evaluation standard.

Defect generation rate R (%)=[total number of places where pattern collapse defects were observed as result of SEM observation]/[total number (500 in case of present example) of places where SEM observation was performed]×100

Evaluation Standard
A: R=0 (that is, pattern collapse defects were not confirmed)
B: 0%<R≤1%
C: 1%<R≤10%
D: 10%—R

<<Evaluation of Reactivity>>

Using FT-IR (Nicolet iS5OR manufactured by Thermo Fisher Scientific Inc.) having a RapidScan function, the reaction speed (reaction rate at 0.5 seconds after exposure) of the curing of the composition for forming a pattern was measured through attenuated total reflection (ATR). First, 1 μL of the composition for forming a pattern was added dropwise onto a diamond-made prism, and slide glass was overlaid on the prism from above the composition for forming a pattern. Subsequently, the composition for forming a pattern was exposed to ultraviolet rays using an ultra-high pressure mercury lamp. Regarding the exposure conditions, the illuminance at a wavelength of 313 nm is 500 mW/cm², and the exposure time is 0.1 seconds.

Moreover, in the exposure, for the polymerizable group of the polymerizable compound in the composition for forming a pattern, the reaction rate at 0.5 seconds after the exposure was measured using the FT-IR device. The reaction rate was defined by the following expression while focusing on a decrease in an infrared absorption peak (near 1,630 cm′) due to C=C stretching vibration of a vinyl group. In the following expression, a “peak surface area” indicates a “peak surface area” of an FT-IR spectrum in a range of 1,650 to 1,600 cm⁻¹. Moreover, the reactivity was evaluated according to the reaction rate based on the following evaluation standard.

Reaction rate (%)=[(peak surface area before exposure)−(peak surface area at 0.5 seconds after exposure)]/[peak surface area before exposure]×100

Conditions for Measurement by FT-IR Device
Measured wave number range: 3,500 to 400 cm⁻¹
Wave number resolution: 32 cm⁻¹
Number of times of high-speed scan: 100 spectra/sec

Evaluation Standard
A: 90%≤Reaction rate
B: 85%≤Reaction rate<90%
C: 75%≤Reaction rate<85%
D: Reaction rate <75%

<<Evaluation of Filling Properties>>

In the same manner as in the case of the above-described evaluation of the suppression of the collapse defects, a closely adhesive layer was formed on a silicon wafer, the composition for forming a pattern was applied onto the closely adhesive layer, and a mold for imprinting was pressed against the silicon wafer from the side of the composition for forming a pattern. However, the used mold is a quartz mold having a concave-type pillar structure in which an opening portion is a circle with a radius of 1 μm and the depth is 2 μm.

The state of filling the inside of the concave part of the mold with the composition for forming a pattern was observed with a camera, and a time required to complete the filling was measured. Moreover, the filling properties were evaluated as follows according to the time.
A: Shorter than 3 seconds
B: 3 seconds or longer and shorter than 5 seconds
C: 5 seconds or longer and shorter than 10 seconds
D: 10 seconds or longer

<<Evaluation of Releasability>>

In the same manner as in the case of the above-described evaluation of the suppression of the collapse defects, a closely adhesive layer was formed on a silicon wafer, and the composition for forming a pattern was applied onto the closely adhesive layer. Thereafter, a mold for imprinting was pressed against the silicon wafer from the side of the composition for forming a pattern under a helium atmosphere. The used mold is a quartz mold with line/space having a line width of 20 nm, a depth of 50 nm, and a pitch of 40 nm. Subsequently, exposure was performed from the surface of the mold using an ultra-high pressure mercury lamp, and the mold was released to obtain a pattern consisting of a cured substance of the composition for forming a pattern. The exposure conditions were an illuminance of 500 mW/cm² at 313 nm and an exposure time of 0.1 seconds.

In the pattern formation, a force (releasing force F, unit: N) required for release in a case where the quartz mold was released from the pattern was measured, and the releasability was evaluated as follows according to the measured value. The releasing force was measured according to the method of Comparative Example described in paragraphs 0102 to 0107 of JP2011-206977A.
A: F≤15 N
B: 15 N<F≤18N
C: 18 N<F≤20 N

<<Evaluation of Defect Increase Rate (Affinity of Composition to Mold)>>

In the same manner as in the case of the above-described evaluation of the suppression of the collapse defects, a closely adhesive layer was formed on a silicon wafer, and the composition for forming a pattern was applied onto the closely adhesive layer. Thereafter, a mold for imprinting was pressed against the composition for forming a pattern under a helium atmosphere. The used mold is a quartz mold with line/space having a line width of 30 nm, a depth of 75 nm, and a pitch of 60 nm. Subsequently, exposure was performed from the surface of the mold using an ultra-high pressure mercury lamp under a condition of an exposure amount of 100 mJ/cm², and the mold was released to obtain a pattern (hereinafter, also referred to as a sample) consisting of a cured substance of the composition for forming a pattern. The series of steps from application by ink jet to mold release was repeated 20 times on the silicon wafer at different locations.

The number of defects in the first and 20th samples was measured using a defect inspection device (KLA2835, manufactured by KLA Corporation.), and the number of defects D (unit: pieces) was confirmed. Moreover, the difference ΔD obtained by subtracting the number of defects in the first time from the number of defects in the 20th time was evaluated based on the following standard. Normally, ΔD is a positive value, but a case where ΔD is a negative value is treated as substantially zero.
A: ΔD=0 piece (no increase in defects)
B: 1 piece≤ΔD<3 pieces
C: 3 pieces ≤ΔD<10 pieces
D: 10 pieces≤ΔD

<Evaluation Result>

The evaluation results of the respective Examples and Comparative Examples are shown in Tables 1 to 3. From the results, it was found that, by using the composition for forming a pattern according to the embodiment of the present invention, an imprinting method in which the occurrence of defects is suppressed can be performed even in high-resolution pattern formation.

In addition, a predetermined pattern corresponding to a semiconductor circuit was formed on the silicon wafer by using the composition for forming a pattern according to each of Examples. Moreover, each silicon wafer was dry-etched by using this pattern as an etching mask, and each semiconductor element was produced using this silicon wafer. There was no problem with the performance of any of the semiconductor elements.

What is claimed is:

1. A composition for forming a pattern for imprinting, comprising:
(A) a polymerizable compound which contains an aromatic ring and does not contain a hydroxyl group;
(B) a photopolymerization initiator which contains an aromatic ring and does not contain a hydroxyl group; and
(C) a photopolymerization initiator represented by Formula (In-1),
wherein a viscosity of components excluding a solvent from the composition for forming a pattern at 23° C. is 300 mPa·s or lower, 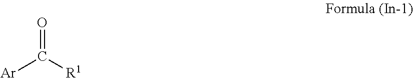
in Formula (In-1), Ar represents an aromatic ring-containing group having an aromatic ring substituted with one or more substituents, where at least one of the substituents is an electron-donating group, at least one of the substituents includes —O— directly linked to the aromatic ring, and at least one of the substituents includes a hydroxyl group, and
R¹ represents an aliphatic hydrocarbon group substituted with one or more hydroxyl groups.

2. The composition for forming a pattern according to claim 1,
wherein Cb/Cc, which is a mass ratio of a content Cb of the photopolymerization initiator (B) to a content Cc of the photopolymerization initiator (C), is 0.5 to 5.

3. The composition for forming a pattern according to claim 1,
wherein a content of the photopolymerization initiator (B) is 0.5% to 8% by mass with respect to the polymerizable compound (A).

4. The composition for forming a pattern according to claim 1,
wherein a content of the photopolymerization initiator (C) is 0.5% to 5% by mass with respect to the polymerizable compound (A).

5. The composition for forming a pattern according to claim 1,
wherein a compound represented by Formula (In-2) is contained as the photopolymerization initiator (C), 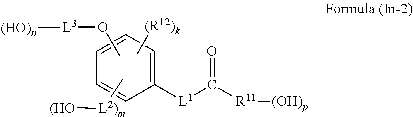
in Formula (In-2), L¹ and L² each independently represent a single bond or a divalent linking group,
L³ represents an (n+1)-valent linking group,
R¹¹ represents a (p+1)-valent aliphatic hydrocarbon group,
R¹² represents a monovalent substituent,
k, m, and n each independently represent an integer of 0 to 2, where m+n is 1 to 3 and k+m+n is 1 to 5, and
p represents an integer of 1 to 3.

6. The composition for forming a pattern according to claim 1,
wherein a compound represented by Formula (In-3) is contained as the photopolymerization initiator (C), 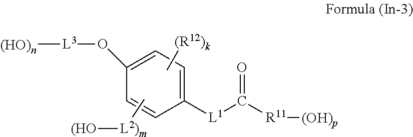
in Formula (In-3), L¹ and L² each independently represent a single bond or a divalent linking group,
L³ represents an (n+1)-valent linking group,
R¹¹ represents a (p+1)-valent aliphatic hydrocarbon group,
R¹² represents a monovalent substituent,
k, m, and n each independently represent an integer of 0 to 2, where m+n is 1 to 3 and k+m+n is 1 to 5, and
p represents an integer of 1 to 3.

7. The composition for forming a pattern according to claim 1,
wherein a molecular weight of the photopolymerization initiator (C) is 170 to 330.

8. The composition for forming a pattern according to claim 1,
wherein a Hansen solubility parameter distance ΔHSP between the photopolymerization initiator (B) and the photopolymerization initiator (C) is 4 or more.

9. The composition for forming a pattern according to claim 1,
wherein an acylphosphine oxide-based compound is contained as the photopolymerization initiator (B).

10. The composition for forming a pattern according to claim 1,
wherein a content of the polymerizable compound (A) is 30% to 90% by mass with respect to a total polymerizable compound.

11. The composition for forming a pattern according to claim 1,
wherein a content of a total solid content in the composition for forming a pattern is 90% by mass or greater with respect to an entire composition for forming a pattern.

12. The composition for forming a pattern according to claim 11,
wherein a content of the solvent is 5% by mass or less with respect to the composition for forming a pattern.

13. The composition for forming a pattern according to claim 1, further comprising:
(D) a release agent.

14. The composition for forming a pattern according to claim 13,
wherein the release agent includes a compound which contains a hydroxyl group.

15. The composition for forming a pattern according to claim 13,
wherein the release agent includes a compound which does not contain a hydroxyl group.

16. A cured film formed from the composition for forming a pattern according to claim 1.

17. A laminate comprising:
a layered film consisting of the composition for forming a pattern according to claim 1; and
a substrate for forming the layered film.

18. A pattern producing method comprising:
applying the composition for forming a pattern according to claim 1 onto a substrate or a mold; and
irradiating the composition for forming a pattern with light in a state of being sandwiched between the mold and the substrate.

19. A method for manufacturing a semiconductor element, comprising:
the producing method according to claim 18 as a step.

20. The method for manufacturing a semiconductor element according to claim 19, further comprising:
etching the substrate using a pattern obtained by the pattern producing method as a mask.
